(19) United States
(12) Patent Application Publication
(10) Pub. No.: US 2026/0293162 A1
(43) Pub. Date: Sep. 24, 2026

(54) MEMORY APPARATUS HAVING BUFFER DIE

(71) Applicant: SK hynix Inc., Icheon-si Gyeonggi-do (KR)

(72) Inventor: Seong Ju LEE, San Jose, CA (US)

(73) Assignee: SK hynix Inc., Icheon-si Gyeonggi-do (KR)

(21) Appl. No.: 19/572,639

(22) Filed: Mar. 19, 2026

Related U.S. Application Data
(60) Provisional application No. 63/775,148, filed on Mar. 20, 2025.

(30) Foreign Application Priority Data
Mar. 9, 2026 (KR) 10-2026-0042098

(51) Int. Cl. H10B 80/00; G11C 7/10; H10W 44/20; H10W 90/00; H10W 90/24

(52) U.S. Cl. CPC H10B 80/00; G11C 7/1048; H10W 44/216; H10W 90/24; H10W 90/754; G11C 2207/2272

(57) ABSTRACT

A memory apparatus includes a package substrate, a plurality of memory dies, and a buffer die. The plurality of memory dies are connected to a data bus through the buffer die. The buffer die selectively connects the data bus to one or more of the memory dies based on a chip selection signal to reduce a capacitive load of the data bus.

### CROSS-REFERENCES TO RELATED APPLICATION

The present application claims benefit under 35 U.S.C. § 119 (e) to U.S. Provisional Application No. 63/775,148 filed on Mar. 20, 2025, and claims priority under 35 U.S.C. § 119 (a) to Korean application number 10-2026-0042098 filed on Mar. 9, 2026, in the Ministry of Intellectual Property, which applications are incorporated herein by reference in their entirety.

### BACKGROUND

### 1. Technical Field

Various embodiments generally relate to integrated circuit technology, and, more particularly, to a memory apparatus having a buffer die.

### 2. Related Art

Recent advances in the fields of artificial intelligence (AI) and big data have driven explosive growth, thereby increasing the demand for memory apparatuses with higher performance, while low-power memory apparatuses are also required in accordance with environmentally friendly policies. In general, low-power DRAM (LPDDR, Low Power Double Data RAM), which has excellent power characteristics, is used as memory for mobile devices. Because server devices are equipped with large memory capacities and thus consume a large amount of power, low-power DRAM may be used as memory for server devices in order to reduce the power consumption of the server devices. However, low-power DRAM has difficulty in expanding memory capacity compared to non-low-power DRAM. Accordingly, various studies have been conducted to increase the memory capacity of low-power DRAM.

Although the memory capacity may be expanded by increasing the number of channels of a semiconductor system, this approach is inefficient because the number of pads provided in a central processing unit (CPU) increases in proportion to the increased number of channels. Therefore, a method of expanding the memory capacity of low-power DRAM itself is more practical, and the memory capacity of low-power DRAM may be increased by increasing the number of memory dies and the number of ranks constituting the low-power DRAM. However, when a plurality of memory dies share a data bus, a capacitive load of the data bus increases, which reduces the speed of the data bus and, as a result, may significantly degrade the bandwidth of the data bus.

### SUMMARY

In an embodiment, a memory apparatus may include a package substrate, a first memory die, a second memory die, a third memory die, a fourth memory die, and a buffer die. The first memory die, the second memory die, the third memory die, and the fourth memory die may be sequentially disposed on the package substrate. The buffer die may be disposed on the package substrate, may be connected to a first data bus and a second data bus, and may be configured, based on a chip selection signal, to connect the first data bus to one of the first memory die and the second memory die and connect the second data bus to one of the third memory die and the fourth memory die.

In an embodiment, a memory apparatus may include a package substrate, a buffer die, a first memory die, a second memory die, a third memory die, and a fourth memory die. The buffer die may be disposed on the package substrate. The first memory die, the second memory die, the third memory die, and the fourth memory die may be sequentially disposed on the buffer die. The buffer die may be connected to a first data bus and a second data bus and may, based on a chip selection signal, connect the first data bus to one of the first memory die and the second memory die and connect the second data bus to one of the third memory die and the fourth memory die.

In an embodiment, a memory apparatus may include a package substrate, a first memory die, a second memory die, a third memory die, a fourth memory die, a fifth memory die, a sixth memory die, a seventh memory die, an eighth memory die, and a buffer die. The package substrate may include first signal transmission lines, second signal transmission lines, third signal transmission lines, and fourth signal transmission lines. The first memory die, the second memory die, the third memory die, the fourth memory die, the fifth memory die, the sixth memory die, the seventh memory die, and the eighth memory die may be sequentially disposed on the package substrate. The buffer die may be disposed on the package substrate, may be connected to a first data bus and a second data bus, and may be configured, based on a chip selection signal, to connect the first data bus to one of the first signal transmission lines and the second signal transmission lines and connect the second data bus to one of the third signal transmission lines and the fourth signal transmission lines. The first signal transmission lines may be connected in common to the first memory die and the second memory die. The second signal transmission lines may be connected in common to the third memory die and the fourth memory die. The third signal transmission lines may be connected in common to the fifth memory die and the sixth memory die. The fourth signal transmission lines may be connected in common to the seventh memory die and the eighth memory die.

In an embodiment, a memory apparatus may include a package substrate, a plurality of memory dies, and a buffer die. The package substrate may include first signal transmission lines, second signal transmission lines, third signal transmission lines, fourth signal transmission lines, fifth signal transmission lines, sixth signal transmission lines, seventh signal transmission lines, and eighth signal transmission lines. The plurality of memory dies may be sequentially disposed on the package substrate, each including n first data pads, n second data pads, n third data pads, and n fourth data pads. The buffer die may be disposed on the package substrate, may be connected to a first data bus, a second data bus, a third data bus, and a fourth data bus, and may be configured to connect the first data bus to the first signal transmission lines and the second signal transmission lines based on a first chip selection signal, may be configured to connect the second data bus to the third signal transmission lines and the fourth signal transmission lines based on a second chip selection signal, may be configured to connect the third data bus to the fifth signal transmission lines and the sixth signal transmission lines based on the first chip selection signal, and may be configured to connect the fourth data bus to the seventh signal transmission lines and the eighth signal transmission lines based on the second chip selection signal. The plurality of memory dies may be connected to the buffer die through the first to eighth signal transmission lines.

### BRIEF DESCRIPTION OF THE DRAWINGS

FIG. 1 is a diagram illustrating a configuration of a memory die according to an embodiment of the present disclosure.

FIG. 2 is a diagram illustrating a configuration of a memory apparatus according to an embodiment of the present disclosure.

FIG. 3 is a diagram illustrating a configuration of a buffer die illustrated in FIG. 2.

FIG. 4 is a diagram illustrating a configuration of a buffer control circuit illustrated in FIG. 3.

FIG. 5A is a diagram illustrating a configuration of a first data buffering circuit illustrated in FIG. 3.

FIG. 5B is a diagram illustrating a configuration of a second data buffering circuit illustrated in FIG. 3.

FIG. 6A is a timing diagram illustrating an operation of a buffer die during a write operation according to an embodiment of the present disclosure.

FIG. 6B is a timing diagram illustrating an operation of another buffer die during a read operation according to an embodiment of the present disclosure.

FIG. 7 is a diagram illustrating a configuration of a memory apparatus according to an embodiment of the present disclosure.

FIG. 8 is a diagram illustrating a configuration of a memory apparatus according to an embodiment of the present disclosure.

FIG. 9 is a diagram illustrating a configuration of a memory apparatus according to an embodiment of the present disclosure.

FIG. 10 is a diagram illustrating a configuration of a buffer die illustrated in FIG. 9.

FIG. 11 is a diagram illustrating a configuration of a buffer control circuit illustrated in FIG. 10.

FIG. 12A is a diagram illustrating a configuration of a first data buffering circuit illustrated in FIG. 10.

FIG. 12B is a diagram illustrating a configuration of a second data buffering circuit illustrated in FIG. 10.

FIG. 13 is a diagram illustrating a configuration of a memory die according to an embodiment of the present disclosure.

FIG. 14 is a diagram illustrating a configuration of a memory apparatus according to an embodiment of the present disclosure.

FIG. 15A is a diagram illustrating a configuration of a memory apparatus according to an embodiment of the present disclosure.

FIG. 15B is a diagram illustrating a configuration of a memory apparatus according to an embodiment of the present disclosure.

FIGS. 16A and 16B are diagrams illustrating a configuration of a buffer die according to an embodiment of the present disclosure.

### DETAILED DESCRIPTION

When an element is described as being “connected” to another element in the present disclosure, the elements may be directly coupled to each other or may be coupled through one or more intervening elements.

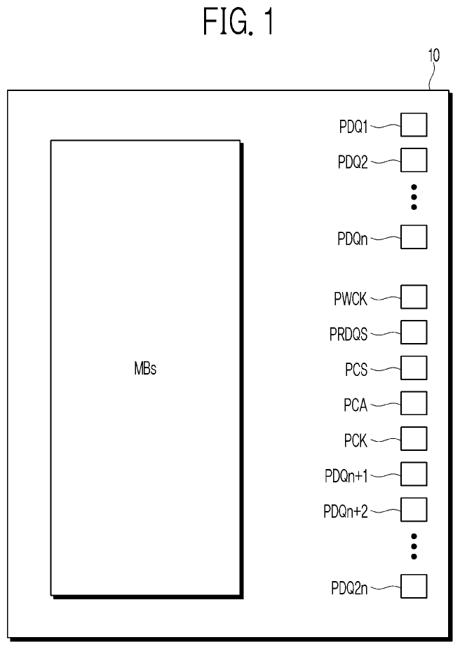

FIG. 1 is a diagram illustrating a configuration of a memory die 10 according to an embodiment of the present disclosure. Referring to FIG. 1, the memory die 10 may include a plurality of memory banks MBs, first data pads PDQ1, PDQ2, . . . , PDQn, and second data pads PDQn+1, PDQn+2, . . . , PDQ2n. The memory die 10 may further include a data clock pad PWCK, a read strobe pad PRDQS, a chip selection pad PCS, a command address pad PCA, and a system clock pad PCK. The first and second data pads PDQ1 to PDQ2n may each include n data pads. Here, n may be a multiple of 2 and may be 4, 6, 8, or 12. For example, in the memory die 10, n may be 8. A memory system to which the memory die 10 is applied may use a data bus composed of 2n signal transmission lines. The first data pads PDQ1, PDQ2, . . . , PDQn may be connected to one half of the data bus, and the second data pads PDQn+1, PDQn+2, . . . , PDQ2n may be connected to the other half of the data bus. The memory die 10 may receive a data clock signal through the data clock pad PWCK and may output a read strobe signal through the read strobe pad PRDQS. The memory die 10 may receive a chip selection signal through the chip selection pad PCS, may receive a command address signal through the command address pad PCA, and may receive a system clock signal through the system clock pad PCK. The memory die 10 may support a plurality of byte modes. For example, the memory die 10 may operate in a first byte mode and a second byte mode. In the first byte mode, the memory die 10 may receive n data signals at one time or may output n data signals at one time. In the second byte mode, the memory die 10 may receive 2n data signals at one time or may output 2n data signals at one time. The memory die 10 may support the first byte mode to provide an expanded memory capacity. In the first byte mode, the memory die 10 may store n data signals received through the first data pads PDQ1, PDQ2, . . . , PDQn or the second data pads PDQn+1, PDQn+2, . . . , PDQ2n in the plurality of memory banks MBs. Therefore, when a memory apparatus includes two memory dies that may be accessed together based on one chip selection signal, the memory apparatus may provide twice a memory capacity. To further increase the memory capacity, the memory apparatus may include a plurality of ranks, and a plurality of memory dies constituting different ranks and assigned different chip selection signals may be connected in common to the data bus to perform data input/output operations. For example, in the first byte mode, the memory apparatus may include four memory dies constituting first and second ranks, two memory dies constituting the first rank may be assigned a first chip selection signal, and two memory dies constituting the second rank may be assigned a second chip selection signal. As the number of ranks included in the memory apparatus increases, the number of memory dies and the number of chip selection signals may also increase in proportion. As the number of ranks and the number of memory dies included in the memory apparatus increase, the number of memory dies connected in common to the data bus increases, and a capacitive load of the data bus may increase. When the capacitive load of the data bus increases, a speed of the data bus and a data bandwidth decrease, and integrity of data signals propagated through the data bus may be degraded. Accordingly, an embodiment of the present disclosure provides a memory apparatus capable of reducing the capacitive load of the data bus while increasing a memory capacity by increasing the number of ranks and the number of memory dies included in the memory apparatus.

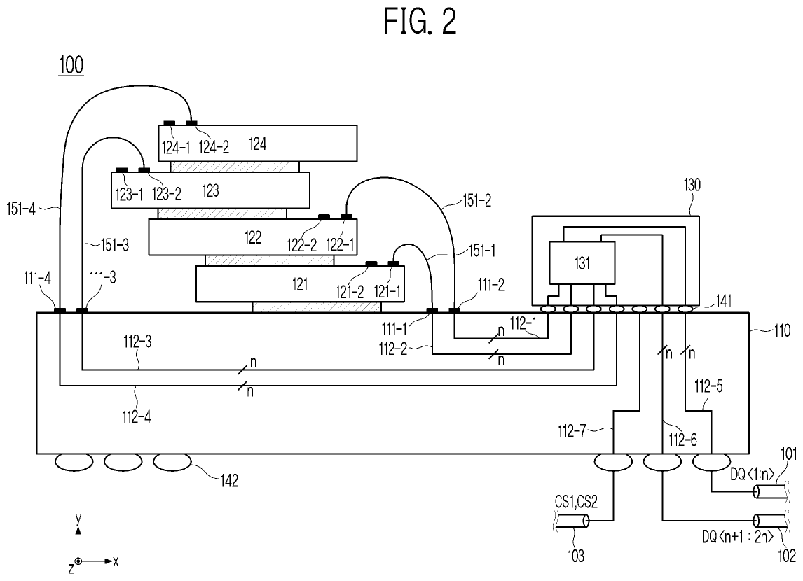

FIG. 2 is a diagram illustrating a configuration of a memory apparatus 100 according to an embodiment of the present disclosure. Referring to FIG. 2, the memory apparatus 100 may include a package substrate 110, a plurality of memory dies, and a buffer die 130. The plurality of memory dies and the buffer die 130 may be disposed on the package substrate 110, and the plurality of memory dies, the buffer die 130, and the package substrate 110 may be packaged as a single package to implement a single memory apparatus. The number of memory dies included in the memory apparatus 100 may be a multiple of 2, and the memory apparatus 100 may include at least a first memory die 121, a second memory die 122, a third memory die 123, and a fourth memory die 124. The first to fourth memory dies 121 to 124 may be sequentially disposed on the package substrate. For example, the first to fourth memory dies 121 to 124 may be stacked on the package substrate 110 in a vertical direction. The first to fourth memory dies 121 to 124 may be disposed on the package substrate 110 in a first region on the package substrate 110. The first memory die 121 may be disposed on the package substrate in a y-axis direction. The second memory die 122 may be disposed on the first memory die 121 in the y-axis direction. The third memory die 123 may be disposed on the second memory die 122 in the y-axis direction. The fourth memory die 124 may be disposed on the third memory die 123 in the y-axis direction. The first memory die 121 may be bonded on the package substrate 110 using a die attach film, and the second to fourth memory dies 122 to 124 may also be bonded on the first to third memory dies 121 to 123, respectively, using die attach films. The first memory die 121 may include n first data pads 121-1 and n second data pads 121-2. Here, n may be a multiple of 2 and may be, for example, 4, 6, 8, or 12. The second to fourth memory dies 122 to 124 may each include n first data pads 122-1, 123-1, and 124-1 and n second data pads 122-2, 123-2, and 124-2, respectively.

The second memory die 122 may be disposed on the first memory die 121 while being offset in a second direction of an x-axis such that the first and second data pads 121-1 and 121-2 of the first memory die 121 are exposed in a first direction of the x-axis. The second direction may be opposite to the first direction. The third memory die 123 may be disposed on the second memory die 122 while being offset in the second direction of the x-axis such that the first and second data pads 122-1 and 122-2 of the second memory die 122 are exposed in the first direction of the x-axis. The fourth memory die 124 may be disposed on the third memory die 123 while being offset in the first direction of the x-axis such that the first and second pads 123-1 and 123-2 of the third memory die 123 are exposed in the second direction of the x-axis. Because the fourth memory die 124 is disposed at the uppermost layer in a y-axis direction, the first and second data pads 124-1 and 124-2 of the fourth memory die 124 may be exposed in the second direction of the x-axis.

The first to fourth memory dies 121 to 124 may each have a structure substantially identical to that of the memory die 10 illustrated in FIG. 1 and may support a plurality of byte modes. For example, the first to fourth memory dies 121 to 124 may operate in a first byte mode and a second byte mode. In the first byte mode, the first to fourth memory dies 121 to 124 may receive n data signals at one time or may output n data signals at one time. In the second byte mode, the first to fourth memory dies 121 to 124 may receive 2n data signals at one time or may output 2n data signals at one time. The first to fourth memory dies 121 to 124 may each include 2n data pads to support both the first and second byte modes. The first to fourth memory dies 121 to 124 may operate in the first byte mode to provide an expanded memory capacity, and the first to fourth memory dies 121 to 124 may receive or output data signals through n data pads. The first and third memory dies 121 and 123 may constitute a first rank and may be assigned the same chip selection signal. The second and fourth memory dies 122 and 124 may constitute a second rank and may be assigned the same chip selection signal.

The buffer die 130 may be disposed on the package substrate 110 in the second region on the package substrate 110. The second region might not overlap with the first region. The buffer die 130 may be disposed on the package substrate in a y-axis direction. The buffer die 130 may be disposed on the package substrate 110 in a flip chip manner and may be electrically connected to signal transmission lines of the package substrate 110 through bumps 141. The buffer die 130 may be connected to a first data bus 101 and a second data bus 102. The first and second data buses 101 and 102 may be signal paths, channels, and/or links connecting the memory apparatus 100 to an external apparatus such as a memory controller or a processor. First data signals DQ<1:n> may be transmitted through the first data bus 101, and second data signals DQ<n+1:2n> may be transmitted through the second data bus 102. The first and second data buses 101 and 102 may each include n signal transmission lines, and n data signals may be transmitted at one time through each of the first and second data buses 101 and 102. The 2n data signals may each be serial data signals including the number of consecutive data bits defined by a burst length. The burst length may be a transmission length of data and may be information regarding the number of data bits continuously transmitted through one signal transmission line during one write operation and one read operation. The buffer die 130 may connect the first and second data buses 101 and 102 to the first to fourth memory dies 121-124. The buffer die 130 may be further connected to a chip selection bus 103 and may receive a chip selection signal through the chip selection bus 103. The buffer die 130 may connect the first data bus 101 to one of the first and second memory dies 121 and 122 and may connect the second data bus 102 to one of the third and fourth memory dies 123 and 124 based on the chip selection signal. For example, the chip selection signal may include a first chip selection signal CS1 and a second chip selection signal CS2. When the external apparatus asserts the first chip selection signal CS1, the first and third memory dies 121 and 123 may be accessed based on the first chip selection signal CS1. When the external apparatus asserts the second chip selection signal CS2, the second and fourth memory dies 122 and 124 may be accessed based on the second chip selection signal CS2. When the first chip selection signal CS1 is asserted, the buffer die 130 may connect the first data bus 101 to the first memory die 121 and may connect the second data bus 102 to the third memory die 123. When the second chip selection signal CS2 is asserted, the buffer die 130 may connect the first data bus 101 to the second memory die 122 and may connect the second data bus 102 to the fourth memory die 124.

The package substrate 110 may include first pads 111-1, second pads 111-2, third pads 111-3, and fourth pads 111-4. The first to fourth pads 111-1 to 111-4 may be formed on the package substrate 110. The first pads 111-1 and the second pads 111-2 may be provided on an upper surface of the package substrate 110 at distances spaced apart from the first memory die 121 in the first direction of an x-axis. The third pads 111-3 and the fourth pads 111-4 may be provided on the upper surface of the package substrate 110 at distances spaced apart from the first memory die 121 in the second direction of the x-axis. The package substrate 110 may include first signal transmission lines 112-1, second signal transmission lines 112-2, third signal transmission lines 112-3, and fourth signal transmission lines 112-4. The first to fourth signal transmission lines 112-1 to 112-4 may be wirings inside the package substrate 110 and may each include n lines. The first signal transmission lines 112-1 may connect the first pads 111-1 and the buffer die 130. The second signal transmission lines 112-2 may connect the second pads 111-2 and the buffer die 130. The third signal transmission lines 112-3 may connect the third pads 111-3 and the buffer die 130. The fourth signal transmission lines 112-4 may connect the fourth pads 111-4 and the buffer die 130. The package substrate 110 may include a plurality of package balls 142. The package substrate 110 may be respectively connected to the first data bus 101, the second data bus 102, and the chip selection bus 103 through the package balls 142. The package substrate 110 may further include fifth signal transmission lines 112-5, sixth signal transmission lines 112-6, and seventh signal transmission lines 112-7. The fifth to seventh signal transmission lines 112-5 to 112-7 may be wirings inside the package substrate 110. The fifth signal transmission lines 112-5 may connect the first data bus 101 and the buffer die 130, and the fifth signal transmission lines 112-5 may include n lines. The sixth signal transmission lines 112-6 may connect the second data bus 102 and the buffer die 130, and the sixth signal transmission lines 112-6 may include n lines. The seventh signal transmission lines 112-7 may connect the chip selection bus 103 and the buffer die 130, and the seventh signal transmission lines 112-7 may include the number of lines corresponding to the number of the chip selection signals. The buffer die 130 may be respectively connected to the first to seventh signal transmission lines 112-1 to 112-7 of the package substrate 110 through the bumps 141.

The first data pads 121-1 of the first memory die 121 may be connected to the first pads 111-1. The first data pads 121-1 of the first memory die 121 may be connected to the first pads 111-1 through first bonding wires 151-1. The number of the first bonding wires 151-1 may be n. The second data pads 121-2 of the first memory die 121 might not have an electrical connection with the package substrate 110. The first data pads 122-1 of the second memory die 122 may be connected to the second pads 111-2. The first data pads 122-1 of the second memory die 122 may be connected to the second pads 111-2 through second bonding wires 151-2. The number of the second bonding wires 151-2 may be n. The second data pads 122-2 of the second memory die 122 might not have an electrical connection with the package substrate 110. The second data pads 123-2 of the third memory die 123 may be connected to the third pads 111-3. The second data pads 123-2 of the third memory die 123 may be connected to the third pads 111-3 through third bonding wires 151-3. The number of the third bonding wires 151-3 may be n. The first data pads 123-1 of the third memory die 123 might not have an electrical connection with the package substrate 110. The second data pads 124-2 of the fourth memory die 124 may be connected to the fourth pads 111-4. The second data pads 124-2 of the fourth memory die 124 may be connected to the fourth pads 111-4 through fourth bonding wires 151-4. The number of the fourth bonding wires 151-4 may be n. The first data pads 124-1 of the fourth memory die 124 might not have an electrical connection with the package substrate 110.

The buffer die 130 may include a data control circuit 131. The data control circuit 131 may selectively connect the first data bus 101 to the first and second memory dies 121 and 122 by connecting the first data bus 101 to one of the first and second signal transmission lines 112-1 and 112-2 based on the chip selection signal. The data control circuit 131 may selectively connect the second data bus 102 to the third and fourth memory dies 123 and 124 by connecting the second data bus 102 to one of the third and fourth signal transmission lines 112-3 and 112-4 based on the chip selection signal. When the first chip selection signal CS1 is asserted, the data control circuit 131 may connect the first data bus 101 to the first signal transmission lines 112-1 and may connect the second data bus 102 to the third signal transmission lines 112-3. When the second chip selection signal CS2 is asserted, the data control circuit 131 may connect the first data bus 101 to the second signal transmission lines 112-2 and may connect the second data bus 102 to the fourth signal transmission lines 112-4.

The memory apparatus 100 may provide an expanded memory capacity by using two ranks and two chip selection signals. Because the external apparatus accesses the first and third memory dies 121 and 123 together based on the first chip selection signal CS1 and accesses the second and fourth memory dies 122 and 124 together based on the second chip selection signal CS2, four times a memory capacity may be utilized compared to when one memory die is accessed. For example, when the memory apparatus includes four memory dies, in the second byte mode, the first and second data signals DQ<1:n> and DQ<n+1:2n> may be stored in one memory die accessed by one chip selection signal. In contrast, in the first byte mode, two memory dies may be accessed by one chip selection signal, the first data signals DQ<1:n> may be stored in one memory die, and the second data signals DQ<n+1:2n> may be stored in another memory die, and thus, in the first byte mode, a memory capacity of the memory apparatus may be twice a memory capacity of the memory apparatus in the second byte mode. However, because two memory dies assigned different chip selection signals are connected in common to one data bus, a capacitive load of the data bus may be increased by two times. Although FIG. 2 illustrates a structure in which four memory dies constitute two ranks, the number of memory dies included in the memory apparatus may be increased to 8, 12, or 16, and the number of ranks may also be increased to 4, 6, or 8. In this case, because one data bus is connected to a capacitive load corresponding to 4, 6, or 8 memory dies, a transmission speed of the data bus and/or a data bandwidth may decrease, and integrity of data signals transmitted through the data bus may be degraded. The buffer die 130 may improve a data bandwidth of the first and second data buses 101 and 102 and improve integrity of data signals while increasing a memory capacity of the memory apparatus 100 by allowing one data bus to be connected to a capacitive load corresponding to one memory die based on a chip selection signal.

In an embodiment of the present disclosure, because the first to fourth signal transmission lines 112-1 to 112-4 are respectively connected to a capacitive load corresponding to one memory die, stable signal transmission may be possible even when a voltage swing of signals transmitted through the first to fourth signal transmission lines 112-1 to 112-4 is reduced. Accordingly, power consumption of the memory apparatus 100 may be reduced by using Dynamic Voltage Frequency Scaling (DVFS) technology. A voltage swing of signals transmitted between the buffer die 130 and the first to fourth memory dies 121 to 124 may be smaller than a voltage swing of signals transmitted between the buffer die 130 and the external apparatus. For example, amplitudes of data signals transmitted through the first to fourth signal transmission lines 112-1 to 112-4 may be smaller than amplitudes of data signals transmitted through the first and second data buses 101 and 102. The buffer die 130 may reduce a voltage swing of data signals transmitted through the first to fourth signal transmission lines 112-1 to 112-4 by down-converting voltage levels of data signals received through the first and second data buses 101 and 102. The buffer die 130 may increase a voltage swing of data signals transmitted through the first and second data buses 101 and 102 by up-converting voltage levels of data signals received through the first to fourth signal transmission lines 112-1 to 112-4.

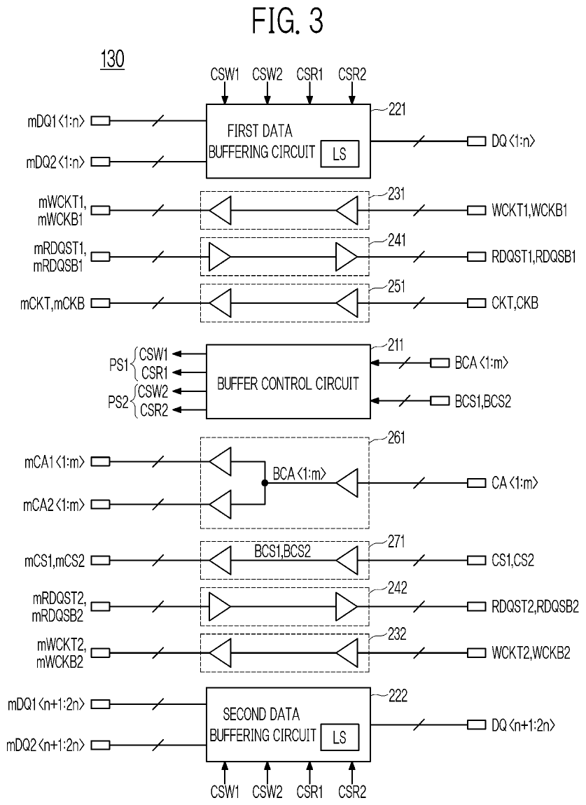

FIG. 3 is a diagram illustrating a configuration of the buffer die 130 shown in FIG. 2. Referring to FIG. 3, the buffer die 130 may include a buffer control circuit 211, a first data buffering circuit 221, and a second data buffering circuit 222. The buffer control circuit 211, the first data buffering circuit 221, and the second data buffering circuit 222 may constitute the data control circuit 131 shown in FIG. 2. The buffer control circuit 211 may generate a first path selection signal PS1 and a second path selection signal PS2 based on a command address signal CA<1:m> and a chip selection signal. Here, m may be an integer greater than or equal to 2. The buffer control circuit 211 may receive a buffered command address signal BCA<1:m> generated by buffering the command address signal CA<1:m> and a first buffered chip selection signal BCS1 and a second buffered chip selection signal BCS2 generated by buffering the first and second chip selection signals CS1 and CS2, and may generate the first and second path selection signals PS1 and PS2. The buffer control circuit 211 may enable the first path selection signal PS1 when the first chip selection signal CS1 is asserted. The buffer control circuit 211 may enable the second path selection signal PS2 when the second chip selection signal CS2 is asserted. The command address signal CA<1:m> may include a write command and a read command. The first path selection signal PS1 may include a first write path signal CSW1 and a first read path signal CSR1, and the second path selection signal PS2 may include a second write path signal CSW2 and a second read path signal CSR2. The write command may indicate a write operation in which data signals are transmitted from an external apparatus to the memory apparatus 100, and the read command may indicate a read operation in which data signals are transmitted from the memory apparatus 100 to the external apparatus. When the command address signal CA<1:m> includes the write command, the buffer control circuit 211 may enable one of the first and second write path signals CSW1 and CSW2 based on the first and second chip selection signals CS1 and CS2. The buffer control circuit 211 may enable the first write path signal CSW1 when the write command and the first chip selection signal CS1 are asserted. The buffer control circuit 211 may enable the second write path signal CSW2 when the write command and the second chip selection signal CS2 are asserted. When the command address signal CA<1:m> includes the read command, the buffer control circuit 211 may enable one of the first and second read path signals CSR1 and CSR2 based on the first and second chip selection signals CS1 and CS2. The buffer control circuit 211 may enable the first read path signal CSR1 when the read command and the first chip selection signal CS1 are asserted. The buffer control circuit 211 may enable the second read path signal CSR2 when the read command and the second chip selection signal CS2 are asserted.

In FIG. 3, signals transmitted between the buffer die 130 and the external apparatus may have characteristics identical to those of signals transmitted between the buffer die 130 and memory dies, but for clarity of description, “memory” is additionally added to names of signals transmitted between the buffer die 130 and the memory dies, and “m” is additionally added to reference numerals. The first data buffering circuit 221 may receive the first and second path selection signals PS1 and PS2 from the buffer control circuit 211. The first data buffering circuit 221 may be connected to the first data bus 101, the first memory die 121, and the second memory die 122. The first data buffering circuit 221 may be connected to the first memory die 121 through the first signal transmission lines 112-1 and may be connected to the second memory die 122 through the second signal transmission lines 112-2. When the first path selection signal PS1 is enabled, the first data buffering circuit 221 may connect the first data bus 101 to the first memory die 121. When the second path selection signal PS2 is enabled, the first data buffering circuit 221 may connect the first data bus 101 to the second memory die 122. The first data signals DQ<1:n> may be propagated through the first data bus 101, first memory data signals mDQ1<1:n> may be propagated through the first signal transmission lines 112-1, and second memory data signals mDQ2<1:n> may be propagated through the second signal transmission lines 112-2. When the first write path signal CSW1 is enabled, the first data buffering circuit 221 may receive the first data signals DQ<1:n> transmitted from the external apparatus through the first data bus 101 and may transmit the first data signals DQ<1:n> as the first memory data signals mDQ1<1:n> to the first signal transmission lines 112-1 and the first memory die 121. When the second write path signal CSW2 is enabled, the first data buffering circuit 221 may receive the first data signals DQ<1:n> transmitted from the external apparatus through the first data bus 101 and may transmit the first data signals DQ<1:n> as the second memory data signals mDQ2<1:n> to the second signal transmission lines 112-2 and the second memory die 122. When the first read path signal CSR1 is enabled, the first data buffering circuit 221 may receive the first memory data signals mDQ1<1:n> from the first memory die 121 and the first signal transmission lines 112-1 and may output the first memory data signals mDQ1<1:n> as the first data signals DQ<1:n> to the external apparatus through the first data bus 101. When the second read path signal CSR2 is enabled, the first data buffering circuit 221 may receive the second memory data signals mDQ2<1:n> from the second memory die 122 and the second signal transmission lines 112-2 and may output the second memory data signals mDQ2<1:n> as the first data signals DQ<1:n> to the external apparatus through the first data bus 101. In an embodiment, the first data buffering circuit 221 may further include a level shifting circuit LS. The level shifting circuit LS of the first data buffering circuit 221 may down-convert voltage levels of the first data signals DQ<1:n> during a write operation to generate the first and second memory data signals mDQ1<1:n> and mDQ2<1:n> having voltage swings smaller than those of the first data signals DQ<1:n>. The level shifting circuit LS of the first data buffering circuit 221 may up-convert voltage levels of the first and second memory data signals mDQ1<1:n> and mDQ2<1:n> during a read operation to generate the first data signals DQ<1:n> having voltage swings larger than those of the first and second memory data signals mDQ1<1:n> and mDQ2<1:n>.

The second data buffering circuit 222 may receive the first and second path selection signals PS1 and PS2 from the buffer control circuit 211. The second data buffering circuit 222 may be connected to the second data bus 102, the third memory die 123, and the fourth memory die 124. The second data buffering circuit 222 may be connected to the third memory die 123 through the third signal transmission lines 112-3 and may be connected to the fourth memory die 124 through the fourth signal transmission lines 112-4. When the first path selection signal PS1 is enabled, the second data buffering circuit 222 may connect the second data bus 102 to the third memory die 123. When the second path selection signal PS2 is enabled, the second data buffering circuit 222 may connect the second data bus 102 to the fourth memory die 124. Second data signals DQ<n+1:2n> may be propagated through the second data bus 102, third memory data signals mDQ1<n+1:2n> may be propagated through the third signal transmission lines 112-3, and fourth memory data signals mDQ2<n+1:2n> may be propagated through the fourth signal transmission lines 112-4. When the first write path signal CSW1 is enabled, the second data buffering circuit 222 may receive the second data signals DQ<n+1:2n> transmitted from the external apparatus through the second data bus 102 and may transmit the second data signals DQ<n+1:2n> as the third memory data signals mDQ1<n+1:2n> to the third signal transmission lines 112-3 and the third memory die 123. When the second write path signal CSW2 is enabled, the second data buffering circuit 222 may receive the second data signals DQ<n+1:2n> transmitted from the external apparatus through the second data bus 102 and may transmit the second data signals DQ<n+1:2n> the fourth memory data signals mDQ2<n+1:2n> to the fourth signal transmission lines 112-4 and the fourth memory die 124. When the first read path signal CSR1 is enabled, the second data buffering circuit 222 may receive the third memory data signals mDQ1<n+1:2n> transmitted from the third memory die 123 and the third signal transmission lines 112-3 and may output the third memory data signals mDQ1<n+1:2n> as the second data signals DQ<n+1:2n> to the external apparatus through the second data bus 102. When the second read path signal CSR2 is enabled, the second data buffering circuit 222 may receive the fourth memory data signals mDQ2<n+1:2n> transmitted from the fourth memory die 124 and the fourth signal transmission lines 112-4 and may output the fourth memory data signals mDQ2<n+1:2n> as the second data signals DQ<n+1:2n> to the external apparatus through the second data bus 102. In an embodiment, the second data buffering circuit 222 may further include a level shifting circuit LS. The level shifting circuit LS of the second data buffering circuit 222 may down-convert voltage levels of the second data signals DQ<n+1:2n> during a write operation to generate the third and fourth memory data signals mDQ1<n+1:2n> and mDQ2<n+1:2n> having voltage swings smaller than those of the second data signals DQ<n+1:2n>. The level shifting circuit LS of the second data buffering circuit 222 may up-convert voltage levels of the third and fourth memory data signals mDQ1<n+1:2n> and mDQ2<n+1:2n> during a read operation to generate the second data signals DQ<n+1:2n> having voltage swings larger than those of the third and fourth memory data signals mDQ1<n+1:2n> and mDQ2<n+1:2n>.

The buffer die 130 may further include a plurality of buffer circuits. The buffer die 130 may further include a first data clock buffer circuit 231, a first read strobe buffer circuit 241, a system clock buffer circuit 251, a command address buffer circuit 261, a chip selection buffer circuit 271, a second data clock buffer circuit 232, and a second read strobe buffer circuit 242. The components of the buffer die 130 are merely illustrative, and the buffer die 130 may include any other components not illustrated in FIG. 3 in order to interface signals required for operation of the memory apparatus 100. The first data clock buffer circuit 231 may receive a first data clock signal WCKT1 and a first complementary data clock signal WCKB1 from an external apparatus and may buffer the first data clock signal WCKT1 and the first complementary data clock signal WCKB1. The first data clock buffer circuit 231 may output the buffered first data clock signal WCKT1 and the buffered first complementary data clock signal WCKB1 as a first memory data clock signal mWCKT1 and a first complementary memory data clock signal mWCKB1. The first data clock buffer circuit 231 may be connected in common to the first and second memory dies 121 and 122 and may provide the first memory data clock signal pair mWCKT1 and mWCKB1 to the first and second memory dies 121 and 122 in common. The first and second memory dies 121 and 122 may perform data input/output operations in synchronization with the first memory data clock signal pair mWCKT1 and mWCKB1.

The first read strobe buffer circuit 241 may receive a first memory read strobe signal mRDQST1 and a first complementary memory read strobe signal mRDQSB1 from the first and second memory dies 121 and 122. The first memory read strobe signal pair mRDQST1 and mRDQSB1 may be generated based on the first memory data clock signal pair mWCKT1 and mWCKB1 and may be synchronized with a timing at which first and second memory data signals mDQ1<1:n> and mDQ2<1:n> are output from the first and second memory dies 121 and 122. The first read strobe buffer circuit 241 may buffer the first memory read strobe signal pair mRDQST1 and mRDQSB1 and may output a first read strobe signal RDQST1 and a first complementary read strobe signal RDQSB1 to the external apparatus. When the first chip selection signal CS1 is asserted, the first read strobe buffer circuit 241 may receive the first memory read strobe signal mRDQST1 and the first complementary memory read strobe signal mRDQSB1 from the first memory die 121 and may buffer the first memory read strobe signal pair mRDQST1 and mRDQSB1. The first read strobe buffer circuit 241 may output the buffered first memory read strobe signal mRDQST1 as the first read strobe signal RDQST1 and may output the buffered first complementary memory read strobe signal mRDQSB1 as the first complementary read strobe signal RDQSB1. When the second chip selection signal CS2 is asserted, the first read strobe buffer circuit 241 may receive the first memory read strobe signal mRDQST1 and the first complementary memory read strobe signal mRDQSB1 from the second memory die 122 and may buffer the first memory read strobe signal pair mRDQST1 and mRDQSB1. The first read strobe buffer circuit 241 may output the buffered first memory read strobe signal mRDQST1 as the first read strobe signal RDQST1 and may output the buffered first complementary memory read strobe signal mRDQSB1 as the first complementary read strobe signal RDQSB1.

The system clock buffer circuit 251 may receive a system clock signal CKT and a complementary system clock signal CKB from the external apparatus and may buffer the system clock signal pair CKT and CKB. The system clock buffer circuit 251 may output the buffered system clock signal CKT as a memory system clock signal mCKT and may output the buffered complementary system clock signal CKB as a complementary memory system clock signal mCKB. The system clock buffer circuit 251 may be connected in common to the first to fourth memory dies 121 to 124 and may provide the memory system clock signal pair mCKT and mCKB to the first to fourth memory dies 121 to 124 in common.

The command address buffer circuit 261 may receive the command address signal CA<1:m> from the external apparatus and may buffer the command address signal CA<1:m> to generate the buffered command address signal BCA<1:m>. The command address buffer circuit 261 may output the buffered command address signal BCA<1:m> as a first memory command address signal mCA1<1:m> and a second memory command address signal mCA2<1:m>. The buffered command address signal BCA<1:m> may be provided to the buffer control circuit 211. The first and second memory dies 121 and 122 may receive the first memory command address signal mCA1<1:m> in common, and the third and fourth memory dies 123 and 124 may receive the second memory command address signal mCA2<1:m> in common. The command address signal CA<1:m> may be synchronized with the system clock signal pair CKT and CKB. The first and second memory dies 121 and 122 may receive the first memory command address signal mCA1<1:m> in synchronization with the memory system clock signal pair mCKT and mCKB, and the third and fourth memory dies 123 and 124 may receive the second memory command address signal mCA2<1:m> in synchronization with the memory system clock signal pair mCKT and mCKB.

The chip selection buffer circuit 271 may receive the first chip selection signal CS1 and the second chip selection signal CS2 from the external apparatus. The chip selection buffer circuit 271 may buffer the first and second chip selection signals CS1 and CS2 to generate a first buffered chip selection signal BCS1 and a second buffered chip selection signal BCS2. The chip selection buffer circuit 271 may output the first buffered chip selection signal BCS1 as a first memory chip selection signal mCS1 and may output the second buffered chip selection signal BCS2 as a second memory chip selection signal mCS2. The first and third memory dies 121 and 123 may receive the first memory chip selection signal mCS1 in common because the first chip selection signal CS1 is assigned thereto. The second and fourth memory dies 122 and 124 may receive the second memory chip selection signal mCS2 in common because the second chip selection signal CS2 is assigned thereto. The first buffered chip selection signal BCS1 and the second buffered chip selection signal BCS2 may be provided to the buffer control circuit 211.

The second data clock buffer circuit 232 may receive a second data clock signal WCKT2 and a second complementary data clock signal WCKB2 from the external apparatus and may buffer the second data clock signal WCKT2 and the second complementary data clock signal WCKB2. The second data clock signal pair WCKT2 and WCKB2 may be independent of the first data clock signal pair WCKT1 and WCKB1 and may have the same timing as each other, but may have different timings. The second data clock buffer circuit 232 may output the buffered second data clock signal WCKT2 and the buffered second complementary data clock signal WCKB2 as a second memory data clock signal mWCKT2 and a second complementary memory data clock signal mWCKB2. The second data clock buffer circuit 232 may be connected in common to the third and fourth memory dies 123 and 124 and may provide the second memory data clock signal mWCKT2 and the second complementary memory data clock signal mWCKB2 to the third and fourth memory dies 123 and 124 in common. The third and fourth memory dies 123 and 124 may perform data input/output operations in synchronization with the second memory data clock signal mWCKT2 and the second complementary memory data clock signal mWCKB2.

The second read strobe buffer circuit 242 may receive a second memory read strobe signal mRDQST2 and a second complementary memory read strobe signal mRDQSB2 from the third memory die 123 and the fourth memory die 124. The second memory read strobe signal pair mRDQST2 and mRDQSB2 may be generated based on the second memory data clock signal pair mWCKT2 and mWCKB2 and may be synchronized with timings at which third and fourth memory data signals mDQ1<n+1:2n> and mDQ2<n+1:2n> are output from the third and fourth memory dies 123 and 124, respectively. The second read strobe buffer circuit 242 may buffer the second memory read strobe signal pair mRDQST2 and mRDQSB2 and may output a second read strobe signal RDQST2 and a second complementary read strobe signal RDQSB2 to the external apparatus. When the first chip selection signal CS1 is asserted, the second read strobe buffer circuit 242 may receive the second memory read strobe signal mRDQST2 and the second complementary memory read strobe signal mRDQSB2 from the third memory die 123 and may buffer the second memory read strobe signal pair mRDQST2 and mRDQSB2. The second read strobe buffer circuit 242 may output the buffered second memory read strobe signal mRDQST2 as the second read strobe signal RDQST2 and may output the buffered second complementary memory read strobe signal mRDQSB2 as the second complementary read strobe signal RDQSB2. When the second chip selection signal CS2 is asserted, the second read strobe buffer circuit 242 may receive the second memory read strobe signal mRDQST2 and the second complementary memory read strobe signal mRDQSB2 from the fourth memory die 124 and may buffer the second memory read strobe signal pair mRDQST2 and mRDQSB2. The second read strobe buffer circuit 242 may output the buffered second memory read strobe signal mRDQST2 as the second read strobe signal RDQST2 and may output the buffered second complementary memory read strobe signal mRDQSB2 as the second complementary read strobe signal RDQSB2.

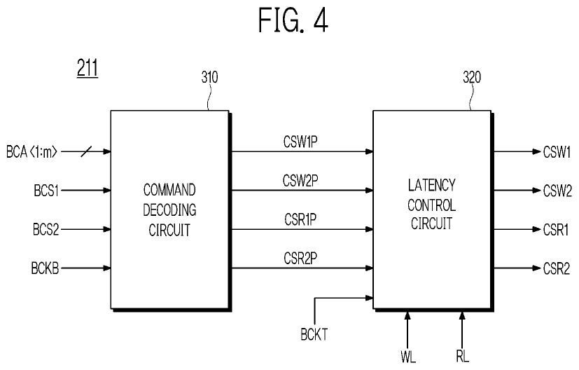

FIG. 4 is a diagram illustrating a configuration of the buffer control circuit 211 illustrated in FIG. 3. Referring to FIG. 4, the buffer control circuit 211 may include a command decoding circuit 310 and a latency control circuit 320. The command decoding circuit 310 may receive the buffered command address signal BCA<1:m>, the first buffered chip selection signal BCS1, and the second buffered chip selection signal BCS2. The command decoding circuit 310 may generate a first preliminary write path signal CSW1P, a second preliminary write path signal CSW2P, a first preliminary read path signal CSR1P, and a second preliminary read path signal CSR2P based on the buffered command address signal BCA<1:m>, the first buffered chip selection signal BCS1, and the second buffered chip selection signal BCS2. When the buffered command address signal BCA<1:m> includes a write command, the command decoding circuit 310 may enable one of the first and second preliminary write path signals CSW1P and CSW2P according to the first and second buffered chip selection signals BCS1 and BCS2. When the first buffered chip selection signal BCS1 is asserted, the command decoding circuit 310 may enable the first preliminary write path signal CSW1P. When the second buffered chip selection signal BCS2 is asserted, the command decoding circuit 310 may enable the second preliminary write path signal CSW2P. When the buffered command address signal BCA<1:m> includes a read command, the command decoding circuit 310 may enable one of the first and second preliminary read path signals CSR1P and CSR2P according to the first and second buffered chip selection signals BCS1 and BCS2. When the first buffered chip selection signal BCS1 is asserted, the command decoding circuit 310 may enable the first preliminary read path signal CSR1P. When the second buffered chip selection signal BCS2 is asserted, the command decoding circuit 310 may enable the second preliminary read path signal CSR2P. The command decoding circuit 310 may receive a buffered complementary system clock signal BCKB generated by buffering the complementary system clock signal CKB by the system clock buffer circuit 251 illustrated in FIG. 3 and may output the first preliminary write path signal CSW1P, the second preliminary write path signal CSW2P, the first preliminary read path signal CSR1P, and the second preliminary read path signal CSR2P in synchronization with the buffered complementary system clock signal BCKB.

The latency control circuit 320 may receive the first preliminary write path signal CSW1P, the second preliminary write path signal CSW2P, the first preliminary read path signal CSR1P, and the second preliminary read path signal CSR2P, and may generate the first write path signal CSW1, the second write path signal CSW2, the first read path signal CSR1, and the second read path signal CSR2. The latency control circuit 320 may receive a write latency signal WL and a read latency signal RL. The write latency signal WL may include information about a write latency, and the read latency signal RL may include information about a read latency. The write latency may indicate a time interval from when the command address signal CA<1:m> including the write command is provided from the external apparatus until data signals are input from the external apparatus to the memory apparatus 100. The read latency may indicate a time interval from when the command address signal CA<1:m> including the read command is provided from the external apparatus until data signals are output from the memory apparatus 100. The write latency included in the write latency signal WL and the read latency included in the read latency signal RL received by the latency control circuit 320 may differ from an actual write latency and an actual read latency of the memory apparatus 100, for example, may be shorter, and may be variously adjusted to secure a sufficient margin for data signals provided from the external apparatus or the memory apparatus 100 to be output to the memory apparatus 100 or the external apparatus. The write latency and the read latency may be defined as multiples of cycles of the system clock signal CKT. The latency control circuit 320 may generate the first write path signal CSW1 by delaying the first preliminary write path signal CSW1P by a time corresponding to the write latency. The latency control circuit 320 may generate the second write path signal CSW2 by delaying the second preliminary write path signal CSW2P by a time corresponding to the write latency. The latency control circuit 320 may generate the first read path signal CSR1 by delaying the first preliminary read path signal CSR1P by a time corresponding to the read latency. The latency control circuit 320 may generate the second read path signal CSR2 by delaying the second preliminary read path signal CSR2P by a time corresponding to the read latency. The latency control circuit 320 may further receive a buffered system clock signal BCKT generated by buffering the system clock signal CKT by the system clock buffer circuit 251. The latency control circuit 320 may generate the first and second write path signals CSW1 and CSW2 by delaying the first and second preliminary write path signals CSW1P and CSW2P by a time corresponding to the write latency in synchronization with the buffered system clock signal BCKT. Likewise, the latency control circuit 320 may generate the first and second read path signals CSR1 and CSR2 by delaying the first and second preliminary read path signals CSR1P and CSR2P by a time corresponding to the read latency in synchronization with the buffered system clock signal BCKT. The latency control circuit 320 may adjust pulse widths of the first and second write path signals CSW1 and CSW2 and the first and second read path signals CSR1 and CSR2 according to a burst length of the memory apparatus 100. The latency control circuit 320 may generate the first and second write path signals CSW1 and CSW2 and the first and second read path signals CSR1 and CSR2 having pulse widths wider than pulse widths corresponding to the burst length.

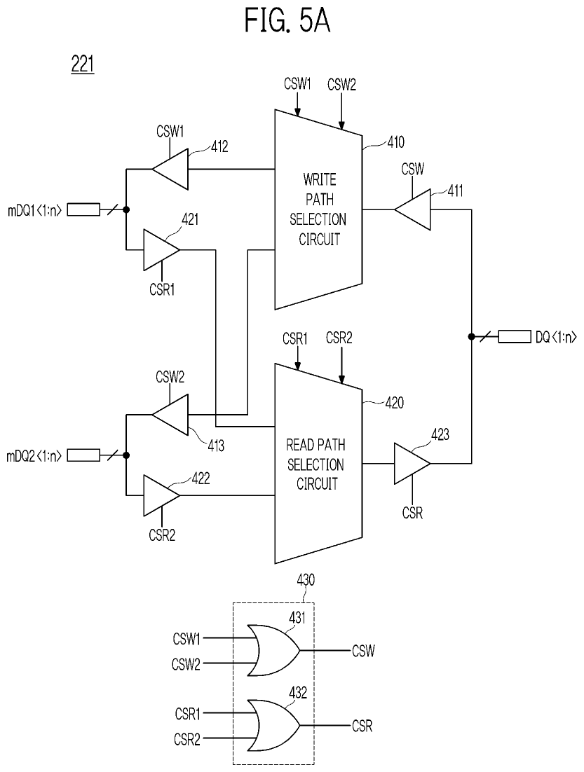

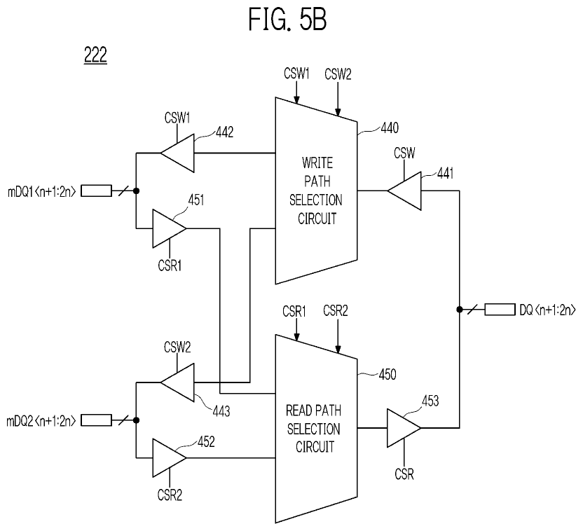

FIG. 5A is a diagram illustrating a configuration of the first data buffering circuit 221 shown in FIG. 3. Referring to FIG. 5A, the first data buffering circuit 221 may include a write path selection circuit 410 and a read path selection circuit 420. The write path selection circuit 410 may be connected between the first data bus 101, the first signal transmission lines 112-1, and the second signal transmission lines 112-2, and may receive the first and second write path signals CSW1 and CSW2. When the first write path signal CSW1 is enabled, the write path selection circuit 410 may output the first data signals DQ<1:n> received through the first data bus 101 as the first memory data signals mDQ1<1:n> to the first signal transmission lines 112-1 and the first memory die 121. When the second write path signal CSW2 is enabled, the write path selection circuit 410 may output the first data signals DQ<1:n> received through the first data bus 101 as the second memory data signals mDQ2<1:n> to the second signal transmission lines 112-2 and the second memory die 122.

The read path selection circuit 420 may be connected between the first data bus 101, the first signal transmission lines 112-1, and the second signal transmission lines 112-2, and may receive the first and second read path signals CSR1 and CSR2. When the first read path signal CSR1 is enabled, the read path selection circuit 420 may output the first memory data signals mDQ1<1:n> transmitted from the first memory die 121 and the first signal transmission lines 112-1 as the first data signals DQ<1:n> to the first data bus 101. When the second read path signal CSR2 is enabled, the read path selection circuit 420 may output the second memory data signals mDQ2<1:n> transmitted from the second memory die 122 and the second signal transmission lines 112-2 as the first data signals DQ<1:n> to the first data bus 101.

The first data buffering circuit 221 may include a first buffer 411, a second buffer 412, a third buffer 413, a fourth buffer 421, a fifth buffer 422, and a sixth buffer 423. The first buffer 411 may buffer the first data signals DQ<1:n> and provide buffered signals to the write path selection circuit 410. The second buffer 412 may buffer output signals of the write path selection circuit 410 and output buffered signals to the first signal transmission lines 112-1 as the first memory data signals mDQ1<1:n>. The third buffer 413 may buffer output signals of the write path selection circuit 410 and output buffered signals to the second signal transmission lines 112-2 as the second memory data signals mDQ2<1:n>. The fourth buffer 421 may buffer the first memory data signals mDQ1<1:n> and output buffered signals to the read path selection circuit 420. The fifth buffer 422 may buffer the second memory data signals mDQ2<1:n> and output buffered signals to the read path selection circuit 420. The sixth buffer 423 may buffer output signals of the read path selection circuit 420 and output buffered signals to the first data bus 101 as the first data signals DQ<1:n>.

The first data buffering circuit 221 may further include a gating circuit 430, and may control activation of the first to sixth buffers 411, 412, 413, 421, 422, and 423. The gating circuit 430 may receive the first and second write path signals CSW1 and CSW2, and may enable a write buffer signal CSW when one of the first and second write path signals CSW1 and CSW2 is enabled. The gating circuit 430 may receive the first and second read path signals CSR1 and CSR2, and may enable a read buffer signal CSR when one of the first and second read path signals CSR1 and CSR2 is enabled. The gating circuit 430 may include a first OR gate 431 and a second OR gate 432. The first OR gate 431 may perform an OR operation on the first and second write path signals CSW1 and CSW2 to output the write buffer signal CSW. The second OR gate 432 may perform an OR operation on the first and second read path signals CSR1 and CSR2 to output the read buffer signal CSR. The first buffer 411 may receive the write buffer signal CSW and may be activated when the write buffer signal CSW is enabled. The second buffer 412 may receive the first write path signal CSW1 and may be activated when the first write path signal CSW1 is enabled. The third buffer 413 may receive the second write path signal CSW2 and may be activated when the second write path signal CSW2 is enabled. The fourth buffer 421 may receive the first read path signal CSR1 and may be activated when the first read path signal CSR1 is enabled. The fifth buffer 422 may receive the second read path signal CSR2 and may be activated when the second read path signal CSR2 is enabled. The sixth buffer 423 may receive the read buffer signal CSR and may be activated when the read buffer signal CSR is enabled.

FIG. 5B is a diagram illustrating a configuration of the second data buffering circuit 222 illustrated in FIG. 3. Referring to FIG. 5B, the second data buffering circuit 222 may include a write path selection circuit 440 and a read path selection circuit 450. The write path selection circuit 440 may be connected between the second data bus 102, the third signal transmission lines 112-3, and the fourth signal transmission lines 112-4, and may receive the first and second write path signals CSW1 and CSW2. When the first write path signal CSW1 is enabled, the write path selection circuit 440 may output the second data signals DQ<n+1:2n> received through the second data bus 102 to the third signal transmission lines 112-3 and the third memory die 123 as the third memory data signals mDQ1<n+1:2n>. When the second write path signal CSW2 is enabled, the write path selection circuit 440 may output the second data signals DQ<n+1:2n> received through the second data bus 102 to the fourth signal transmission lines 112-4 and the fourth memory die 124 as the fourth memory data signals mDQ2<n+1:2n>.

The read path selection circuit 450 may be connected between the second data bus 102, the third signal transmission lines 112-3, and the fourth signal transmission lines 112-4, and may receive the first and second read path signals CSR1 and CSR2. When the first read path signal CSR1 is enabled, the read path selection circuit 450 may output the third memory data signals mDQ1<n+1:2n> transmitted from the third memory die 123 and the third signal transmission lines 112-3 to the second data bus 102 as the second data signals DQ<n+1:2n>. When the second read path signal CSR2 is enabled, the read path selection circuit 450 may output the fourth memory data signals mDQ2<n+1:2n> transmitted from the fourth memory die 124 and the fourth signal transmission lines 112-4 to the second data bus 102 as the second data signals DQ<n+1:2n>.

The second data buffering circuit 222 may include a first buffer 441, a second buffer 442, a third buffer 443, a fourth buffer 451, a fifth buffer 452, and a sixth buffer 453. The first buffer 441 may buffer the second data signals DQ<n+1:2n> and may provide buffered signals to the write path selection circuit 440. The second buffer 442 may buffer output signals of the write path selection circuit 440 and may output the buffered signals to the third signal transmission lines 112-3 as the third memory data signals mDQ1<n+1:2n>. The third buffer 443 may buffer the output signals of the write path selection circuit 440 and may output the buffered signals to the fourth signal transmission lines 112-4 as the fourth memory data signals mDQ2<n+1:2n>. The fourth buffer 451 may buffer the third memory data signals mDQ1<n+1:2n> and may output buffered signals to the read path selection circuit 450. The fifth buffer 452 may buffer the fourth memory data signals mDQ2<n+1:2n> and may output buffered signals to the read path selection circuit 450. The sixth buffer 453 may buffer output signals of the read path selection circuit 450 and may output the buffered signals to the second data bus 102 as the second data signals DQ<n+1:2n>.

The first buffer 441 may receive the write buffer signal CSW and may be activated when the write buffer signal CSW is enabled. The second buffer 442 may receive the first write path signal CSW1 and may be activated when the first write path signal CSW1 is enabled. The third buffer 443 may receive the second write path signal CSW2 and may be activated when the second write path signal CSW2 is enabled. The fourth buffer 451 may receive the first read path signal CSR1 and may be activated when the first read path signal CSR1 is enabled. The fifth buffer 452 may receive the second read path signal CSR2 and may be activated when the second read path signal CSR2 is enabled. The sixth buffer 453 may receive the read buffer signal CSR and may be activated when the read buffer signal CSR is enabled.

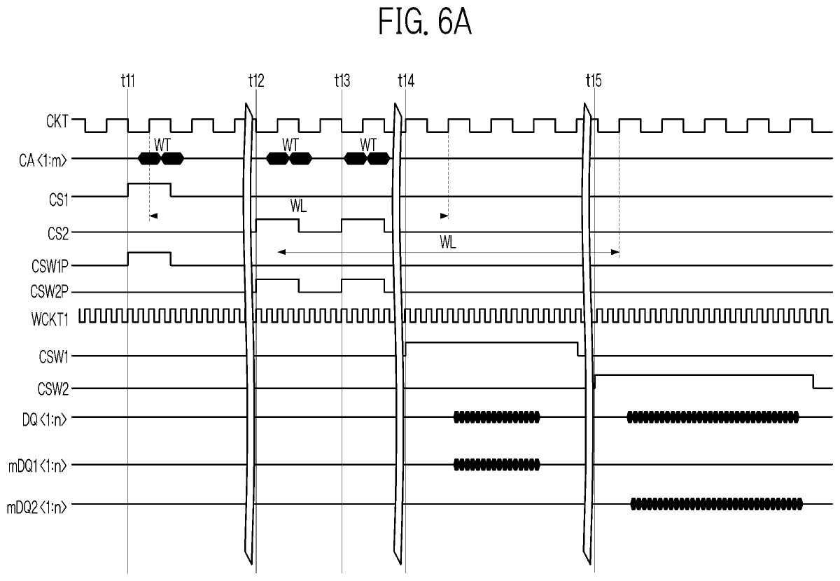

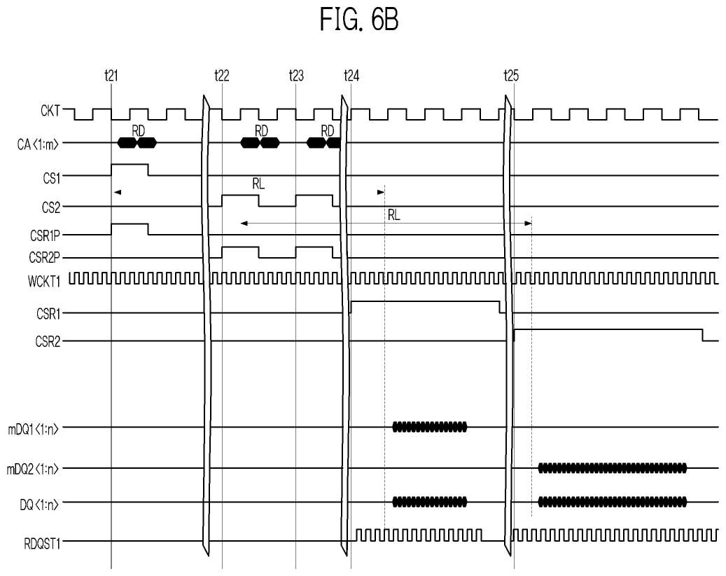

FIG. 6A is a timing diagram illustrating an operation of the buffer die 130 during a write operation according to an embodiment of the present disclosure. The buffer die 130 may receive, at a time point t11, in synchronization with the system clock signal CKT, the first chip selection signal CS1 and the command address signal CA<1:m> including the write command WT. The command decoding circuit 310 of the buffer control circuit 211 may enable the first preliminary write path signal CSW1P. The buffer die 130 may receive, at a time point t12, in synchronization with the system clock signal CKT, the second chip selection signal CS2 and the command address signal CA<1:m> including the write command WT. The command decoding circuit 310 of the buffer control circuit 211 may enable the second preliminary write path signal CSW2P. The buffer die 130 may receive, at a time point t13, the second chip selection signal CS2 and the command address signal CA<1:m> including the write command WT consecutively. The command decoding circuit 310 of the buffer control circuit 211 may enable the second preliminary write path signal CSW2P.

The latency control circuit 320 of the buffer control circuit 211 may delay the first preliminary write path signal CSW1P generated at the time point t11 by a time corresponding to the write latency and may enable the first write path signal CSW1 at a time point t14. The buffer die 130 may receive, after the time point t14, through the first data bus 101, the first data signals DQ<1:n> synchronized with the first data clock signal WCKT1. The first data buffering circuit 221 may transmit the first data signals DQ<1:n> to the first memory die 121 as the first memory data signals mDQ1<1:n> based on the first write path signal CSW1. The first memory die 121 may receive the first memory data signals mDQ1<1:n> and may store the first memory data signals mDQ1<1:n> in memory banks of the first memory die 121. Although not illustrated, the buffer die 130 may receive, after the time point t14, through the second data bus 102, the second data signals DQ<n+1:2n> synchronized with the second data clock signal WCKT2. The second data buffering circuit 222 may transmit the second data signals DQ<n+1:2n> to the third memory die 123 as the third memory data signals mDQ1<n+1:2n> based on the first write path signal CSW1. The third memory die 123 may receive the third memory data signals mDQ1<n+1:2n> and may store the third memory data signals mDQ1<n+1:2n> in memory banks of the third memory die 123.

The latency control circuit 320 of the buffer control circuit 211 may delay the second preliminary write path signal CSW2P generated at the time points t12 and t13 by a time corresponding to the write latency, respectively, and may enable the second write path signal CSW2 at a time point t15. Because the second preliminary write path signal CSW2P is continuously enabled, the latency control circuit 320 may generate the second write path signal CSW2 having a pulse width wider than a pulse width corresponding to twice the burst length. The buffer die 130 may receive, after the time point t15, through the first data bus 101, the first data signals DQ<1:n> synchronized with the first data clock signal WCKT1. The first data buffering circuit 221 may transmit the first data signals DQ<1:n> to the second memory die 122 as the second memory data signals mDQ2<1:n> based on the second write path signal CSW2. The second memory die 122 may receive the second memory data signals mDQ2<1:n> and may store the second memory data signals mDQ2<1:n> in memory banks of the second memory die 122. Although not illustrated, the buffer die 130 may receive, after the time point t15, through the second data bus 102, the second data signals DQ<n+1:2n> synchronized with the second data clock signal WCKT2. The second data buffering circuit 222 may transmit the second data signals DQ<n+1:2n> to the fourth memory die 124 as the fourth memory data signals mDQ2<n+1:2n> based on the second write path signal CSW2. The fourth memory die 124 may receive the fourth memory data signals mDQ2<n+1:2n> and may store the fourth memory data signals mDQ2<n+1:2n> in memory banks of the fourth memory die 124.

FIG. 6B is a timing diagram illustrating an operation of another buffer die 130 during a read operation according to an embodiment of the present disclosure. The buffer die 130 may receive, at a time point t21, in synchronization with the system clock signal CKT, the first chip selection signal CS1 and the command address signal CA<1:m> including a read command RD. The command decoding circuit 310 of the buffer control circuit 211 may enable the first preliminary read path signal CSR1P. The buffer die 130 may receive, at a time point t22, in synchronization with the system clock signal CKT, the second chip selection signal CS2 and the command address signal CA<1:m> including the read command RD. The command decoding circuit 310 of the buffer control circuit 211 may enable the second preliminary read path signal CSR2P. The buffer die 130 may receive, at a time point t23, the second chip selection signal CS2 and the command address signal CA<1:m> including the read command RD consecutively. The command decoding circuit 310 of the buffer control circuit 211 may enable the second preliminary read path signal CSR2P.

The latency control circuit 320 of the buffer control circuit 211 may delay the first preliminary read path signal CSR1P generated at the time point t21 by a time corresponding to the read latency and may enable the first read path signal CSR1 at a time point t24. The first memory die 121 may output data signals stored in memory banks of the first memory die 121 as the first memory data signals mDQ1<1:n>. The first memory die 121 may generate the first memory read strobe signal mRDQST1 based on the first data clock signal WCKT1. The buffer die 130 may receive, after the time point t24, the first memory data signals mDQ1<1:n> from the first memory die 121 and the first signal transmission lines 112-1, and may receive, from the first memory die 121, the first memory read strobe signal mRDQST1 synchronized with the first memory data signals mDQ1<1:n>. The first data buffering circuit 221 may output the first memory data signals mDQ1<1:n> to the first data bus 101 as the first data signals DQ<1:n> based on the first read path signal CSR1. The buffer die 130 may output the first read strobe signal RDQST1 together. Although not illustrated, the third memory die 123 may output data signals stored in memory banks of the third memory die 123 as the third memory data signals mDQ1<n+1:2n>, and may generate the second memory read strobe signal mRDQST2 based on the second data clock signal WCKT2. The buffer die 130 may receive, after the time point t24, the third memory data signals mDQ1<n+1:2n> through the third memory die 123 and the third signal transmission lines 112-3, and may receive, from the third memory die 123, the second memory read strobe signal mRDQST2 synchronized with the third memory data signals mDQ1<n+1:2n>. The second data buffering circuit 222 may output the third memory data signals mDQ1<n+1:2n> to the second data bus 102 as the second data signals DQ<n+1:2n> based on the second read path signal CSR2. The buffer die 130 may output the second read strobe signal RDQST2 together.

The latency control circuit 320 of the buffer control circuit 211 may delay the second preliminary read path signal CSR2P generated at the time points t22 and t23 by a time corresponding to the read latency, respectively, and may enable the second read path signal CSR2 at a time point t25. Because the second preliminary read path signal CSR2P is continuously enabled, the latency control circuit 320 may generate the second read path signal CSR2 having a pulse width wider than a pulse width corresponding to twice the burst length. The second memory die 122 may output data signals stored in memory banks of the second memory die 122 as the second memory data signals mDQ2<1:n>, and may generate the first memory read strobe signal mRDQST1 based on the first data clock signal WCKT1. The buffer die 130 may receive, after the time point t25, the second memory data signals mDQ2<1:n> from the second memory die 122 and the second signal transmission lines 112-2, and may receive, from the second memory die 122, the first memory read strobe signal mRDQST1 synchronized with the second memory data signals mDQ2<1:n>. The first data buffering circuit 221 may output the second memory data signals mDQ2<1:n> to the first data bus 101 as the first data signals DQ<1:n> based on the second read path signal CSR2. The buffer die 130 may output the first read strobe signal RDQST1 together. Although not illustrated, the fourth memory die 124 may output data signals stored in memory banks of the fourth memory die 124 as the fourth memory data signals mDQ2<n+1:2n>, and may generate the second memory read strobe signal mRDQST2 based on the second data clock signal WCKT2. The buffer die 130 may receive, after the time point t25, the fourth memory data signals mDQ2<n+1:2n> through the fourth memory die 124 and the fourth signal transmission lines 112-4, and may receive, from the fourth memory die 124, the second memory read strobe signal mRDQST2 synchronized with the fourth memory data signals mDQ2<n+1:2n>. The second data buffering circuit 222 may output the fourth memory data signals mDQ2<n+1:2n> to the second data bus 102 as the second data signals DQ<n+1:2n> based on the second read path signal CSR2. The buffer die 130 may output the second read strobe signal RDQST2 together.

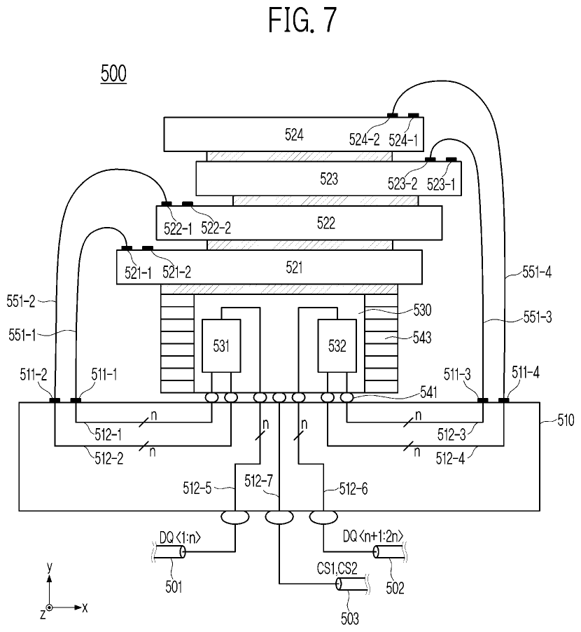

FIG. 7 is a diagram illustrating a configuration of a memory apparatus 500 according to an embodiment of the present disclosure. The memory apparatus 500 illustrated in FIG. 7 may perform substantially the same function as the memory apparatus 100 illustrated in FIG. 2, but may have a structure different from that of the memory apparatus 100. Referring to FIG. 7, the memory apparatus 500 may include a package substrate 510, a first memory die 521, a second memory die 522, a third memory die 523, a fourth memory die 524, and a buffer die 530. The first to fourth memory dies 521 to 524 and the buffer die 530 may be disposed on the package substrate 510, and the first to fourth memory dies 521 to 524, the buffer die 530, and the package substrate 510 may be packaged as a single package to implement a single memory apparatus. The buffer die 530 may be disposed on the package substrate 510. The buffer die 530 may be disposed on an upper side of the package substrate 510 in a y-axis direction. The first to fourth memory dies 521 to 524 may be sequentially disposed on the buffer die 530. The first memory die 521 may be disposed on an upper side of the buffer die 530 in the y-axis direction. In an embodiment, the buffer die 530 may have a size smaller than that of the first to fourth memory dies 521 to 524. In order for the first memory die 521 to be stably disposed on the buffer die 530, a periphery of the buffer die 530 may be molded with a molding member 543. The second memory die 522 may be disposed on an upper side of the first memory die 521 in the y-axis direction. The third memory die 523 may be disposed on an upper side of the second memory die 522 in the y-axis direction. The fourth memory die 524 may be disposed on an upper side of the third memory die 523 in the y-axis direction. The buffer die 530 may be disposed on the package substrate 510 in a flip-chip manner and may be electrically connected to signal transmission lines of the package substrate 510 through bumps 541. The first memory die 521 may be bonded on an upper side of the buffer die 530 using a die attach film, and the second to fourth memory dies 522-524 may also be bonded on upper sides of the first to third memory dies 521-523, respectively, using die attach films. The first memory die 521 may include n first data pads 521-1 and n second data pads 521-2. Here, n may be a multiple of 2 and may be, for example, 4, 6, 8, or 12. The second to fourth memory dies 522-524 may each include n first data pads 522-1, 523-1, 524-1 and n second data pads 522-2, 523-2, 524-2, respectively.

The second memory die 522 may be disposed on the first memory die 521 while being offset in a second direction of an x-axis such that the first data pads 521-1 and the second data pads 521-2 of the first memory die 521 are exposed in a first direction of the x-axis. The second direction may be opposite to the first direction. The third memory die 523 may be disposed on the second memory die 522 while being offset in the second direction of the x-axis such that the first data pads 522-1 and the second data pads 522-2 of the second memory die 522 are exposed in the first direction of the x-axis. The fourth memory die 524 may be disposed on the third memory die 523 while being offset in the first direction of the x-axis such that the first data pads 523-1 and the second data pads 523-2 of the third memory die 523 are exposed in the second direction of the x-axis. Because the fourth memory die 524 is disposed at the uppermost layer in a y-axis direction, the first data pads 524-1 and the second data pads 524-2 of the fourth memory die 524 may be exposed in the second direction of the x-axis.

The first to fourth memory dies 521 to 524 may have substantially the same structure as the memory die 10 illustrated in FIG. 1. The first to fourth memory dies 521 to 524 may support a plurality of byte modes. For example, the first to fourth memory dies 521 to 524 may operate in a first byte mode and a second byte mode. In the first byte mode, the first to fourth memory dies 521 to 524 may receive or output n data signals at one time. In the second byte mode, the first to fourth memory dies 521 to 524 may receive or output 2n data signals at one time. The first to fourth memory dies 521 to 524 may each include 2n data pads to support both the first byte mode and the second byte mode. The first to fourth memory dies 521 to 524 may operate in the first byte mode to provide an extended memory capacity, and the first to fourth memory dies 521 to 524 may receive or output data signals through n data pads.

The buffer die 530 may be connected to the first data bus 501 and the second data bus 502. First data signals DQ<1:n> may be transmitted through the first data bus 501, and second data signals DQ<n+1:2n> may be transmitted through the second data bus 502. The first and second data buses 501 and 502 may each include n signal transmission lines, and n data signals may be transmitted at one time through each of the first and second data buses 501 and 502. The buffer die 530 may connect the first and second data buses 501 and 502 to the first to fourth memory dies 521 to 524. The buffer die 530 may be further connected to the chip selection bus 503 and may receive a chip selection signal through the chip selection bus 503. The buffer die 530 may connect the first data bus 501 to one of the first and second memory dies 521 and 522, and may connect the second data bus 502 to one of the third and fourth memory dies 523 and 524 based on the chip selection signal. For example, the chip selection signal may include a first chip selection signal CS1 and a second chip selection signal CS2. When the external apparatus asserts the first chip selection signal CS1, the first and third memory dies 521 and 523 may be accessed based on the first chip selection signal CS1. When the external apparatus asserts the second chip selection signal CS2, the second and fourth memory dies 522 and 524 may be accessed based on the second chip selection signal CS2. When the first chip selection signal CS1 is asserted, the buffer die 530 may connect the first data bus 501 to the first memory die 521 and may connect the second data bus 502 to the third memory die 523. When the second chip selection signal CS2 is asserted, the buffer die 530 may connect the first data bus 501 to the second memory die 522 and may connect the second data bus 502 to the fourth memory die 524.

The package substrate 510 may include first pads 511-1, second pads 511-2, third pads 511-3, and fourth pads 511-4. The first to fourth pads 511-1 to 511-4 may be formed on the package substrate 510. The first pads 511-1 and the second pads 511-2 may be disposed on an upper side of the package substrate 510 at a distance spaced apart from the buffer die 530 in the first direction of the x-axis. The third pads 511-3 and the fourth pads 511-4 may be disposed on the upper side of the package substrate 510 at a distance spaced apart from the buffer die 530 in the second direction of the x-axis. The package substrate 510 may include first signal transmission lines 512-1, second signal transmission lines 512-2, third signal transmission lines 512-3, and fourth signal transmission lines 512-4. The first to fourth signal transmission lines 512-1 to 512-4 may be wirings inside the package substrate 510 and may each include n lines. The first signal transmission lines 512-1 may connect the first pads 511-1 and the buffer die 530. The second signal transmission lines 512-2 may connect the second pads 511-2 and the buffer die 530. The third signal transmission lines 512-3 may connect the third pads 511-3 and the buffer die 530. The fourth signal transmission lines 512-4 may connect the fourth pads 511-4 and the buffer die 530. The package substrate 510 may include a plurality of package balls 542. The package substrate 510 may be connected to the first data bus 501, the second data bus 502, and the chip selection bus 503 through the package balls 542, respectively. The package substrate 510 may further include fifth signal transmission lines 512-5, sixth signal transmission lines 512-6, and seventh signal transmission lines 512-7. The fifth to seventh signal transmission lines 512-5 to 512-7 may be wirings inside the package substrate 510. The fifth signal transmission lines 512-5 may connect the first data bus 501 and the buffer die 530, and the fifth signal transmission lines 512-5 may include n lines. The sixth signal transmission lines 512-6 may connect the second data bus 502 and the buffer die 530, and the sixth signal transmission lines 512-6 may include n lines. The seventh signal transmission lines 512-7 may connect the chip selection bus 503 and the buffer die 530, and the seventh signal transmission lines 512-7 may include the number of lines corresponding to the number of chip selection signals. The buffer die 530 may be connected to the first to seventh signal transmission lines 512-1 to 512-7 of the package substrate 510 through the bumps 541.

The first data pads 521-1 of the first memory die 521 may be connected to the first pads 511-1. The first data pads 521-1 of the first memory die 521 may be connected to the first pads 511-1 through first bonding wires 551-1. The number of the first bonding wires 551-1 may be n. The second data pads 521-2 of the first memory die 521 might not have an electrical connection with the package substrate 510. The first data pads 522-1 of the second memory die 522 may be connected to the second pads 511-2. The first data pads 522-1 of the second memory die 522 may be connected to the second pads 511-2 through second bonding wires 551-2. The number of the second bonding wires 551-2 may be n. The second data pads 522-2 of the second memory die 522 might not have an electrical connection with the package substrate 510. The second data pads 523-2 of the third memory die 523 may be connected to the third pads 511-3. The second data pads 523-2 of the third memory die 523 may be connected to the third pads 511-3 through third bonding wires 551-3. The number of the third bonding wires 551-3 may be n. The first data pads 523-1 of the third memory die 523 might not have an electrical connection with the package substrate 510. The second data pads 524-2 of the fourth memory die 524 may be connected to the fourth pads 511-4. The second data pads 524-2 of the fourth memory die 524 may be connected to the fourth pads 511-4 through fourth bonding wires 551-4. The number of the fourth bonding wires 551-4 may be n. The first data pads 524-1 of the fourth memory die 524 might not have an electrical connection with the package substrate 510.

The buffer die 530 may include a first data control circuit 531 and a second data control circuit 532. The first data control circuit 531 may selectively connect the first data bus 501 to the first memory die 521 and the second memory die 522 by connecting the first data bus 501 to one of the first and second signal transmission lines 512-1 and 512-2 based on the chip selection signal. The second data control circuit 532 may selectively connect the second data bus 502 to the third memory die 523 and the fourth memory die 524 by connecting the second data bus 502 to one of the third and fourth signal transmission lines 512-3 and 512-4 based on the chip selection signal. When the first chip selection signal CS1 is asserted, the first data control circuit 531 may connect the first data bus 501 to the first signal transmission lines 512-1, and the second data control circuit 532 may connect the second data bus 502 to the third signal transmission lines 512-3. When the second chip selection signal CS2 is asserted, the first data control circuit 531 may connect the first data bus 501 to the second signal transmission lines 512-2, and the second data control circuit 532 may connect the second data bus 502 to the fourth signal transmission lines 512-4. The buffer die 530 may include substantially the same configuration as the buffer die 130 illustrated in FIG. 3. The first data control circuit 531 may include a configuration corresponding to the first data buffering circuit 221, and the second data control circuit 532 may include a configuration corresponding to the second data buffering circuit 222. The buffer control circuit 211 may be disposed in either one of the first and second data control circuits 531 and 532, or may be disposed in both the first and second data control circuits 531 and 532. In an embodiment, the buffer control circuit 211 may be separated from the first and second data control circuits 531 and 532 and may be disposed between the first and second data control circuits 531 and 532.

As the first to fourth memory dies 521 to 524 are disposed on the buffer die 530, the lengths of the first and second signal transmission lines 512-1 and 512-2 and the lengths of the third and fourth signal transmission lines 512-3 and 512-4 may be formed to be substantially the same. In addition, it may become easier to match a propagation delay of a signal path connected from the first data bus 501 to the first data pads 521-1 and 522-1 of the first and second memory dies 521 and 522 with a propagation delay of a signal path connected from the second data bus 502 to the second data pads 523-2 and 524-2 of the third and fourth memory dies 523 and 524.

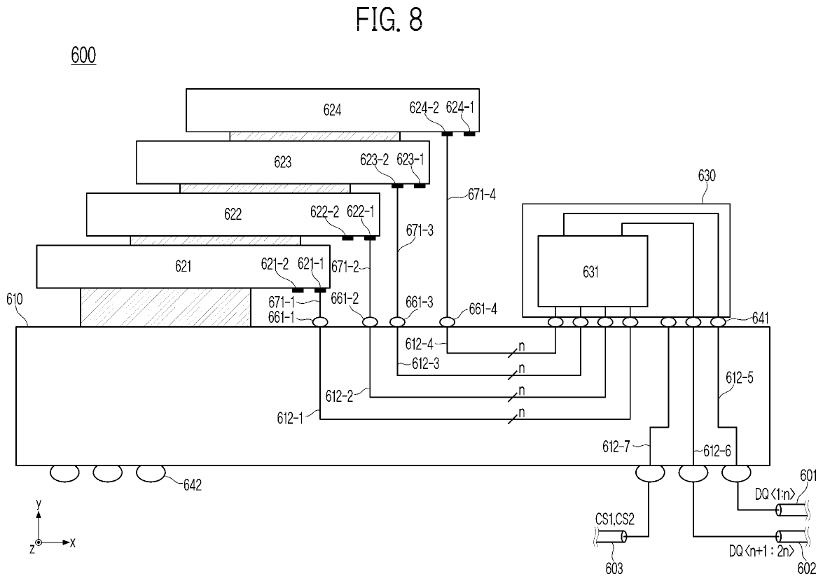

FIG. 8 is a diagram illustrating a configuration of a memory apparatus 600 according to an embodiment of the present disclosure. Referring to FIG. 8, the memory apparatus 600 may include a package substrate 610, a plurality of memory dies, and a buffer die 630. The memory apparatus 600 may include at least a first memory die 621, a second memory die 622, a third memory die 623, and a fourth memory die 624. The buffer die 630 may include a data control circuit 631. The memory apparatus 600 may include substantially the same components as the memory apparatus 100 illustrated in FIG. 2, and redundant descriptions of the same components will be omitted. In the memory apparatus 600, the first memory die 621, the second memory die 622, the third memory die 623, and the fourth memory die 624 may be disposed on the package substrate 610 in a flip-chip manner. Accordingly, the first data pads 621-1 to 624-1 and the second data pads 621-2 to 624-2 of the first to fourth memory dies 621 to 624 may be exposed toward an upper direction of the package substrate 610. Because the first memory die 621 is disposed at the lowermost layer in a y-axis direction, the first and second data pads 621-1 and 621-2 of the first memory die 621 may be exposed in a first direction of an x-axis. The second memory die 622 may be disposed on the first memory die 621 while being offset in the first direction of the x-axis such that the first and second data pads 622-1 and 622-2 of the second memory die 622 are exposed in the first direction of the x-axis. The third memory die 623 may be disposed on the second memory die 622 while being offset in the first direction of the x-axis such that the first and second data pads 623-1 and 623-2 of the third memory die 623 are exposed in the first direction of the x-axis. The fourth memory die 624 may be disposed on the third memory die 623 while being offset in the first direction of the x-axis such that the first and second data pads 624-1 and 624-2 of the fourth memory die 624 are exposed in the first direction of the x-axis.

The package substrate 610 may include first bumps 661-1, second bumps 661-2, third bumps 661-3, and fourth bumps 661-4 instead of the first to fourth pads 111-1 to 111-4 illustrated in FIG. 2. The first data pads 621-1 of the first memory die 621 may be connected to the first bumps 661-1 through first vertical bonding wires 671-1. The second data pads 621-2 of the first memory die 621 might not have an electrical connection with the package substrate 610. The first data pads 622-1 of the second memory die 622 may be connected to the second bumps 661-2 through second vertical bonding wires 671-2. The second data pads 622-2 of the second memory die 622 might not have an electrical connection with the package substrate 610. The second data pads 623-2 of the third memory die 623 may be connected to the third bumps 661-3 through third vertical bonding wires 671-3. The first data pads 623-1 of the third memory die 623 might not have an electrical connection with the package substrate 610. The second data pads 624-2 of the fourth memory die 624 may be connected to the fourth bumps 661-4 through fourth vertical bonding wires 671-4. The first data pads 624-1 of the fourth memory die 624 might not have an electrical connection with the package substrate 610. The package substrate 610 may include first to fourth signal transmission lines 612-1, 612-2, 612-3, and 612-4. The first bumps 661-1 may be connected to the buffer die 630 through the first signal transmission lines 612-1, the second bumps 661-2 may be connected to the buffer die 630 through the second signal transmission lines 612-2, the third bumps 661-3 may be connected to the buffer die 630 through the third signal transmission lines 612-3, and the fourth bumps 661-4 may be connected to the buffer die 630 through the fourth signal transmission lines 612-4. The buffer die 630 may be connected to a first data bus 601, a second data bus 602, and a chip selection bus 603. First data signals DQ<1:n> may be transmitted through the first data bus 601, second data signals DQ<n+1:2n> may be transmitted through the second data bus 602, and first and second chip selection signals CS1 and CS2 may be transmitted through the chip selection bus 603. The package substrate 610 may be connected to the first data bus 601, the second data bus 602, and the chip selection bus 603 through a plurality of package balls 642. The package substrate 610 may further include fifth to seventh signal transmission lines 612-5, 612-6, and 612-7. The fifth signal transmission lines 612-5 may connect the first data bus 601 and the buffer die 630, the sixth signal transmission lines 612-6 may connect the second data bus 602 and the buffer die 630, and the seventh signal transmission lines 612-7 may connect the chip selection bus 603 and the buffer die 630. The buffer die 630 may be connected to signal transmission lines of the package substrate 610 through bumps 641.

When the number of memory dies included in the memory apparatus 600 increases, in a case where the memory dies are connected to pads of the package substrate 110 through bonding wires as in the memory apparatus 100 illustrated in FIG. 1, not only the number of bonding wires but also the sizes of the package substrate and a memory package may increase because of the bonding wires. In the memory apparatus 600, when the memory dies are flipped and electrically connected to the package substrate 610 through vertical bonding wires, an increase in the sizes of the package substrate and the memory package can be mitigated. In addition, lengths of first to fourth signal transmission lines 612-1 to 612-4 connecting the first to fourth memory dies 621-624 and the buffer die 630 can be reduced. In FIG. 8, although the buffer die 630 is illustrated as being disposed in a region that does not overlap with a region in which the first to fourth memory dies 621-624 are disposed, the structure may be modified to a structure in which the first to fourth memory dies 621-624 are sequentially disposed on the buffer die 630 as illustrated in FIG. 7.

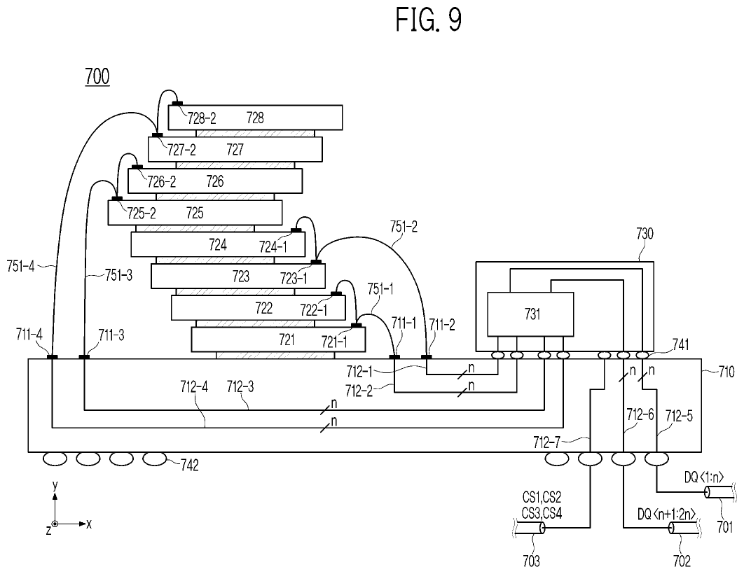

FIG. 9 is a diagram illustrating a configuration of the memory apparatus 700 according to an embodiment of the present disclosure. Referring to FIG. 9, the memory apparatus 700 may include a package substrate 710, a first memory die 721, a second memory die 722, a third memory die 723, a fourth memory die 724, a fifth memory die 725, a sixth memory die 726, a seventh memory die 727, an eighth memory die 728, and a buffer die 730. The first to eighth memory dies 721 to 728 may be sequentially disposed on the package substrate 710. For example, the first to eight memory dies 721 to 728 may be stacked on the package substrate 710 in a vertical direction. The first to eighth memory dies 721 to 728 may be disposed on the package substrate 710 in a first region of the package substrate 710. The first memory die 721 may be disposed on the package substrate 710 in a y-axis direction. The second memory die 722 may be disposed on the first memory die 721 in the y-axis direction. The third memory die 723 may be disposed on the second memory die 722 in the y-axis direction. The fourth memory die 724 may be disposed on the third memory die 723 in the y-axis direction. The fifth memory die 725 may be disposed on the fourth memory die 724 in the y-axis direction. The sixth memory die 726 may be disposed on the fifth memory die 725 in the y-axis direction. The seventh memory die 727 may be disposed on the sixth memory die 726 in the y-axis direction. The eighth memory die 728 may be disposed on the seventh memory die 727 in the y-axis direction. The first memory die 721 may be bonded on the package substrate 710 using a die attach film, and the second to eighth memory dies 722 to 728 may also be bonded on the first to seventh memory dies 721 to 727, respectively, using die attach films. The first memory die 721 may include n first data pads 721-1 and n second data pads. Here, n may be a multiple of 2, for example, 4, 6, 8, or 12. Each of the second to eighth memory dies 722 to 728 may also include n first data pads 722-1, 723-1, and 724-1, and n second data pads 725-2, 726-2, 727-2, and 728-2. The second data pads of the first to fourth memory dies 721 to 724 and the first data pads of the fifth to eighth memory dies 725 to 728 are not separately illustrated in FIG. 9.

The second memory die 722 may be disposed on the first memory die 721 while being offset in a second direction of an x-axis such that the first data pads 721-1 of the first memory die 721 are exposed in a first direction of the x-axis. The second direction may be opposite to the first direction. The third memory die 723 may be disposed on the second memory die 722 while being offset in the second direction of the x-axis such that the first data pads 722-1 of the second memory die 722 are exposed in the first direction of the x-axis. The fourth memory die 724 may be disposed on the third memory die 723 while being offset in the second direction of the x-axis such that the first data pads 723-1 of the third memory die 723 are exposed in the first direction of the x-axis. The fifth memory die 725 may be disposed on the fourth memory die 724 while being offset in the second direction of the x-axis such that the first data pads 724-1 of the fourth memory die 724 are exposed in the first direction of the x-axis. The sixth memory die 726 may be disposed on the fifth memory die 725 while being offset in the first direction of the x-axis such that the second data pads 725-2 of the fifth memory die 725 are exposed in the second direction of the x-axis. The seventh memory die 727 may be disposed on the sixth memory die 726 while being offset in the first direction of the x-axis such that the second data pads 726-2 of the sixth memory die 726 are exposed in the second direction of the x-axis. The eighth memory die 728 may be disposed on the seventh memory die 727 while being offset in the first direction of the x-axis such that the second data pads 727-2 of the seventh memory die 727 are exposed in the second direction of the x-axis. Because the eighth memory die 728 is disposed at the uppermost layer in a y-axis direction, the second data pads 728-2 of the eighth memory die 728 may be exposed in the second direction of the x-axis.

The first to eighth memory dies 721 to 728 may have substantially the same structure as the memory die 10 illustrated in FIG. 1. The first to eighth memory dies 721 to 728 may support a plurality of byte modes. For example, the first to eighth memory dies 721 to 728 may operate in a first byte mode and a second byte mode. In the first byte mode, the first to eighth memory dies 721 to 728 may receive n data signals at one time or output n data signals at one time. In the second byte mode, the first to eighth memory dies 721 to 728 may receive 2n data signals at one time or output 2n data signals at one time. The first to eighth memory dies 721 to 728 may each include 2n data pads to support both the first byte mode and the second byte mode. The first to eighth memory dies 721 to 728 may operate in the first byte mode to provide expanded memory capacity, and the first to eighth memory dies 721 to 728 may each receive or output data signals through n pads.

The buffer die 730 may be disposed on the package substrate 710 in the second region on the package substrate 710. The second region might not overlap the first region. The buffer die 730 may be disposed on the package substrate 710 in a y-axis direction. The buffer die 730 may be disposed on the package substrate 710 in a flip-chip manner and may be electrically connected to signal transmission lines of the package substrate 710 through bumps 741. The buffer die 730 may be connected to a first data bus 701 and a second data bus 702. First data signals DQ<1:n> may be transmitted through the first data bus 701, and second data signals DQ<n+1:2n> may be transmitted through the second data bus 702. The first and second data buses 701 and 702 may each include n signal transmission lines, and n data signals may be transmitted at one time through the first and second data buses 701 and 702, respectively. The buffer die 730 may connect the first and second data buses 701 and 702 to the first to eighth memory dies 721 to 728. The buffer die 730 may be further connected to a chip selection bus 703, and may receive a chip selection signal through the chip selection bus 703. The buffer die 730 may connect the first data bus 701 to one of the first to fourth memory dies 721 to 724 and may connect the second data bus 702 to one of the fifth to eighth memory dies 725 to 728 based on the chip selection signal. For example, the chip selection signal may include a first chip selection signal CS1, a second chip selection signal CS2, a third chip selection signal CS3, and a fourth chip selection signal CS4. When the external apparatus asserts the first chip selection signal CS1, the first and fifth memory dies 721 and 725 may be accessed based on the first chip selection signal CS1. When the external apparatus asserts the second chip selection signal CS2, the second and sixth memory dies 722 and 726 may be accessed based on the second chip selection signal CS2. When the external apparatus asserts the third chip selection signal CS3, the third and seventh memory dies 723 and 727 may be accessed based on the third chip selection signal CS3. When the external apparatus asserts the fourth chip selection signal CS4, the fourth and eighth memory dies 724 and 728 may be accessed based on the fourth chip selection signal CS4. The buffer die 730 may connect the first data bus 701 to the first memory die 721 and may connect the second data bus 702 to the fifth memory die 725 when the first chip selection signal CS1 is asserted. The buffer die 730 may connect the first data bus 701 to the second memory die 722 and may connect the second data bus 702 to the sixth memory die 726 when the second chip selection signal CS2 is asserted. The buffer die 730 may connect the first data bus 701 to the third memory die 723 and may connect the second data bus 702 to the seventh memory die 727 when the third chip selection signal CS3 is asserted. The buffer die 730 may connect the first data bus 701 to the fourth memory die 724 and may connect the second data bus 702 to the eighth memory die 728 when the fourth chip selection signal CS4 is asserted.

The package substrate 710 may include first pads 711-1, second pads 711-2, third pads 711-3, and fourth pads 711-4. The first to fourth pads 711-1 to 711-4 may be formed on the package substrate 710. The first pads 711-1 and the second pads 711-2 may be provided on the package substrate 710 at a distance spaced apart from the first memory die 721 in the first direction of an x-axis. The third pads 711-3 and the fourth pads 711-4 may be provided on the package substrate 710 at a distance spaced apart from the first memory die 721 in the second direction of the x-axis. The package substrate 710 may include first signal transmission lines 712-1, second signal transmission lines 712-2, third signal transmission lines 712-3, and fourth signal transmission lines 712-4. The first to fourth signal transmission lines 712-1 to 712-4 may be wirings inside the package substrate 710 and may each include n lines. The first signal transmission lines 712-1 may connect the first pads 711-1 and the buffer die 730. The second signal transmission lines 712-2 may connect the second pads 711-2 and the buffer die 730. The third signal transmission lines 712-3 may connect the third pads 711-3 and the buffer die 730. The fourth signal transmission lines 712-4 may connect the fourth pads 711-4 and the buffer die 730. The package substrate 710 may include a plurality of package balls 742. The package substrate 710 may be connected to the first data bus 701, the second data bus 702, and the chip selection bus 703 through the package balls 742, respectively. The package substrate 710 may further include fifth signal transmission lines 712-5, sixth signal transmission lines 712-6, and seventh signal transmission lines 712-7. The fifth to seventh signal transmission lines 712-5 to 712-7 may be wirings inside the package substrate 710. The fifth signal transmission lines 712-5 may connect the first data bus 701 and the buffer die 730, and the fifth signal transmission lines 712-5 may include n lines. The sixth signal transmission lines 712-6 may connect the second data bus 702 and the buffer die 730, and the sixth signal transmission lines 712-6 may include n lines. The seventh signal transmission lines 712-7 may connect the chip selection bus 703 and the buffer die 730, and the seventh signal transmission lines 712-7 may include the number of lines corresponding to the number of the chip selection signals. The buffer die 730 may be connected to the first to seventh signal transmission lines 712-1 to 712-7 of the package substrate 710 through the bumps 741, respectively.

The first data pads 721-1 of the first memory die 721 and the first data pads 722-1 of the second memory die 722 may be connected in common to the first pads 711-1 and the first signal transmission lines 712-1. The first data pads 721-1 of the first memory die 721 and the first data pads 722-1 of the second memory die 722 may be connected to the first pads 711-1 through first bonding wires 751-1. The number of the first bonding wires 751-1 may be n. The second data pads of the first memory die 721 and the second data pads of the second memory die 722 might not have an electrical connection with the package substrate 710. The first data pads 723-1 of the third memory die 723 and the first data pads 724-1 of the fourth memory die 724 may be connected in common to the second pads 711-2 and the second signal transmission lines 712-2. The first data pads 723-1 of the third memory die 723 and the first data pads 724-1 of the fourth memory die 724 may be connected to the second pads 711-2 through second bonding wires 751-2. The number of the second bonding wires 751-2 may be n. The second data pads of the third memory die 723 and the second data pads of the fourth memory die 724 might not have an electrical connection with the package substrate 710. The second data pads 725-2 of the fifth memory die 725 and the second data pads 726-2 of the sixth memory die 726 may be connected in common to the third pads 711-3 and the third signal transmission lines 712-3. The second data pads 725-2 of the fifth memory die 725 and the second data pads 726-2 of the sixth memory die 726 may be connected to the third pads 711-3 through third bonding wires 751-3. The number of the third bonding wires 751-3 may be n. The first data pads of the fifth memory die 725 and the first data pads of the sixth memory die 726 might not have an electrical connection with the package substrate 710. The second data pads 727-2 of the seventh memory die 727 and the second data pads 728-2 of the eighth memory die 728 may be connected in common to the fourth pads 711-4 and the fourth signal transmission lines 712-4. The second data pads 727-2 of the seventh memory die 727 and the second data pads 728-2 of the eighth memory die 728 may be connected to the fourth pads 711-4 through fourth bonding wires 751-4. The number of the fourth bonding wires 751-4 may be n. The first data pads of the seventh memory die 727 and the first data pads of the eighth memory die 728 might not have an electrical connection with the package substrate 710.

The buffer die 730 may include a data control circuit 731. The data control circuit 731 may selectively connect the first data bus 701 to the first to fourth memory dies 721 to 724 by connecting the first data bus 701 to one of the first and second signal transmission lines 712-1 and 712-2 based on the chip selection signal. The data control circuit 731 may selectively connect the second data bus 702 to the fifth to eighth memory dies 725 to 728 by connecting the second data bus 702 to one of the third and fourth signal transmission lines 712-3 and 712-4 based on the chip selection signal. When any one of the first chip selection signal CS1 and the second chip selection signal CS2 is asserted, the data control circuit 731 may connect the first data bus 701 to the first signal transmission lines 712-1 and connect the second data bus 702 to the third signal transmission lines 712-3. When any one of the third chip selection signal CS3 and the fourth chip selection signal CS4 is asserted, the data control circuit 731 may connect the first data bus 701 to the second signal transmission lines 712-2 and connect the second data bus 702 to the fourth signal transmission lines 712-4.

The memory apparatus 700 may provide an increased memory capacity by using four ranks and four chip selection signals. The external apparatus may access the first and fifth memory dies 721 and 725 together based on the first chip selection signal CS1, access the second and sixth memory dies 722 and 726 together based on the second chip selection signal CS2, access the third and seventh memory dies 723 and 727 together based on the third chip selection signal CS3, and access the fourth and eighth memory dies 724 and 728 together based on the fourth chip selection signal CS4, and thus a memory capacity eight times greater than when accessing one memory die may be utilized. The memory apparatus 100 shown in FIG. 2 may limit a capacitive load of the first and second data buses 101 and 102 to a capacitive load corresponding to one memory die. However, as the number of ranks and the number of memory dies included in a memory apparatus increase in order to increase a memory capacity, a package substrate should include the number of signal transmission lines corresponding to the number of memory dies. For example, in FIG. 9, when the package substrate includes signal transmission lines separately connected to data pads of the first to eighth memory dies 721 to 728, 16n wirings should be formed in the package substrate 710 to transmit data signals. It is difficult for the package substrate 710 to form a large number of wirings like a silicon interposer, and when a large number of wirings are formed, signal integrity may may be degraded due to cross-talk between the wirings. The memory apparatus 700 can reduce the number of wirings formed on the package substrate by half while minimizing an increase in the capacitive load of a data bus by allowing one data bus to be connected to a capacitive load corresponding to two memory dies.

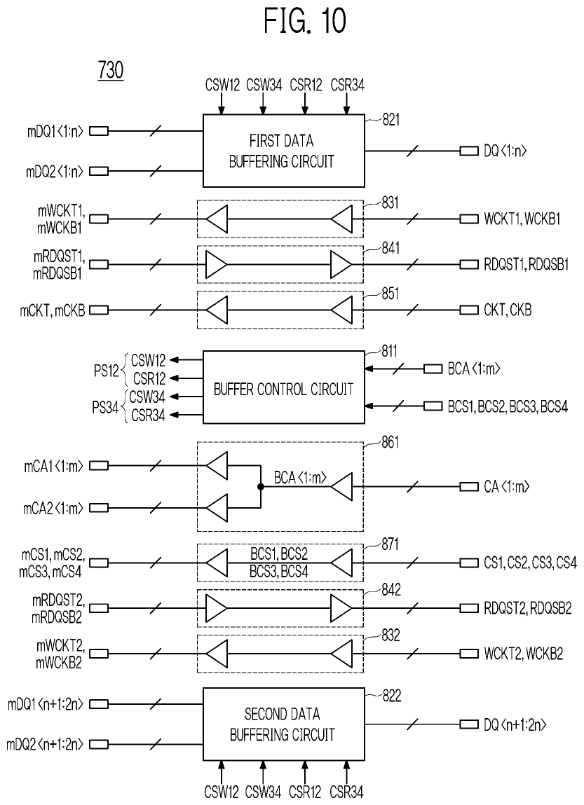

FIG. 10 is a diagram illustrating a configuration of the buffer die 730 shown in FIG. 9. Referring to FIG. 10, the buffer die 730 may include a buffer control circuit 811, a first data buffering circuit 821, and a second data buffering circuit 822. The buffer control circuit 811, the first data buffering circuit 821, and the second data buffering circuit 822 may constitute the data control circuit 731 shown in FIG. 9. The buffer control circuit 811 may generate a first path selection signal PS12 and a second path selection signal PS34 based on a command address signal CA<1:m> and a chip selection signal. The buffer control circuit 811 may generate the first and second path selection signals PS12 and PS34 by receiving a buffered command address signal BCA<1:m> generated by buffering the command address signal CA<1:m> and first to fourth buffered chip selection signals BCS1 to BCS4 generated by buffering the first to fourth chip selection signals CS1 to CS4. The buffer control circuit 811 may enable the first path selection signal PS12 when any one of the first and second chip selection signals CS1 and CS2 is asserted. The buffer control circuit 811 may enable the second path selection signal PS34 when any one of the third and fourth chip selection signals CS3 and CS4 is asserted. The command address signal CA<1:m> may include a write command and a read command. The first path selection signal PS12 may include a first write path signal CSW12 and a first read path signal CSR12, and the second path selection signal PS34 may include a second write path signal CSW34 and a second read path signal CSR34. The write command may instruct a write operation in which data is transmitted from an external apparatus to a memory apparatus 700, and the read command may instruct a read operation in which data is transmitted from the memory apparatus 700 to the external apparatus. When the command address signal CA<1:m> includes the write command and any one of the first and second chip selection signals CS1 and CS2 is asserted, the buffer control circuit 811 may enable the first write path signal CSW12. When the command address signal CA<1:m> includes the write command and any one of the third and fourth chip selection signals CS3 and CS4 is asserted, the buffer control circuit 811 may enable the second write path signal CSW34. When the command address signal CA<1:m> includes the read command and any one of the first and second chip selection signals CS1 and CS2 is asserted, the buffer control circuit 811 may enable the first read path signal CSR12. When the command address signal CA<1:m> includes the read command and any one of the third and fourth chip selection signals CS3 and CS4 is asserted, the buffer control circuit 811 may enable the second read path signal CSR34.

In FIG. 10, signals transmitted between the buffer die 730 and the external apparatus have the same characteristics as signals transmitted between the buffer die 730 and the memory dies, but for clarity of description, “memory” is additionally added to names of signals transmitted between the buffer die 730 and the first to eighth memory dies 721 to 728 and “m” is additionally added to reference numerals. Referring to FIG. 9 together, the first data buffering circuit 821 may receive the first and second path selection signals PS12 and PS34 from the buffer control circuit 811. The first data buffering circuit 821 may be connected to the first data bus 701 and the first to fourth memory dies 721 to 724. The first data buffering circuit 821 may be connected to the first and second memory dies 721 and 722 through the first signal transmission lines 712-1 and may be connected to the third and fourth memory dies 723 and 724 through the second signal transmission lines 712-2. The first data buffering circuit 821 may connect the first data bus 701 to the first and second memory dies 721 and 722 when the first path selection signal PS12 is enabled. The first data buffering circuit 821 may connect the first data bus 701 to the third and fourth memory dies 723 and 724 when the second path selection signal PS34 is enabled. First data signals DQ<1:n> are transmitted through the first data bus 701, first memory data signals mDQ1<1:n> are transmitted through the first signal transmission lines 712-1, and second memory data signals mDQ2<1:n> may be transmitted through the second signal transmission lines 712-2. The first data buffering circuit 821 may receive the first data signals DQ<1:n> transmitted from the external apparatus through the first data bus 701 when the first write path signal CSW12 is enabled, and may transmit the first data signals DQ<1:n> as the first memory data signals mDQ1<1:n> to the first signal transmission lines 712-1 and the first and second memory dies 721 and 722. The first data buffering circuit 821 may receive the first data signals DQ<1:n> transmitted from the external apparatus through the first data bus 701 when the second write path signal CSW34 is enabled, and may transmit the first data signals DQ<1:n> as the second memory data signals mDQ2<1:n> to the second signal transmission lines 712-2 and the third and fourth memory dies 723 and 724. The first data buffering circuit 821 may receive the first memory data signals mDQ1<1:n> transmitted from one of the first and second memory dies 721 and 722 and the first signal transmission lines 712-1 when the first read path signal CSR12 is enabled, and may output the first memory data signals mDQ1<1:n> as the first data signals DQ<1:n> to the external apparatus through the first data bus 701. The first data buffering circuit 821 may receive the second memory data signals mDQ2<1:n> transmitted from one of the third and fourth memory dies 723 and 724 and the second signal transmission lines 712-2 when the second read path signal CSR34 is enabled, and may output the second memory data signals mDQ2<1:n> as the first data signals DQ<1:n> to the external apparatus through the first data bus 701.

The second data buffering circuit 822 may receive the first and second path selection signals PS12 and PS34 from the buffer control circuit 811. The second data buffering circuit 822 may be connected to the second data bus 702 and the fifth to eighth memory dies 725 to 728. The second data buffering circuit 822 may be connected to the fifth and sixth memory dies 725 and 726 through the third signal transmission lines 712-3 and may be connected to the seventh and eighth memory dies 727 and 728 through the fourth signal transmission lines 712-4. The second data buffering circuit 822 may connect the second data bus 702 to the fifth and sixth memory dies 725 and 726 when the first path selection signal PS12 is enabled. The second data buffering circuit 822 may connect the second data bus 702 to the seventh and eighth memory dies 727 and 728 when the second path selection signal PS34 is enabled. Second data signals DQ<n+1:2n> are transmitted through the second data bus 702, third memory data signals mDQ1<n+1:2n> are transmitted through the third signal transmission lines 712-3, and fourth memory data signals mDQ2<n+1:2n> may be transmitted through the fourth signal transmission lines 712-4. The second data buffering circuit 822 may receive the second data signals DQ<n+1:2n> transmitted from the external apparatus through the second data bus 702 when the first write path signal CSW12 is enabled, and may transmit the second data signals DQ<n+1:2n> as the third memory data signals mDQ1<n+1:2n> to the third signal transmission lines 712-3 and the fifth and sixth memory dies 725 and 726. The second data buffering circuit 822 may receive the second data signals DQ<n+1:2n> transmitted from the external apparatus through the second data bus 702 when the second write path signal CSW34 is enabled, and may transmit the second data signals DQ<n+1:2n> as the fourth memory data signals mDQ2<n+1:2n> to the fourth signal transmission lines 712-4 and the seventh and eighth memory dies 727 and 728. The second data buffering circuit 822 may receive the third memory data signals mDQ1<n+1:2n> transmitted from one of the fifth and sixth memory dies 725 and 726 and the third signal transmission lines 712-3 when the first read path signal CSR12 is enabled, and may output the third memory data signals mDQ1<n+1:2n> as the second data signals DQ<n+1:2n> to the external apparatus through the second data bus 702. The second data buffering circuit 822 may receive the fourth memory data signals mDQ2<n+1:2n> transmitted from one of the seventh and eighth memory dies 727 and 728 and the fourth signal transmission lines 712-4 when the second read path signal CSR34 is enabled, and may output the fourth memory data signals mDQ2<n+1:2n> as the second data signals DQ<n+1:2n> to the external apparatus through the second data bus 702.

The buffer die 730 may further include a plurality of buffer circuits. The buffer die 730 may further include a first data clock buffer circuit 831, a first read strobe buffer circuit 841, a system clock buffer circuit 851, a command address buffer circuit 861, a chip selection buffer circuit 871, a second data clock buffer circuit 832, and a second read strobe buffer circuit 842. Components of the buffer die 730 are only illustrative, and the buffer die 730 may include any other component not shown in FIG. 10 in order to interface signals required for operation of the memory apparatus 700. The first data clock buffer circuit 831 may receive a first data clock signal WCKT1 and a first complementary data clock signal WCKB1 from the external apparatus and may buffer the first data clock signal pair WCKT1 and WCKB1. The first data clock buffer circuit 831 may output the buffered first data clock signal WCKT1 and the buffered first complementary data clock signal WCKB1 as a first memory data clock signal mWCKT1 and a first complementary memory data clock signal mWCKB1, respectively. The first data clock buffer circuit 831 may be connected in common to the first to fourth memory dies 721 to 724 and may provide the first memory data clock signal mWCKT1 and the first complementary memory data clock signal mWCKB1 in common to the first to fourth memory dies 721 to 724. The first to fourth memory dies 721 to 724 may perform data input/output operations in synchronization with the first memory data clock signal pair mWCKT1 and mWCKB1.

The first read strobe buffer circuit 841 may receive a first memory read strobe signal mRDQST1 and a first complementary memory read strobe signal mRDQSB1 from one of the first to fourth memory dies 721 to 724. The first memory read strobe signal pair mRDQST1 and mRDQSB1 may be generated based on the first memory data clock signal pair mWCKT1 and mWCKB1 and may be synchronized with a timing at which the first memory data signals mDQ1<1:n> are output from the first and second memory dies 721 and 722 and a timing at which the second memory data signals mDQ2<1:n> are output from the third and fourth memory dies 723 and 724. The first read strobe buffer circuit 841 may buffer the first memory read strobe signal pair mRDQST1 and mRDQSB1 and may output a first read strobe signal RDQST1 and a first complementary read strobe signal RDQSB1 to the external apparatus. When the first chip selection signal CS1 is asserted, the first read strobe buffer circuit 841 may receive the first memory read strobe signal mRDQST1 and the first complementary memory read strobe signal mRDQSB1 from the first memory die 721 and may output the first read strobe signal pair RDQST1 and RDQSB1 from the first memory read strobe signal pair mRDQST1 and mRDQSB1. When the second chip selection signal CS2 is asserted, the first read strobe buffer circuit 841 may receive the first memory read strobe signal mRDQST1 and the first complementary memory read strobe signal mRDQSB1 from the second memory die 722 and may output the first read strobe signal pair RDQST1 and RDQSB1 from the first memory read strobe signal pair mRDQST1 and mRDQSB1. When the third chip selection signal CS3 is asserted, the first read strobe buffer circuit 841 may receive the first memory read strobe signal mRDQST1 and the first complementary memory read strobe signal mRDQSB1 from the third memory die 723 and may output the first read strobe signal pair RDQST1 and RDQSB1 from the first memory read strobe signal pair mRDQST1 and mRDQSB1. When the fourth chip selection signal CS4 is asserted, the first read strobe buffer circuit 841 may receive the first memory read strobe signal mRDQST1 and the first complementary memory read strobe signal mRDQSB1 from the fourth memory die 724 and may output the first read strobe signal pair RDQST1 and RDQSB1 from the first memory read strobe signal pair mRDQST1 and mRDQSB1.

The system clock buffer circuit 851 may receive a system clock signal CKT and a complementary system clock signal CKB from the external apparatus and may buffer the system clock signal pair CKT and CKB. The system clock buffer circuit 751 may output the buffered system clock signal CKT as a memory system clock signal mCKT and may output the buffered complementary system clock signal CKB as a complementary memory system clock signal mCKB. The system clock buffer circuit 851 may be connected in common to the first to eighth memory dies 721 to 728 and may provide the memory system clock signal pair mCKT and mCKB in common to the first to eighth memory dies 721 to 728.

The command address buffer circuit 861 may receive the command address signal CA<1:m> from the external apparatus and may generate a buffered command address signal BCA<1:m> by buffering the command address signal CA<1:m>. The command address buffer circuit 861 may output the buffered command address signal BCA<1:m> as a first memory command address signal mCA1<1:m> and a second memory command address signal mCA2<1:m>. The buffered command address signal BCA<1:m> may be provided to the buffer control circuit 811. The first to fourth memory dies 721 to 724 may receive the first memory command address signal mCA1<1:m> in common, and the fifth to eighth memory dies 725 to 728 may receive the second memory command address signal mCA2<1:m> in common. The command address signal CA<1:m> may be synchronized with the system clock signal pair CKT and CKB. The first to fourth memory dies 721 to 724 may receive the first memory command address signal mCA1<1:m> in synchronization with the memory system clock signal pair mCKT and mCKB, and the fifth to eighth memory dies 725 to 728 may receive the second memory command address signal mCA2<1:m> in synchronization with the memory system clock signal pair mCKT and mCKB.

The chip selection buffer circuit 871 may receive the first chip selection signal CS1, the second chip selection signal CS2, the third chip selection signal CS3, and the fourth chip selection signal CS4 from the external apparatus. The chip selection buffer circuit 871 may generate the first buffered chip selection signal BCS1, the second buffered chip selection signal BCS2, the third buffered chip selection signal BCS3, and the fourth buffered chip selection signal BCS4 by buffering the first to fourth chip selection signals CS1 to CS4. The chip selection buffer circuit 871 may output the first buffered chip selection signal BCS1 as a first memory chip selection signal mCS1, output the second buffered chip selection signal BCS2 as a second memory chip selection signal mCS2, output the third buffered chip selection signal BCS3 as a third memory chip selection signal mCS3, and output the fourth buffered chip selection signal BCS4 as a fourth memory chip selection signal mCS4. The first and fifth memory dies 721 and 725 may receive the first memory chip selection signal mCS1 in common because the first chip selection signal CS1 is assigned thereto. The second and sixth memory dies 722 and 726 may receive the second memory chip selection signal mCS2 in common because the second chip selection signal CS2 is assigned thereto. The third and seventh memory dies 723 and 727 may receive the third memory chip selection signal mCS3 in common because the third chip selection signal CS3 is assigned thereto. The fourth and eighth memory dies 724 and 728 may receive the fourth memory chip selection signal mCS4 in common because the fourth chip selection signal CS4 is assigned thereto. The first to fourth buffered chip selection signals BCS1 to BCS4 may be provided to the buffer control circuit 811.

The second data clock buffer circuit 832 may receive a second data clock signal WCKT2 and a second complementary data clock signal WCKB2 from the external apparatus and may buffer the second data clock signal WCKT2 and the second complementary data clock signal WCKB2. The second data clock signal pair WCKT2 and WCKB2 may be independent of the first data clock signal pair WCKT1 and WCKB1 and may have identical timing or different timing. The second data clock buffer circuit 832 may output the buffered second data clock signal WCKT2 and the buffered second complementary data clock signal WCKB2 as a second memory data clock signal mWCKT2 and a second complementary memory data clock signal mWCKB2, respectively. The second data clock buffer circuit 832 may be connected in common to the fifth to eighth memory dies 725 to 728 and may provide the second memory data clock signal mWCKT2 and the second complementary memory data clock signal mWCKB2 in common to the fifth to eighth memory dies 725 to 728. The fifth to eighth memory dies 725 to 728 may perform data input/output operations in synchronization with the second memory data clock signal pair mWCKT2 and mWCKB2.

The second read strobe buffer circuit 842 may receive a second memory read strobe signal mRDQST2 and a second complementary memory read strobe signal mRDQSB2 from one of the fifth to eighth memory dies 725 to 728. The second memory read strobe signal pair mRDQST2 and mRDQSB2 may be generated based on the second memory data clock signal pair mWCKT2 and mWCKB2 and may be synchronized with a timing at which the third memory data signals mDQ1<n+1:2n> are output from the fifth and sixth memory dies 725 and 726 and a timing at which the fourth memory data signals mDQ2<n+1:2n> are output from the seventh and eighth memory dies 727 and 728. The second read strobe buffer circuit 842 may buffer the second memory read strobe signal pair mRDQST2 and mRDQSB2 and may output a second read strobe signal RDQST2 and a second complementary read strobe signal RDQSB2 to the external apparatus. When the first chip selection signal CS1 is asserted, the second read strobe buffer circuit 842 may receive the second memory read strobe signal mRDQST2 and the second complementary memory read strobe signal mRDQSB2 from the fifth memory die 725 and may output the second read strobe signal pair RDQST2 and RDQSB2 from the second memory read strobe signal pair mRDQST2 and mRDQSB2. When the second chip selection signal CS2 is asserted, the second read strobe buffer circuit 842 may receive the second memory read strobe signal mRDQST2 and the second complementary memory read strobe signal mRDQSB2 from the sixth memory die 726 and may output the second read strobe signal pair RDQST2 and RDQSB2 from the second memory read strobe signal pair mRDQST2 and mRDQSB2. When the third chip selection signal CS3 is asserted, the second read strobe buffer circuit 842 may receive the second memory read strobe signal mRDQST2 and the second complementary memory read strobe signal mRDQSB2 from the seventh memory die 727 and may output the second read strobe signal pair RDQST2 and RDQSB2 from the second memory read strobe signal pair mRDQST2 and mRDQSB2. When the fourth chip selection signal CS4 is asserted, the second read strobe buffer circuit 842 may receive the second memory read strobe signal mRDQST2 and the second complementary memory read strobe signal mRDQSB2 from the eighth memory die 728 and may output the second read strobe signal pair RDQST2 and RDQSB2 from the second memory read strobe signal pair mRDQST2 and mRDQSB2.

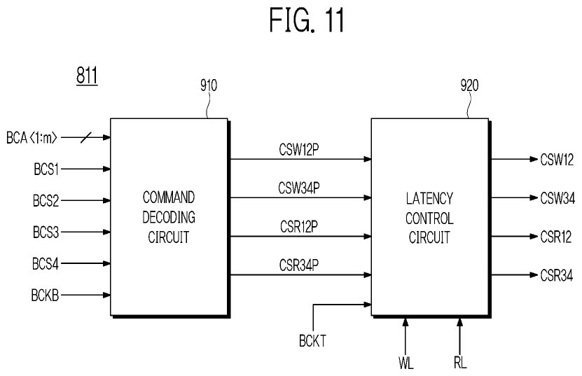

FIG. 11 is a diagram illustrating a configuration of the buffer control circuit 811 illustrated in FIG. 10. Referring to FIG. 11, the buffer control circuit 811 may include a command decoding circuit 910 and a latency control circuit 920. The command decoding circuit 910 may receive the buffered command address signal BCA<1:m>, the first buffered chip selection signal BCS1, the second buffered chip selection signal BCS2, the third buffered chip selection signal BCS3, and the fourth buffered chip selection signal BCS4. The command decoding circuit 910 may generate a first preliminary write path signal CSW12P, a second preliminary write path signal CSW34P, a first preliminary read path signal CSR12P, and a second preliminary read path signal CSR34P based on the buffered command address signal BCA<1:m> and the first to fourth buffered chip selection signals BCS1 to BCS4. The command decoding circuit 910 may enable the first preliminary write path signal CSW12P when the buffered command address signal BCA<1:m> includes the write command and one of the first and second buffered chip selection signals BCS1 and BCS2 is asserted. The command decoding circuit 910 may enable the second preliminary write path signal CSW34P when the buffered command address signal BCA<1:m> includes the write command and one of the third and fourth buffered chip selection signals BCS3 and BCS4 is asserted. The command decoding circuit 910 may enable the first preliminary read path signal CSR12P when the buffered command address signal BCA<1:m> includes the read command and one of the first and second buffered chip selection signals BCS1 and BCS2 is asserted. The command decoding circuit 910 may enable the second preliminary read path signal CSR34P when the buffered command address signal BCA<1:m> includes the read command and one of the third and fourth buffered chip selection signals BCS3 and BCS4 is asserted. The command decoding circuit 910 may receive a buffered complementary system clock signal BCKB generated by buffering the complementary system clock signal CKB by the system clock buffer circuit 851 and may output the first preliminary write path signal CSW12P, the second preliminary write path signal CSW34P, the first preliminary read path signal CSR12P, and the second preliminary read path signal CSR34P in synchronization with the buffered complementary system clock signal BCKB.

The latency control circuit 920 may receive the first preliminary write path signal CSW12P, the second preliminary write path signal CSW34P, the first preliminary read path signal CSR12P, and the second preliminary read path signal CSR34P and may generate the first write path signal CSW12, the second write path signal CSW34, the first read path signal CSR12, and the second read path signal CSR34. The latency control circuit 920 may receive a write latency signal WL and a read latency signal RL. The latency control circuit 920 may generate the first write path signal CSW12 by delaying the first preliminary write path signal CSW12P by a time corresponding to a write latency based on the write latency signal WL. The latency control circuit 920 may generate the second write path signal CSW34 by delaying the second preliminary write path signal CSW34P by a time corresponding to the write latency based on the write latency signal WL. The latency control circuit 920 may generate the first read path signal CSR12 by delaying the first preliminary read path signal CSR12P by a time corresponding to a read latency based on the read latency signal RL. The latency control circuit 920 may generate the second read path signal CSR34 by delaying the second preliminary read path signal CSR34P by a time corresponding to the read latency based on the read latency signal RL. The latency control circuit 920 may further receive a buffered system clock signal BCKT generated by buffering the system clock signal CKT by the system clock buffer circuit 851. The latency control circuit 920 may generate the first and second write path signals CSW12 and CSW34 by delaying the first and second preliminary write path signals CSW12P and CSW34P by a time corresponding to the write latency in synchronization with the buffered system clock signal BCKT. Likewise, the latency control circuit 920 may generate the first and second read path signals CSR12 and CSR34 by delaying the first and second preliminary read path signals CSR12P and CSR34P by a time corresponding to the read latency in synchronization with the buffered system clock signal BCKT.

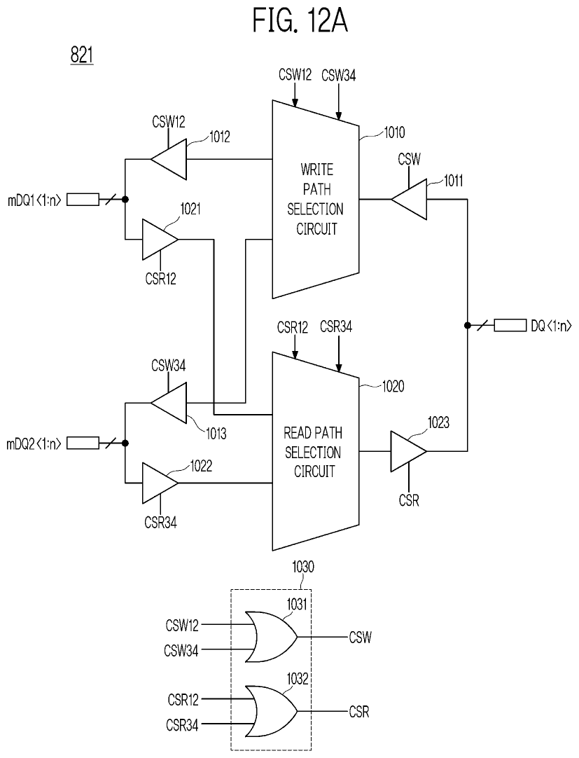

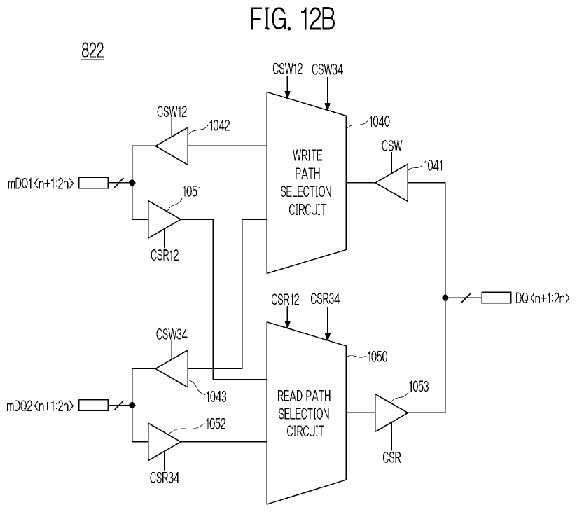

FIG. 12A is a diagram illustrating a configuration of the first data buffering circuit 821 illustrated in FIG. 10. Referring to FIG. 12A, the first data buffering circuit 821 may include a write path selection circuit 1010 and a read path selection circuit 1020. The write path selection circuit 1010 may be connected between the first data bus 701, the first signal transmission lines 712-1, and the second signal transmission lines 712-2 and may receive the first and second write path signals CSW12 and CSW34. The write path selection circuit 1010 may output the first data signals DQ<1:n> received through the first data bus 701 as the first memory data signals mDQ1<1:n> to the first signal transmission lines 712-1 when the first write path signal CSW12 is enabled. The write path selection circuit 1010 may output the first data signals DQ<1:n> received through the first data bus 701 as the second memory data signals mDQ2<1:n> to the second signal transmission lines 712-2 when the second write path signal CSW34 is enabled.

The read path selection circuit 1020 may be connected between the first data bus 701, the first signal transmission lines 712-1, and the second signal transmission lines 712-2 and may receive the first and second read path signals CSR12 and CSR34. The read path selection circuit 1020 may output the first memory data signals mDQ1<1:n> transmitted from the first signal transmission lines 712-1 as the first data signals DQ<1:n> to the first data bus 701 when the first read path signal CSR12 is enabled. The read path selection circuit 1020 may output the second memory data signals mDQ2<1:n> transmitted from the second signal transmission lines 712-2 as the first data signals DQ<1:n> to the first data bus 701 when the second read path signal CSR34 is enabled.

The first data buffering circuit 821 may include a first buffer 1011, a second buffer 1012, a third buffer 1013, a fourth buffer 1021, a fifth buffer 1022, and a sixth buffer 1023. The first buffer 1011 may buffer the first data signals DQ<1:n> and may provide buffered signals to the write path selection circuit 1010. The second buffer 1012 may buffer output signals of the write path selection circuit 1010 and may output buffered signals as the first memory data signals mDQ1<1:n> to the first signal transmission lines 712-1. The third buffer 1013 may buffer output signals of the write path selection circuit 1010 and may output buffered signals as the second memory data signals mDQ2<1:n> to the second signal transmission lines 712-2. The fourth buffer 1021 may buffer the first memory data signals mDQ1<1:n> and may output buffered signals to the read path selection circuit 1020. The fifth buffer 1022 may buffer the second memory data signals mDQ2<1:n> and may output buffered signals to the read path selection circuit 1020. The sixth buffer 1023 may buffer output signals of the read path selection circuit 1020 and may output buffered signals as the first data signals DQ<1:n> to the first data bus 701.

The first data buffering circuit 821 may further include a gating circuit 1030 and may control whether the first to sixth buffers 1011, 1012, 1013, 1021, 1022, and 1023 are activated. The gating circuit 1030 may receive the first and second write path signals CSW12 and CSW34 and may enable a write buffer signal CSW when one of the first and second write path signals CSW12 and CSW34 is enabled. The gating circuit 1030 may receive the first and second read path signals CSR12 and CSR34 and may enable a read buffer signal CSR when one of the first and second read path signals CSR12 and CSR34 is enabled. The gating circuit 1030 may include a first OR gate 1031 and a second OR gate 1032. The first OR gate 1031 may perform an OR operation on the first and second write path signals CSW12 and CSW34 and may output the write buffer signal CSW. The second OR gate 1032 may perform an OR operation on the first and second read path signals CSR12 and CSR34 and may output the read buffer signal CSR. The first buffer 1011 may receive the write buffer signal CSW and may be activated when the write buffer signal CSW is enabled. The second buffer 1012 may receive the first write path signal CSW12 and may be activated when the first write path signal CSW12 is enabled. The third buffer 1013 may receive the second write path signal CSW34 and may be activated when the second write path signal CSW34 is enabled. The fourth buffer 1021 may receive the first read path signal CSR12 and may be activated when the first read path signal CSR12 is enabled. The fifth buffer 1022 may receive the second read path signal CSR34 and may be activated when the second read path signal CSR34 is enabled. The sixth buffer 1023 may receive the read buffer signal CSR and may be activated when the read buffer signal CSR is enabled.

FIG. 12B is a diagram illustrating a configuration of the second data buffering circuit 822 illustrated in FIG. 10. Referring to FIG. 12B, the second data buffering circuit 822 may include a write path selection circuit 1040 and a read path selection circuit 1050. The write path selection circuit 1040 may be connected between the second data bus 702, the third signal transmission lines 712-3, and the fourth signal transmission lines 712-4 and may receive the first and second write path signals CSW12 and CSW34. The write path selection circuit 1040 may output the second data signals DQ<n+1:2n> received through the second data bus 702 as the third memory data signals mDQ1<n+1:2n> to the third signal transmission lines 712-3 when the first write path signal CSW12 is enabled. The write path selection circuit 1040 may output the second data signals DQ<n+1:2n> received through the second data bus 702 as the fourth memory data signals mDQ2<n+1:2n> to the fourth signal transmission lines 712-4 when the second write path signal CSW34 is enabled.

The read path selection circuit 1050 may be connected between the second data bus 702, the third signal transmission lines 712-3, and the fourth signal transmission lines 712-4 and may receive the first and second read path signals CSR12 and CSR34. The read path selection circuit 1050 may output the third memory data signals mDQ1<n+1:2n> transmitted from the third signal transmission lines 712-3 as the second data signals DQ<n+1:2n> to the second data bus 702 when the first read path signal CSR12 is enabled. The read path selection circuit 1050 may output the fourth memory data signals mDQ2<n+1:2n> transmitted from the fourth signal transmission lines 712-4 as the second data signals DQ<n+1:2n> to the second data bus 702 when the second read path signal CSR34 is enabled.

The second data buffering circuit 822 may include a first buffer 1041, a second buffer 1042, a third buffer 1043, a fourth buffer 1051, a fifth buffer 1052, and a sixth buffer 1053. The first buffer 1041 may buffer the second data signals DQ<n+1:2n> and may provide buffered signals to the write path selection circuit 1040. The second buffer 1042 may buffer output signals of the write path selection circuit 1040 and may output buffered signals as the third memory data signals mDQ1<n+1:2n> to the third signal transmission lines 712-3. The third buffer 1043 may buffer output signals of the write path selection circuit 1040 and may output buffered signals as the fourth memory data signals mDQ2<n+1:2n> to the fourth signal transmission lines 712-4. The fourth buffer 1051 may buffer the third memory data signals mDQ1<n+1:2n> and may output buffered signals to the read path selection circuit 1050. The fifth buffer 1052 may buffer the fourth memory data signals mDQ2<n+1:2n> and may output buffered signals to the read path selection circuit 1050. The sixth buffer 1053 may buffer an output signal of the read path selection circuit 1050 and may output buffered signals as the second data signals DQ<n+1:2n> to the second data bus 702.

The first buffer 1041 may receive the write buffer signal CSW and may be activated when the write buffer signal CSW is enabled. The second buffer 1042 may receive the first write path signal CSW12 and may be activated when the first write path signal CSW12 is enabled. The third buffer 1043 may receive the second write path signal CSW34 and may be activated when the second write path signal CSW34 is enabled. The fourth buffer 1051 may receive the first read path signal CSR12 and may be activated when the first read path signal CSR12 is enabled. The fifth buffer 1052 may receive the second read path signal CSR34 and may be activated when the second read path signal CSR34 is enabled. The sixth buffer 1053 may receive the read buffer signal CSR and may be activated when the read buffer signal CSR is enabled.

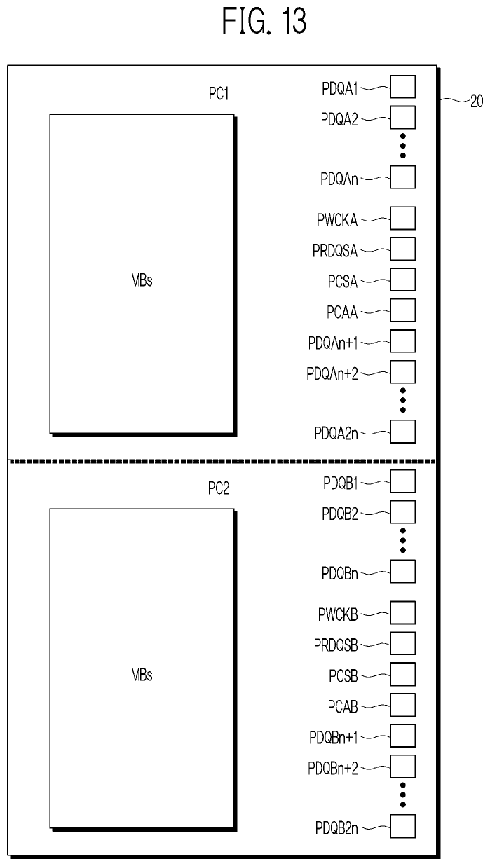

FIG. 13 is a diagram illustrating a configuration of a memory die 20 according to an embodiment of the present disclosure. Referring to FIG. 13, the memory die 20 may include a first pseudo channel PC1 and a second pseudo channel PC2. The first pseudo channel PC1 may include a plurality of memory banks MBs, first data pads PDQA1, PDQA2, . . . , PDQAn, and second data pads PDQAn+1, PDQAn+2, . . . , PDQA2n. The second pseudo channel PC2 may include a plurality of memory banks MBs, third data pads PDQB1, PDQB2, . . . , PDQBn, and fourth data pads PDQBn+1, PDQBn+2, . . . , PDQB2n. The first pseudo channel PC1 may further include a data clock pad PWCKA, a read strobe pad PRDQSA, a chip selection pad PCSA, and a command address pad PCAA. The second pseudo channel PC2 may further include a data clock pad PWCKB, a read strobe pad PRDQSB, a chip selection pad PCSB, and a command address pad PCAB. The first to fourth data pads PDQA1 to PDQA2n and PDQB1 to PDQB2n may each include n data pads. Here, n may be a multiple of 2 and may be, for example, 4, 6, 8, or 12. For example, in the memory die, n may be 6. A memory system to which the memory die 20 is applied may use a data bus composed of 4n signal transmission lines. The first data pads PDQA1, PDQA2, . . . , PDQAn may be connected to first to nth signal transmission lines among the data bus, and the second data pads PDQAn+1, PDQAn+2, . . . , PDQA2n may be connected to n+1th to 2nth signal transmission lines among the data bus. The third data pads PDQB1, PDQB2, . . . , PDQBn may be connected to 2n+1th to 3nth signal transmission lines among the data bus, and the fourth data pads PDQBn+1, PDQBn+2, . . . , PDQB2n may be connected to 3n+1th to 4nth signal transmission lines among the data bus. The first pseudo channel PC1 may receive a data clock signal through the data clock pad PWCKA and may output a read strobe signal through the read strobe pad PRDQSA. The first pseudo channel PC1 may receive a chip selection signal through the chip selection pad PCSA and may receive a command address signal through the command address pad PCAA. The second pseudo channel PC2 may receive a data clock signal through the data clock pad PWCKB and may output a read strobe signal through the read strobe pad PRDQSB. The second pseudo channel PC2 may receive a chip selection signal through the chip selection pad PCSB and may receive a command address signal through the command address pad PCAB.

The memory die 20 may support a plurality of byte modes. For example, the memory die 20 may operate in a first byte mode, a second byte mode, and a third byte mode. In the first byte mode, the memory die 20 may receive n data signals at one time or may output n data signals at one time. In the second byte mode, the memory die 20 may receive 2n data signals at one time or may output 2n data signals at one time. In the third byte mode, the memory die 20 may receive 4n data signals at one time or may output 4n data signals at one time. The memory die 20 may support the first and second byte modes to provide an expanded memory capacity. In the second byte mode, the memory die 20 may store 2n data signals received through the first and second data pads PDQA1 to PDQA2n or the third and fourth data pads PDQB1 to PDQB2n in memory banks MBs of the first and second pseudo channels PC1 and PC2, and therefore a memory apparatus may include two memory dies that are assigned one chip selection signal and are accessed together to provide twice the memory capacity. In the first byte mode, n data signals received through one of the first data pads PDQA1, PDQA2, . . . , PDQAn, the second data pads PDQAn+1, PDQAn+2, . . . , PDQA2n, the third data pads PDQB1, PDQB2, . . . , PDQBn, and the fourth data pads PDQBn+1, PDQBn+2, . . . , PDQB2n may be stored in the memory banks MBs of the first and second pseudo channels PC1 and PC2, and therefore a memory apparatus may include four memory dies that are assigned one chip selection signal and are accessed together to provide four times the memory capacity. To further increase memory capacity, the memory apparatus may include a plurality of ranks, and a plurality of memory dies that constitute different ranks and are assigned different chip selection signals may be connected to one data bus in common to perform data input/output operations. For example, in the second byte mode, the memory apparatus may include four memory dies constituting first and second ranks, two memory dies constituting the first rank may be assigned a first chip selection signal, and two memory dies constituting the second rank may be assigned a second chip selection signal. As the number of ranks included in the memory apparatus increases, the number of memory dies and the number of chip selection signals may also increase proportionally. In addition, in the first byte mode, the memory apparatus may include eight memory dies constituting first and second ranks, four memory dies constituting the first rank may be assigned a first chip selection signal, and four memory dies constituting the second rank may be assigned a second chip selection signal. As the number of ranks included in the memory apparatus increases, the number of memory dies and the number of chip selection signals may also increase proportionally. As the number of ranks and memory dies included in the memory apparatus increases, the number of memory dies connected in common to the data bus increases, and a capacitive load of the data bus may increase. When the capacitive load of the data bus increases, the speed and the data bandwidth of the data bus may decrease, and integrity of data signals propagated through the data bus may deteriorate. Accordingly, an embodiment of the present disclosure provides a memory apparatus capable of reducing a capacitive load of the data bus while increasing memory capacity by increasing the number of ranks and memory dies included in the memory apparatus.

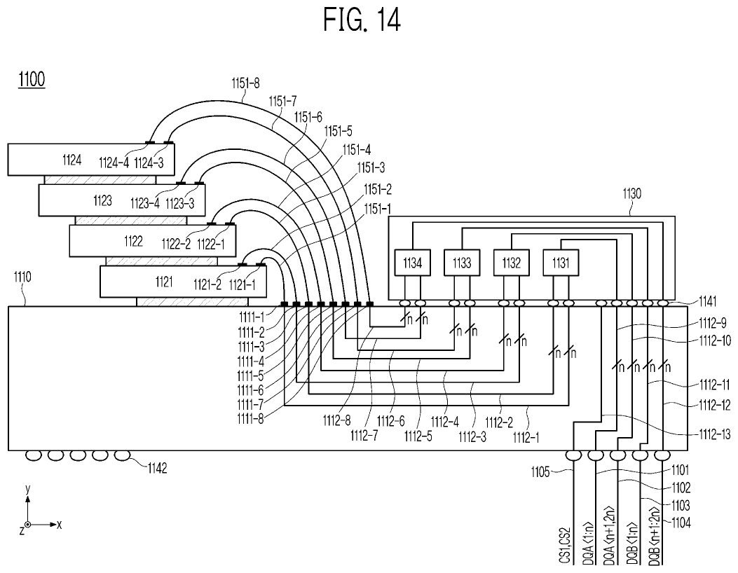

FIG. 14 is a diagram illustrating a configuration of a memory apparatus 1100 according to an embodiment of the present disclosure. Referring to FIG. 14, the memory apparatus 1100 may include a package substrate 1110, a plurality of memory dies, and a buffer die 1130. The plurality of memory dies and the buffer die 1130 may be disposed on the package substrate 1110, and the plurality of memory dies, the buffer die 1130, and the package substrate 1110 may be packaged as a single package to implement a single memory apparatus. The number of memory dies included in the memory apparatus 1100 may be a multiple of two, and the memory apparatus 1100 may include at least a first memory die 1121, a second memory die 1122, a third memory die 1123, and a fourth memory die 1124. The first to fourth memory dies 1121 to 1124 may be sequentially disposed on the package substrate 1110. For example, the first to fourth memory dies 1121 to 1124 may be stacked on the package substrate 1110 in a vertical direction. The first to fourth memory dies 1121 to 1124 may be disposed on the package substrate 1110 in a first region of the package substrate 1110. The first memory die 1121 may be disposed on the package substrate 1110 in a y-axis direction. The second memory die 1122 may be disposed on the first memory die 1121 in the y-axis direction. The third memory die 1123 may be disposed on the second memory die 1122 in the y-axis direction. The fourth memory die 1124 may be disposed on the third memory die 1123 in the y-axis direction. The first memory die 1121 may be bonded to the package substrate 1110 using a die attach film, and the second to fourth memory dies 1122 to 1124 may also be bonded on the first to third memory dies 1121-1123 using the die attach film. The first memory die 1121 may include n first data pads 1121-1, n second data pads 1121-2, n third data pads, and n fourth data pads. For example, n may be 6. The second to fourth memory dies 1122 to 1124 may each include n first data pads 1122-1, n second data pads 1122-2, n third data pads 1123-3 and 1124-3, and n fourth data pads 1123-4 and 1124-4. In FIG. 14, the first and second data pads 1121-1, 1122-1, 1121-2, and 1122-2 of the first and second memory dies 1121 and 1122 are illustrated, and the third and fourth data pads of the first and second memory dies 1121 and 1122 are not illustrated. The third and fourth data pads 1123-3, 1124-3, 1123-4, and 1124-4 of the third and fourth memory dies 1123 and 1124 are illustrated, and the first and second data pads of the third and fourth memory dies 1123 and 1124 are not illustrated.

The second memory die 1122 may be disposed on the first memory die 1121 while being offset in a second direction of an x-axis so that the first and second data pads 1121-1 and 1121-2 of the first memory die 1121 are exposed in a first direction of the x-axis. The second direction may be opposite to the first direction. The third memory die 1123 may be disposed on the second memory die 1122 while being offset in the second direction of the x-axis so that the first and second data pads 1122-1 and 1122-2 of the second memory die 1122 are exposed in the first direction of the x-axis. The fourth memory die 1124 may be disposed on the third memory die 1123 while being offset in the second direction of the x-axis so that the third and fourth data pads 1123-3 and 1123-4 of the third memory die 1123 are exposed in the first direction of the x-axis. Because the fourth memory die 1124 is disposed at the uppermost layer in a y-axis direction, the third and fourth data pads 1124-3 and 1124-4 of the fourth memory die 1124 may be exposed in the first direction of the x-axis. The first to fourth memory dies 1121 to 1124 may each have substantially the same structure as the memory die 20 illustrated in FIG. 13. The first to fourth memory dies 1121 to 1124 may support the second byte mode. The first to fourth memory dies 1121 to 1124 may receive 2n data signals at one time or may output 2n data signals at one time. The first and third memory dies 1121 and 1123 may constitute a first rank and may be assigned the same chip selection signal. The second and fourth memory dies 1122 and 1124 may constitute a second rank and may be assigned the same chip selection signal.

The buffer die 1130 may be disposed on the package substrate 1110 in a second region on the package substrate 1110. The second region might not overlap the first region. The buffer die 1130 may be disposed on the package substrate 1110 in a y-axis direction. The buffer die 1130 may be disposed on the package substrate 1110 in a flip-chip manner and may be electrically connected to signal transmission lines of the package substrate 1110 through bumps 1141. The buffer die 1130 may be connected to a first data bus 1101, a second data bus 1102, a third data bus 1103, and a fourth data bus 1104. First data signals DQA<1:n> may be transmitted through the first data bus 1101, second data signals DQA<n+1:2n> may be transmitted through the second data bus 1102, third data signals DQB<1:n> may be transmitted through the third data bus 1103, and fourth data signals DQB<n+1:2n> may be transmitted through the fourth data bus 1104. The first to fourth data buses 1101 to 1104 may each include n signal transmission lines, and n data signals may be transmitted at one time through each of the first to fourth data buses 1101 to 1104. The buffer die 1130 may connect the first to fourth data buses 1101 to 1104 to the first to fourth memory dies 1121 to 1124. The buffer die 1130 may be further connected to a chip selection bus 1105 and may receive a chip selection signal through the chip selection bus 1105. The buffer die 1130 may connect the first and second data buses 1101 and 1102 to one of the first and second memory dies 1121 and 1122 and may connect the third and fourth data buses 1103 and 1104 to one of the third and fourth memory dies 1123 and 1124 based on the chip selection signal. For example, the chip selection signal may include a first chip selection signal CS1 and a second chip selection signal CS2. When the external apparatus asserts the first chip selection signal CS1, the first and third memory dies 1121 and 1123 may be accessed based on the first chip selection signal CS1. When the external apparatus asserts the second chip selection signal CS2, the second and fourth memory dies 1122 and 1124 may be accessed based on the second chip selection signal CS2. When the first chip selection signal CS1 is asserted, the buffer die 1130 may connect the first and second data buses 1101 and 1102 to the first memory die 1121 and may connect the third and fourth data buses 1103 and 1104 to the third memory die 1123. When the second chip selection signal CS2 is asserted, the buffer die 1130 may connect the first and second data buses 1101 and 1102 to the second memory die 1122 and may connect the third and fourth data buses 1103 and 1104 to the fourth memory die 1124.

The package substrate 1110 may include first pads 1111-1, second pads 1111-2, third pads 1111-3, fourth pads 1111-4, fifth pads 1111-5, sixth pads 1111-6, seventh pads 1111-7, and eighth pads 1111-8. The first to eighth pads 1111-1 to 1111-8 may be formed on the package substrate 1110. The first to eighth pads 1111-1 to 1111-8 may be provided on an upper surface of the package substrate 1110 at a distance spaced apart from the first memory die 1121 in the first direction of the x-axis. The package substrate 1110 may include first signal transmission lines 1112-1, second signal transmission lines 1112-2, third signal transmission lines 1112-3, fourth signal transmission lines 1112-4, fifth signal transmission lines 1112-5, sixth signal transmission lines 1112-6, seventh signal transmission lines 1112-7, and eighth signal transmission lines 1112-8. The first to eighth signal transmission lines 1112-1 to 1112-8 may be wirings inside the package substrate 1110 and may each include n lines. The first signal transmission lines 1112-1 may connect the first pads 1111-1 and the buffer die 1130. The second signal transmission lines 1112-2 may connect the third pads 1111-3 and the buffer die 1130. The third signal transmission lines 1112-3 may connect the second pads 1111-2 and the buffer die 1130. The fourth signal transmission lines 1112-4 may connect the fourth pads 1111-4 and the buffer die 1130. The fifth signal transmission lines 1112-5 may connect the fifth pads 1111-5 and the buffer die 1130. The sixth signal transmission lines 1112-6 may connect the seventh pads 1111-7 and the buffer die 1130. The seventh signal transmission lines 1112-7 may connect the sixth pads 1111-6 and the buffer die 1130. The eighth signal transmission lines 1112-8 may connect the eighth pads 1111-8 and the buffer die 1130. The package substrate 1110 may include a plurality of package balls 1142. The package substrate 1110 may be connected to the first to fourth data buses 1101 to 1104 and the chip selection bus 1105 through the package balls 1142. The package substrate 1110 may further include ninth signal transmission lines 1112-9, tenth signal transmission lines 1112-10, eleventh signal transmission lines 1112-11, twelfth signal transmission lines 1112-12, and thirteenth signal transmission lines 1112-13. The ninth to thirteenth signal transmission lines 1112-9 to 1112-13 may be wirings inside the package substrate 1110. The ninth signal transmission lines 1112-9 may connect the first data bus 1101 and the buffer die 1130, and the ninth signal transmission lines 1112-9 may include n lines. The tenth signal transmission lines 1112-10 may connect the second data bus 1102 and the buffer die 1130, and the tenth signal transmission lines 1112-10 may include n lines. The eleventh signal transmission lines 1112-11 may connect the third data bus 1103 and the buffer die 1130, and the eleventh signal transmission lines 1112-11 may include n lines. The twelfth signal transmission lines 1112-12 may connect the fourth data bus 1104 and the buffer die 1130, and the twelfth signal transmission lines 1112-12 may include n lines. The thirteenth signal transmission lines 1112-13 may connect the chip selection bus 1105 and the buffer die 1130, and the thirteenth signal transmission lines 1112-13 may include the number of lines corresponding to the number of chip selection signals. The buffer die 1130 may be connected to the first to thirteenth signal transmission lines 1112-1 to 1112-13 of the package substrate 1110 through the bumps 1141.

The first data pads 1121-1 of the first memory die 1121 may be connected to the first pads 1111-1. The first data pads 1121-1 of the first memory die 1121 may be connected to the first pads 1111-1 through first bonding wires 1151-1. The number of the first bonding wires 1151-1 may be n. The second data pads 1121-2 of the first memory die 1121 may be connected to the second pads 1111-2. The second data pads 1121-2 of the first memory die 1121 may be connected to the second pads 1111-2 through second bonding wires 1151-2. The number of the second bonding wires 1151-2 may be n. The third and fourth data pads of the first memory die 1121 may have no electrical connection with the package substrate 1110. The first data pads 1122-1 of the second memory die 1122 may be connected to the third pads 1111-3. The first data pads 1122-1 of the second memory die 1122 may be connected to the third pads 1111-3 through third bonding wires 1151-3. The number of the third bonding wires 1151-3 may be n. The second data pads 1122-2 of the second memory die 1122 may be connected to the fourth pads 1111-4. The second data pads 1122-2 of the second memory die 1122 may be connected to the fourth pads 1111-4 through fourth bonding wires 1151-4. The number of the fourth bonding wires 1151-4 may be n. The third and fourth data pads of the second memory die 1122 may have no electrical connection with the package substrate 1110. The third data pads 1123-3 of the third memory die 1123 may be connected to the fifth pads 1111-5. The third data pads 1123-3 of the third memory die 1123 may be connected to the fifth pads 1111-5 through fifth bonding wires 1151-5. The number of the fifth bonding wires 1151-5 may be n. The fourth data pads 1123-4 of the third memory die 1123 may be connected to the sixth pads 1111-6. The fourth data pads 1123-4 of the third memory die 1123 may be connected to the sixth pads 1111-6 through sixth bonding wires 1151-6. The number of the sixth bonding wires 1151-6 may be n. The first and second data pads of the third memory die 1123 may have no electrical connection with the package substrate 1110. The third data pads 1124-3 of the fourth memory die 1124 may be connected to the seventh pads 1111-7. The third data pads 1124-3 of the fourth memory die 1124 may be connected to the seventh pads 1111-7 through seventh bonding wires 1151-7. The number of the seventh bonding wires 1151-7 may be n. The fourth data pads 1124-4 of the fourth memory die 1124 may be connected to the eighth pads 1111-8. The fourth data pads 1124-4 of the fourth memory die 1124 may be connected to the eighth pads 1111-8 through eighth bonding wires 1151-8. The number of the eighth bonding wires 1151-8 may be n. The first and second data pads of the fourth memory die 1124 may have no electrical connection with the package substrate 1110.

The buffer die 1130 may include a first data control circuit 1131, a second data control circuit 1132, a third data control circuit 1133, and a fourth data control circuit 1134. The first data control circuit 1131 may selectively connect the first data bus 1101 to the first and second memory dies 1121 and 1122 by connecting the first data bus 1101 to one of the first and second signal transmission lines 1112-1 and 1112-2 based on the chip selection signal. The second data control circuit 1132 may selectively connect the second data bus 1102 to the first and second memory dies 1121 and 1122 by connecting the second data bus 1102 to one of the third and fourth signal transmission lines 1112-3 and 1112-4 based on the chip selection signal. The third data control circuit 1133 may selectively connect the third data bus 1103 to the third and fourth memory dies 1123 and 1124 by connecting the third data bus 1103 to one of the fifth and sixth signal transmission lines 1112-5 and 1112-6 based on the chip selection signal. The fourth data control circuit 1134 may selectively connect the fourth data bus 1104 to the third and fourth memory dies 1123 and 1124 by connecting the fourth data bus 1104 to one of the seventh and eighth signal transmission lines 1112-7 and 1112-8 based on the chip selection signal. When the first chip selection signal CS1 is asserted, the first data control circuit 1131 may connect the first data bus 1101 to the first signal transmission lines 1112-1, the second data control circuit 1132 may connect the second data bus 1102 to the third signal transmission lines 1112-3, the third data control circuit 1133 may connect the third data bus 1103 to the fifth signal transmission lines 1112-5, and the fourth data control circuit 1134 may connect the fourth data bus 1104 to the seventh signal transmission lines 1112-7. When the second chip selection signal CS2 is asserted, the first data control circuit 1131 may connect the first data bus 1101 to the second signal transmission lines 1112-2, the second data control circuit 1132 may connect the second data bus 1102 to the fourth signal transmission lines 1112-4, the third data control circuit 1133 may connect the third data bus 1103 to the sixth signal transmission lines 1112-6, and the fourth data control circuit 1134 may connect the fourth data bus 1104 to the eighth signal transmission lines 1112-8. The buffer die 1130 may improve the data bandwidth of the data bus and improve the integrity of data signals while increasing a memory capacity of the memory apparatus 1100 by allowing one data bus to be connected to a capacitive load corresponding to one memory die based on the chip selection signal.

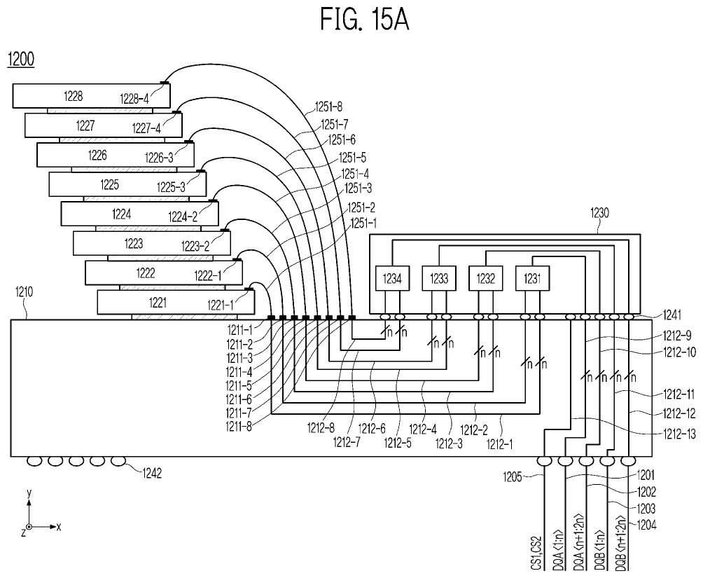

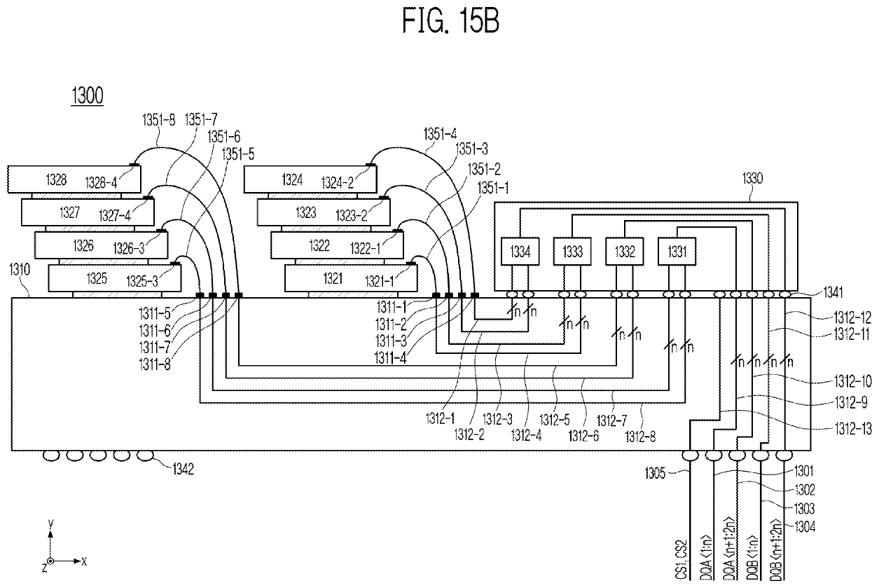

FIG. 15A is a diagram illustrating a configuration of a memory apparatus 1200 according to an embodiment of the present disclosure. Referring to FIG. 15A, the memory apparatus 1200 may include a package substrate 1210, a plurality of memory dies, and a buffer die 1230. The plurality of memory dies and the buffer die 1230 may be disposed on the package substrate 1210, and the plurality of memory dies, the buffer die 1230, and the package substrate 1210 may be packaged as a single package to implement a single memory apparatus. The number of memory dies included in the memory apparatus 1200 may be a multiple of two, and the memory apparatus 1200 may include at least a first memory die 1221, a second memory die 1222, a third memory die 1223, a fourth memory die 1224, a fifth memory die 1225, a sixth memory die 1226, a seventh memory die 1227, and an eighth memory die 1228. The first to eighth memory dies 1221 to 1228 may be sequentially disposed on the package substrate 1210. For example, the first to eight memory dies 1221 to 1228 may be stacked on the package substrate 1210 in a vertical direction. The first to eighth memory dies 1221 to 1228 may be disposed in a first region on the package substrate 1210. The first memory die 1221 may be disposed on the package substrate 1210 in a y-axis direction. The second memory die 1222 may be disposed on the first memory die 1221 in the y-axis direction. The third memory die 1223 may be disposed on the second memory die 1222 in the y-axis direction. The fourth memory die 1224 may be disposed on the third memory die 1223 in the y-axis direction. The fifth memory die 1225 may be disposed on the fourth memory die 1224 in the y-axis direction. The sixth memory die 1226 may be disposed on the fifth memory die 1225 in the y-axis direction. The seventh memory die 1227 may be disposed on the sixth memory die 1226 in the y-axis direction. The eighth memory die 1228 may be disposed on the seventh memory die 1227 in the y-axis direction. The first memory die 1221 may be bonded on the package substrate 1210 using a die attach film, and the second to eighth memory dies 1222 to 1228 may also be bonded on the first to seventh memory dies 1221-1227 using the die attach film. The first memory die 1221 may include n first data pads 1221-1, n second data pads, n third data pads, and n fourth data pads. For example, n may be 6. The second to eighth memory dies 1222 to 1228 may each include n first data pads 1222-1, n second data pads 1223-2 and 1224-2, n third data pads 1225-3 and 1226-3, and n fourth data pads 1227-4 and 1228-4. In FIG. 15A, the first data pads 1221-1 and 1222-1 of the first and second memory dies 1221 and 1222 are illustrated, and the second to fourth data pads of the first and second memory dies 1221 and 1222 are not illustrated. The second data pads 1223-2 and 1224-2 of the third and fourth memory dies 1223 and 1224 are illustrated, and the first, third, and fourth data pads of the third and fourth memory dies 1223 and 1224 are not illustrated. The third data pads 1225-3 and 1226-3 of the fifth and sixth memory dies 1225 and 1226 are illustrated, and the first, second, and fourth data pads of the fifth and sixth memory dies 1225 and 1226 are not illustrated. The fourth data pads 1227-4 and 1228-4 of the seventh and eighth memory dies 1227 and 1228 are illustrated, and the first to third data pads of the seventh and eighth memory dies 1227 and 1228 are not illustrated.

The second memory die 1222 may be disposed on the first memory die 1221 while being offset in a second direction of an x-axis so that the first data pads 1221-1 of the first memory die 1221 may be exposed in a first direction of the x-axis. The second direction may be opposite to the first direction. The third memory die 1223 may be disposed on the second memory die 1222 while being offset in the second direction of the x-axis so that the first data pads 1222-1 of the second memory die 1222 may be exposed in the first direction of the x-axis. The fourth memory die 1224 may be disposed on the third memory die 1223 while being offset in the second direction of the x-axis so that the second data pads 1223-2 of the third memory die 1223 may be exposed in the first direction of the x-axis. The fifth memory die 1225 may be disposed on the fourth memory die 1224 while being offset in the second direction of the x-axis so that the second data pads 1224-2 of the fourth memory die 1224 may be exposed in the first direction of the x-axis. The sixth memory die 1226 may be disposed on the fifth memory die 1225 while being offset in the second direction of the x-axis so that the third data pads 1225-3 of the fifth memory die 1225 may be exposed in the first direction of the x-axis. The seventh memory die 1227 may be disposed on the sixth memory die 1226 while being offset in the second direction of the x-axis so that the third data pads 1226-3 of the sixth memory die 1226 may be exposed in the first direction of the x-axis. The eighth memory die 1228 may be disposed on the seventh memory die 1227 while being offset in the second direction of the x-axis so that the fourth data pads 1227-4 of the seventh memory die 1227 may be exposed in the first direction of the x-axis. Because the eighth memory die 1228 is disposed at the uppermost layer in a y-axis direction, the fourth data pads 1228-4 of the eighth memory die 1228 may be exposed in the first direction of the x-axis.

The first to eighth memory dies 1221 to 1228 may each have a structure substantially identical to the memory die 20 illustrated in FIG. 13. The first to eighth memory dies 1221 to 1228 may support the first byte mode. The first to eighth memory dies 1221 to 1228 may receive n data signals at one time or may output n data signals at one time. The first, third, fifth, and seventh memory dies 1221, 1223, 1225, and 1227 may constitute a first rank and may be assigned the same chip selection signal. The second, fourth, sixth, and eighth memory dies 1222, 1224, 1226, and 1228 may constitute a second rank and may be assigned the same chip selection signal.

The buffer die 1230 may be disposed on the package substrate 1210 in a second region on the package substrate 1210. The second region might not overlap the first region. The buffer die 1230 may be disposed on the package substrate 1210 in a y-axis direction. The buffer die 1230 may be disposed on the package substrate 1210 in a flip-chip manner and may be electrically connected to signal transmission lines of the package substrate 1210 through bumps 1241. The buffer die 1230 may be connected to a first data bus 1201, a second data bus 1202, a third data bus 1203, and a fourth data bus 1204. First data signals DQA<1:n> may be transmitted through the first data bus 1201, second data signals DQA<n+1:2n> may be transmitted through the second data bus 1202, third data signals DQB<1:n> may be transmitted through the third data bus 1203, and fourth data signals DQB<n+1:2n> may be transmitted through the fourth data bus 1204. The first to fourth data buses 1201 to 1204 may each include n signal transmission lines, and n data signals may be transmitted at one time through each of the first to fourth data buses 1201 to 1204. The buffer die 1230 may connect the first to fourth data buses 1201 to 1204 to the first to eighth memory dies 1221-1228. The buffer die 1230 may be further connected to a chip selection bus 1205 and may receive a chip selection signal through the chip selection bus 1205. The buffer die 1230 may connect the first data bus 1201 to one of the first and second memory dies 1221 and 1222 and may connect the second data bus 1202 to one of the third and fourth memory dies 1223 and 1224 based on the chip selection signal. The buffer die 1230 may connect the third data bus 1203 to one of the fifth and sixth memory dies 1225 and 1226 and may connect the fourth data bus 1204 to one of the seventh and eighth memory dies 1227 and 1228 based on the chip selection signal. For example, the chip selection signal may include a first chip selection signal CS1 and a second chip selection signal CS2. When an external apparatus asserts the first chip selection signal CS1, the first, third, fifth, and seventh memory dies 1221, 1223, 1225, and 1227 may be accessed based on the first chip selection signal CS1. When the external apparatus asserts the second chip selection signal CS2, the second, fourth, sixth, and eighth memory dies 1222, 1224, 1226, and 1228 may be accessed based on the second chip selection signal CS2. When the first chip selection signal CS1 is asserted, the buffer die 1230 may connect the first data bus 1201 to the first memory die 1221, may connect the second data bus 1202 to the third memory die 1223, may connect the third data bus 1203 to the fifth memory die 1225, and may connect the fourth data bus 1204 to the seventh memory die 1227. When the second chip selection signal CS2 is asserted, the buffer die 1230 may connect the first data bus 1201 to the second memory die 1222, may connect the second data bus 1202 to the fourth memory die 1224, may connect the third data bus 1203 to the sixth memory die 1226, and may connect the fourth data bus 1204 to the eighth memory die 1228.

The package substrate 1210 may include first pads 1211-1, second pads 1211-2, third pads 1211-3, fourth pads 1211-4, fifth pads 1211-5, sixth pads 1211-6, seventh pads 1211-7, and eighth pads 1211-8. The first to eighth pads 1211-1 to 1211-8 may be formed on the package substrate 1210. The first to eighth pads 1211-1 to 1211-8 may be spaced apart from the first memory die 1221 in the first direction of an x-axis and may be provided on an upper surface of the package substrate 1210 between the first memory die 1221 and the buffer die 1230. The package substrate 1210 may include first signal transmission lines 1212-1, second signal transmission lines 1212-2, third signal transmission lines 1212-3, fourth signal transmission lines 1212-4, fifth signal transmission lines 1212-5, sixth signal transmission lines 1212-6, seventh signal transmission lines 1212-7, and eighth signal transmission lines 1212-8. The first to eighth signal transmission lines 1212-1 to 1212-8 may be wirings inside the package substrate 1210 and may each include n lines. The first signal transmission lines 1212-1 may connect the first pads 1211-1 and the buffer die 1230. The second signal transmission lines 1212-2 may connect the second pads 1211-2 and the buffer die 1230. The third signal transmission lines 1212-3 may connect the third pads 1211-3 and the buffer die 1230. The fourth signal transmission lines 1212-4 may connect the fourth pads 1211-4 and the buffer die 1230. The fifth signal transmission lines 1212-5 may connect the fifth pads 1211-5 and the buffer die 1230. The sixth signal transmission lines 1212-6 may connect the sixth pads 1211-6 and the buffer die 1230. The seventh signal transmission lines 1212-7 may connect the seventh pads 1211-7 and the buffer die 1230. The eighth signal transmission lines 1212-8 may connect the eighth pads 1211-8 and the buffer die 1230. The package substrate 1210 may include a plurality of package balls 1242. The package substrate 1210 may be connected to the first to fourth data buses 1201 to 1204 and the chip selection bus 1205 through the package balls 1242. The package substrate 1210 may further include ninth signal transmission lines 1212-9, tenth signal transmission lines 1212-10, eleventh signal transmission lines 1212-11, twelfth signal transmission lines 1212-12, and thirteenth signal transmission lines 1212-13. The ninth to thirteenth signal transmission lines 1212-9 to 1212-13 may be wirings inside the package substrate 1210. The ninth signal transmission lines 1212-9 may connect the first data bus 1201 and the buffer die 1230, and the ninth signal transmission lines 1212-9 may include n lines. The tenth signal transmission lines 1212-10 may connect the second data bus 1202 and the buffer die 1230, and the tenth signal transmission lines 1212-10 may include n lines. The eleventh signal transmission lines 1212-11 may connect the third data bus 1203 and the buffer die 1230, and the eleventh signal transmission lines 1212-11 may include n lines. The twelfth signal transmission lines 1212-12 may connect the fourth data bus 1204 and the buffer die 1230, and the twelfth signal transmission lines 1212-12 may include n lines. The thirteenth signal transmission lines 1212-13 may connect the chip selection bus 1205 and the buffer die 1230 and may include the number of lines corresponding to the number of chip selection signals. The buffer die 1230 may be connected to the first to thirteenth signal transmission lines 1212-1 to 1212-13 of the package substrate 1210 through bumps 1241.

The first data pads 1221-1 of the first memory die 1221 may be connected to the first pads 1211-1. The first data pads 1221-1 of the first memory die 1221 may be connected to the first pads 1211-1 through first bonding wires 1251-1. The number of the first bonding wires 1251-1 may be n. The first data pads 1222-1 of the second memory die 1222 may be connected to the second pads 1211-2. The first data pads 1222-1 of the second memory die 1222 may be connected to the second pads 1211-2 through second bonding wires 1251-2. The number of the second bonding wires 1251-2 may be n. The second to fourth data pads of the first and second memory dies 1221 and 1222 might not have any electrical connection with the package substrate 1210. The second data pads 1223-2 of the third memory die 1223 may be connected to the third pads 1211-3. The second data pads 1223-2 of the third memory die 1223 may be connected to the third pads 1211-3 through third bonding wires 1251-3. The number of the third bonding wires 1251-3 may be n. The second data pads 1224-2 of the fourth memory die 1224 may be connected to the fourth pads 1211-4. The second data pads 1224-2 of the fourth memory die 1224 may be connected to the fourth pads 1211-4 through fourth bonding wires 1251-4. The number of the fourth bonding wires 1251-4 may be n. The first, third, and fourth data pads of the third and fourth memory dies 1223 and 1224 might not have any electrical connection with the package substrate 1210. The third data pads 1225-3 of the fifth memory die 1225 may be connected to the fifth pads 1211-5. The third data pads 1225-3 of the fifth memory die 1225 may be connected to the fifth pads 1211-5 through fifth bonding wires 1251-5. The number of the fifth bonding wires 1251-5 may be n. The third data pads 1226-3 of the sixth memory die 1226 may be connected to the sixth pads 1211-6. The third data pads 1226-3 of the sixth memory die 1226 may be connected to the sixth pads 1211-6 through sixth bonding wires 1251-6. The number of the sixth bonding wires 1251-6 may be n. The first, second, and fourth data pads of the fifth and sixth memory dies 1225 and 1226 might not have any electrical connection with the package substrate 1210. The fourth data pads 1227-4 of the seventh memory die 1227 may be connected to the seventh pads 1211-7. The fourth data pads 1227-4 of the seventh memory die 1227 may be connected to the seventh pads 1211-7 through seventh bonding wires 1251-7. The number of the seventh bonding wires 1251-7 may be n. The fourth data pads 1228-4 of the eighth memory die 1228 may be connected to the eighth pads 1211-8. The fourth data pads 1228-4 of the eighth memory die 1228 may be connected to the eighth pads 1211-8 through eighth bonding wires 1251-8. The number of the eighth bonding wires 1251-8 may be n. The first to third data pads of the seventh and eighth memory dies 1227 and 1228 might not have any electrical connection with the package substrate 1210.

The buffer die 1230 may include a first data control circuit 1231, a second data control circuit 1232, a third data control circuit 1233, and a fourth data control circuit 1234. The first data control circuit 1231 may selectively connect the first data bus 1201 to the first and second memory dies 1221 and 1222 by connecting the first data bus 1201 to one of the first and second signal transmission lines 1212-1 and 1212-2 based on the chip selection signal. The second data control circuit 1232 may selectively connect the second data bus 1202 to the third and fourth memory dies 1223 and 1224 by connecting the second data bus 1202 to one of the third and fourth signal transmission lines 1212-3 and 1212-4 based on the chip selection signal. The third data control circuit 1233 may selectively connect the third data bus 1203 to the fifth and sixth memory dies 1225 and 1226 by connecting the third data bus 1203 to one of the fifth and sixth signal transmission lines 1212-5 and 1212-6 based on the chip selection signal. The fourth data control circuit 1234 may selectively connect the fourth data bus 1204 to the seventh and eighth memory dies 1227 and 1228 by connecting the fourth data bus 1204 to one of the seventh and eighth signal transmission lines 1212-7 and 1212-8 based on the chip selection signal. When the first chip selection signal CS1 is asserted, the first data control circuit 1231 may connect the first data bus 1201 to the first signal transmission lines 1212-1, the second data control circuit 1232 may connect the second data bus 1202 to the third signal transmission lines 1212-3, the third data control circuit 1233 may connect the third data bus 1203 to the fifth signal transmission lines 1212-5, and the fourth data control circuit 1234 may connect the fourth data bus 1204 to the seventh signal transmission lines 1212-7. When the second chip selection signal CS2 is asserted, the first data control circuit 1231 may connect the first data bus 1201 to the second signal transmission lines 1212-2, the second data control circuit 1232 may connect the second data bus 1202 to the fourth signal transmission lines 1212-4, the third data control circuit 1233 may connect the third data bus 1203 to the sixth signal transmission lines 1212-6, and the fourth data control circuit 1234 may connect the fourth data bus 1204 to the eighth signal transmission lines 1212-8. The buffer die 1230 may connect one data bus to a capacitive load corresponding to one memory die based on the chip selection signal, thereby increasing a memory capacity of the memory apparatus 1200 while improving the data bandwidth of the data bus and improving the integrity of data signals.

FIG. 15B is a diagram illustrating a configuration of a memory apparatus 1300 according to an embodiment of the present disclosure. Referring to FIG. 15B, the memory apparatus 1300 may perform substantially the same function as the memory apparatus 1200 of FIG. 15A but may have a different structure. The memory apparatus 1300 may include a package substrate 1310, a plurality of memory dies, and a buffer die 1330. The plurality of memory dies and the buffer die 1330 may be disposed on the package substrate 1310, and the plurality of memory dies, the buffer die 1330, and the package substrate 1310 may be packaged as a single package to implement a single memory apparatus. The memory apparatus 1300 may include at least a first memory die 1321, a second memory die 1322, a third memory die 1323, a fourth memory die 1324, a fifth memory die 1325, a sixth memory die 1326, a seventh memory die 1327, and an eighth memory die 1328. The first to fourth memory dies 1321 to 1324 may be sequentially disposed on the package substrate 1310. For example, the first to fourth memory dies 1321 to 1324 may be stacked on the package substrate 1310 in a vertical direction in a first region on the package substrate 1310. The first memory die 1321 may be disposed on the package substrate 1310 in a direction of a y-axis. The second memory die 1322 may be disposed on the first memory die 1321 in the direction of the y-axis. The third memory die 1323 may be disposed on the second memory die 1322 in the direction of the y-axis. The fourth memory die 1324 may be disposed on the third memory die 1323 in the direction of the y-axis. The fifth to eighth memory dies 1325 to 1328 may be sequentially disposed on the package substrate 1310. For example, the fifth to eight memory dies 1325 to 1328 may be stacked on the package substrate 1310 in a vertical direction in a second region on the package substrate 1310. The second region might not overlap the first region. The fifth memory die 1325 may be disposed on the package substrate 1310 in the direction of the y-axis. The sixth memory die 1326 may be disposed on the fifth memory die 1325 in the direction of the y-axis. The seventh memory die 1327 may be disposed on the sixth memory die 1326 in the direction of the y-axis. The eighth memory die 1328 may be disposed on the seventh memory die 1327 in the direction of the y-axis. The first and fifth memory dies 1321 and 1325 may be bonded to the package substrate 1310 using a die attach film, respectively, and the second to fourth memory dies 1322-1324 may be bonded to the first to third memory dies 1321-1323 using the die attach film, respectively, and the sixth to eighth memory dies 1326-1328 may be bonded to the fifth to seventh memory dies 1325-1327 using the die attach film, respectively. The first memory die 1321 may include n first data pads 1321-1, n second data pads, n third data pads, and n fourth data pads. For example, n may be 6. Each of the second to eighth memory dies 1322-1328 may also include n first data pads 1322-1, n second data pads 1323-2 and 1324-2, n third data pads 1325-3 and 1326-3, and n fourth data pads 1327-4 and 1328-4. In FIG. 15B, the first data pads 1321-1 and 1322-1 of the first and second memory dies 1321 and 1322 are illustrated, and the second to fourth data pads of the first and second memory dies 1321 and 1322 are not illustrated. The second data pads 1323-2 and 1324-2 of the third and fourth memory dies 1323 and 1324 are illustrated, and the first, third, and fourth data pads of the third and fourth memory dies 1323 and 1324 are not illustrated. The third data pads 1325-3 and 1326-3 of the fifth and sixth memory dies 1325 and 1326 are illustrated, and the first, second, and fourth data pads of the fifth and sixth memory dies 1325 and 1326 are not illustrated. The fourth data pads 1327-4 and 1328-4 of the seventh and eighth memory dies 1327 and 1328 are illustrated, and the first to third data pads of the seventh and eighth memory dies 1327 and 1328 are not illustrated.

The second memory die 1322 may be disposed on the first memory die 1321 while being offset in a second direction of an x-axis such that the first data pads 1321-1 of the first memory die 1321 may be exposed in a first direction of the x-axis. The second direction may be opposite to the first direction. The third memory die 1323 may be disposed on the second memory die 1322 while being offset in the second direction of the x-axis such that the first data pads 1322-1 of the second memory die 1322 may be exposed in the first direction of the x-axis. The fourth memory die 1324 may be disposed on the third memory die 1323 while being offset in the second direction of the x-axis such that the second data pads 1323-2 of the third memory die 1323 may be exposed in the first direction of the x-axis. Because the fourth memory die 1324 is disposed at the uppermost layer in a direction of a y-axis, the second data pads 1324-2 of the fourth memory die 1324 may be exposed in the first direction of the x-axis. The sixth memory die 1326 may be disposed on the fifth memory die 1325 while being offset in the second direction of the x-axis such that the third data pads 1325-3 of the fifth memory die 1325 may be exposed in the first direction of the x-axis. The seventh memory die 1327 may be disposed on the sixth memory die 1326 while being offset in the second direction of the x-axis such that the third data pads 1326-3 of the sixth memory die 1326 may be exposed in the first direction of the x-axis. The eighth memory die 1328 may be disposed on the seventh memory die 1327 while being offset in the second direction of the x-axis such that the fourth data pads 1327-4 of the seventh memory die 1327 may be exposed in the first direction of the x-axis. Because the eighth memory die 1328 is disposed at the uppermost layer in the direction of the y-axis, the fourth data pads 1328-4 of the eighth memory die 1328 may be exposed in the first direction of the x-axis.

The first to eighth memory dies 1321-1328 may each have substantially the same structure as the memory die 20 illustrated in FIG. 13. The first to eighth memory dies 1321-1328 may support the first byte mode. The first to eighth memory dies 1321-1328 may receive n data signals or output n data signals at one time. The first, third, fifth, and seventh memory dies 1321, 1323, 1325, and 1327 may constitute a first rank and may be assigned the same chip selection signal. The second, fourth, sixth, and eighth memory dies 1322, 1324, 1326, and 1328 may constitute a second rank and may be assigned the same chip selection signal.

The buffer die 1330 may be disposed on the package substrate 1310 in a third region on the package substrate 1310. The third region might not overlap the first region or the second region. In an embodiment, a distance from the third region to the first region and a distance from the third region to the second region may be substantially the same. The buffer die 1330 may be disposed on the package substrate 1310 in a direction of a y-axis. The buffer die 1330 may be disposed on the package substrate 1310 in a flip-chip manner and may be electrically connected to signal transmission lines of the package substrate 1310 through bumps 1341. The buffer die 1330 may be connected to a first data bus 1301, a second data bus 1302, a third data bus 1303, and a fourth data bus 1304. First data signals DQA<1:n> may be transmitted through the first data bus 1301, second data signals DQA<n+1:2n> may be transmitted through the second data bus 1302, third data signals DQB<1:n> may be transmitted through the third data bus 1303, and fourth data signals DQB<n+1:2n> may be transmitted through the fourth data bus 1304. The buffer die 1330 may be further connected to a chip selection bus 1305 and may receive a chip selection signal through the chip selection bus 1305. The chip selection signal may include a first chip selection signal CS1 and a second chip selection signal CS2.

The package substrate 1310 may include first pads 1311-1, second pads 1311-2, third pads 1311-3, fourth pads 1311-4, fifth pads 1311-5, sixth pads 1311-6, seventh pads 1311-7, and eighth pads 1311-8. The first to eighth pads 1311-1 to 1311-8 may be formed on the package substrate 1310. The first to fourth pads 1311-1 to 1311-4 may be provided on an upper surface of the package substrate 1310 between the first region and the third region, and the fifth to eighth pads 1311-5 to 1311-8 may be provided on the upper surface of the package substrate 1310 between the second region and the third region. The package substrate 1310 may include first signal transmission lines 1312-1, second signal transmission lines 1312-2, third signal transmission lines 1312-3, fourth signal transmission lines 1312-4, fifth signal transmission lines 1312-5, sixth signal transmission lines 1312-6, seventh signal transmission lines 1312-7, and eighth signal transmission lines 1312-8. The first to eighth signal transmission lines 1312-1 to 1312-8 may be wirings inside the package substrate 1310 and may each include n lines. The first signal transmission lines 1312-1 may connect the first pads 1311-1 and the buffer die 1330. The second signal transmission lines 1312-2 may connect the second pads 1311-2 and the buffer die 1330. The third signal transmission lines 1312-3 may connect the third pads 1311-3 and the buffer die 1330. The fourth signal transmission lines 1312-4 may connect the fourth pads 1311-4 and the buffer die 1330. The fifth signal transmission lines 1312-5 may connect the fifth pads 1311-5 and the buffer die 1330. The sixth signal transmission lines 1312-6 may connect the sixth pads 1311-6 and the buffer die 1330. The seventh signal transmission lines 1312-7 may connect the seventh pads 1311-7 and the buffer die 1330. The eighth signal transmission lines 1312-8 may connect the eighth pads 1311-8 and the buffer die 1330. The package substrate 1310 may include a plurality of package balls 1342. The package substrate 1310 may be connected to the first to fourth data buses 1301 to 1304 and the chip selection bus 1305 through the package balls 1342. The package substrate 1310 may further include ninth signal transmission lines 1312-9, tenth signal transmission lines 1312-10, eleventh signal transmission lines 1312-11, twelfth signal transmission lines 1312-12, and thirteenth signal transmission lines 1312-13. The ninth to thirteenth signal transmission lines 1312-9 to 1312-13 may be wirings inside the package substrate 1310. The ninth signal transmission lines 1312-9 may connect the first data bus 1301 and the buffer die 1330, and the ninth signal transmission lines 1312-9 may include n lines. The tenth signal transmission lines 1312-10 may connect the second data bus 1302 and the buffer die 1330, and the tenth signal transmission lines 1312-10 may include n lines. The eleventh signal transmission lines 1312-11 may connect the third data bus 1303 and the buffer die 1330, and the eleventh signal transmission lines 1312-11 may include n lines. The twelfth signal transmission lines 1312-12 may connect the fourth data bus 1304 and the buffer die 1330, and the twelfth signal transmission lines 1312-12 may include n lines. The thirteenth signal transmission lines 1312-13 may connect the chip selection bus 1305 and the buffer die 1330 and may include the number of lines corresponding to the number of chip selection signals. The buffer die 1330 may be connected to the first to thirteenth signal transmission lines 1312-1 to 1312-13 of the package substrate 1310 through bumps 1341.

The first data pads 1321-1 of the first memory die 1321 may be connected to the first pads 1311-1. The first data pads 1321-1 of the first memory die 1321 may be connected to the first pads 1311-1 through first bonding wires 1351-1. The number of the first bonding wires 1351-1 may be n. The first data pads 1322-1 of the second memory die 1322 may be connected to the second pads 1311-2. The first data pads 1322-1 of the second memory die 1322 may be connected to the second pads 1311-2 through second bonding wires 1351-2. The number of the second bonding wires 1351-2 may be n. The second to fourth data pads of the first and second memory dies 1321 and 1322 might not have any electrical connection with the package substrate 1310. The second data pads 1323-2 of the third memory die 1323 may be connected to the third pads 1311-3. The second data pads 1323-2 of the third memory die 1323 may be connected to the third pads 1311-3 through third bonding wires 1351-3. The number of the third bonding wires 1351-3 may be n. The second data pads 1324-2 of the fourth memory die 1324 may be connected to the fourth pads 1311-4. The second data pads 1324-2 of the fourth memory die 1324 may be connected to the fourth pads 1311-4 through fourth bonding wires 1351-4. The number of the fourth bonding wires 1351-4 may be n. The first, third, and fourth data pads of the third and fourth memory dies 1323 and 1324 might not have any electrical connection with the package substrate 1310. The third data pads 1325-3 of the fifth memory die 1325 may be connected to the fifth pads 1311-5. The third data pads 1325-3 of the fifth memory die 1325 may be connected to the fifth pads 1311-5 through fifth bonding wires 1351-5. The number of the fifth bonding wires 1351-5 may be n. The third data pads 1326-3 of the sixth memory die 1326 may be connected to the sixth pads 1311-6. The third data pads 1326-3 of the sixth memory die 1326 may be connected to the sixth pads 1311-6 through sixth bonding wires 1351-6. The number of the sixth bonding wires 1351-6 may be n. The first, second, and fourth data pads of the fifth and sixth memory dies 1325 and 1326 might not have any electrical connection with the package substrate 1310. The fourth data pads 1327-4 of the seventh memory die 1327 may be connected to the seventh pads 1311-7. The fourth data pads 1327-4 of the seventh memory die 1327 may be connected to the seventh pads 1311-7 through seventh bonding wires 1351-7. The number of the seventh bonding wires 1351-7 may be n. The fourth data pads 1328-4 of the eighth memory die 1328 may be connected to the eighth pads 1311-8 through eighth bonding wires 1351-8. The number of the eighth bonding wires 1351-8 may be n. The first to third data pads of the seventh and eighth memory dies 1327 and 1328 might not have any electrical connection with the package substrate 1310.

The buffer die 1330 may include a first data control circuit 1331, a second data control circuit 1332, a third data control circuit 1333, and a fourth data control circuit 1334. The first data control circuit 1331 may selectively connect the first data bus 1301 to the first and second memory dies 1321 and 1322 by connecting the first data bus 1301 to one of the first and second signal transmission lines 1312-1 and 1312-2 based on the chip selection signal. The second data control circuit 1332 may selectively connect the second data bus 1302 to the third and fourth memory dies 1323 and 1324 by connecting the second data bus 1302 to one of the third and fourth signal transmission lines 1312-3 and 1312-4 based on the chip selection signal. The third data control circuit 1333 may selectively connect the third data bus 1303 to the fifth and sixth memory dies 1325 and 1326 by connecting the third data bus 1303 to one of the fifth and sixth signal transmission lines 1312-5 and 1312-6 based on the chip selection signal. The fourth data control circuit 1334 may selectively connect the fourth data bus 1304 to the seventh and eighth memory dies 1327 and 1328 by connecting the fourth data bus 1304 to one of the seventh and eighth signal transmission lines 1312-7 and 1312-8 based on the chip selection signal. When the first chip selection signal CS1 is asserted, the first data control circuit 1331 may connect the first data bus 1301 to the first signal transmission lines 1312-1, the second data control circuit 1332 may connect the second data bus 1302 to the third signal transmission lines 1312-3, the third data control circuit 1333 may connect the third data bus 1303 to the fifth signal transmission lines 1312-5, and the fourth data control circuit 1334 may connect the fourth data bus 1304 to the seventh signal transmission lines 1312-7. When the second chip selection signal CS2 is asserted, the first data control circuit 1331 may connect the first data bus 1301 to the second signal transmission lines 1312-2, the second data control circuit 1332 may connect the second data bus 1302 to the fourth signal transmission lines 1312-4, the third data control circuit 1333 may connect the third data bus 1303 to the sixth signal transmission lines 1312-6, and the fourth data control circuit 1334 may connect the fourth data bus 1304 to the eighth signal transmission lines 1312-8. The buffer die 1330 may connect one data bus to a capacitive load corresponding to one memory die based on the chip selection signal, thereby increasing a memory capacity of the memory apparatus while improving the data bandwidth of the data bus and improving the integrity of data signals.

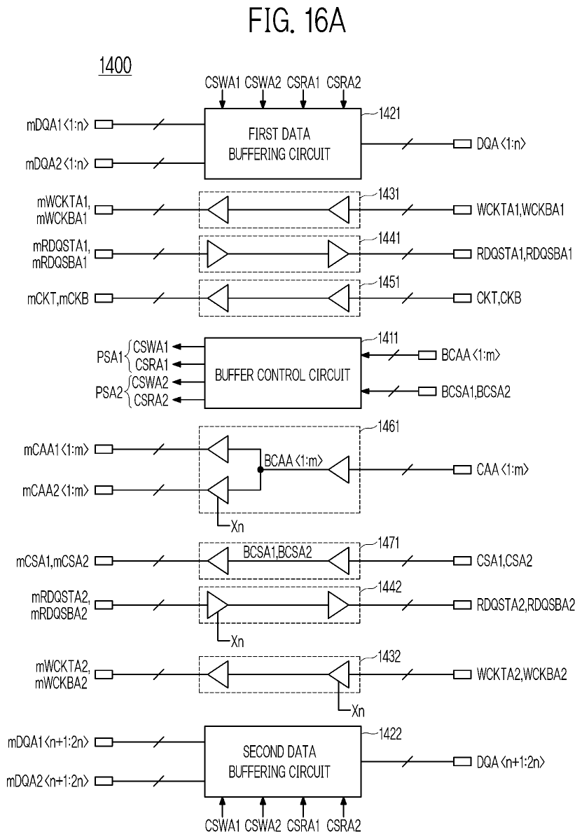

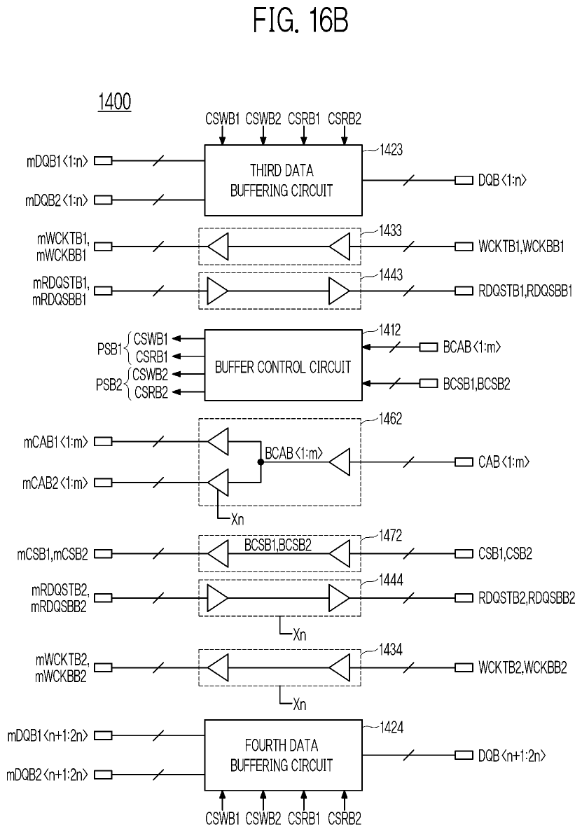

FIGS. 16A and 16B are diagrams illustrating a configuration of a buffer die 1400 according to an embodiment of the present disclosure. The buffer dies 1130, 1230, and 1330 illustrated in FIGS. 14, 15A, and 15B may each be implemented as the buffer die 1400 illustrated in FIGS. 16A and 16B. FIG. 16A illustrates components of the buffer die 1400 that are connected to a first pseudo channel of a memory die, and FIG. 16B illustrates components of the buffer die 1400 that are connected to a second pseudo channel of the memory die. In FIGS. 16A and 16B, signals transmitted between the buffer die 1400 and an external apparatus have substantially the same characteristics as signals transmitted between the buffer die 1400 and memory dies. However, for clarity of description, the term “memory” is additionally included in names of signals transmitted between the buffer die 1400 and the memory dies, and “m” is additionally included in reference numerals of those signals. In addition, the letter “A” is included in reference numerals of signals connected to the first pseudo channel, and the letter “B” is included in reference numerals of signals connected to the second pseudo channel. Signals having the same characteristics use the same names but are assigned different reference numerals depending on whether they are connected to the first pseudo channel or the second pseudo channel, and signals having different characteristics use different names.

Referring to FIG. 16A, the buffer die 1400 may include a first buffer control circuit 1411, a first data buffering circuit 1421, and a second data buffering circuit 1422. The first data buffering circuit 1421 may constitute the first data control circuits 1131, 1231, and 1331 illustrated in FIGS. 14, 15A, and 15B, and the second data buffering circuit 1422 may constitute the second data control circuits 1132, 1232, and 1332 illustrated in FIGS. 14, 15A, and 15B. The first buffer control circuit 1411 may be provided in one of the first and second data control circuits or may be provided between the first and second data control circuits. The first buffer control circuit 1411 may generate a first path selection signal PSA1 and a second path selection signal PSA2 based on a command address signal CAA<1:m> and chip selection signals CSA1 and CSA2. The first buffer control circuit 1411 may receive a buffered command address signal BCAA<1:m> generated by buffering the command address signal CAA<1:m> and a first buffered chip selection signal BCSA1 and a second buffered chip selection signal BCSA2 generated by buffering the first and second chip selection signals CSA1 and CSA2, and may generate the first and second path selection signals PSA1 and PSA2. The first buffer control circuit 1411 may enable the first path selection signal PSA1 when the first chip selection signal CSA1 is asserted. The first buffer control circuit 1411 may enable the second path selection signal PSA2 when the second chip selection signal CSA2 is asserted. The command address signal CAA<1:m> may include a write command and a read command. The first path selection signal PSA1 may include a first write path signal CSWA1 and a first read path signal CSRA1, and the second path selection signal PSA2 may include a second write path signal CSWA2 and a second read path signal CSRA2. The first buffer control circuit 1411 may enable the first write path signal CSWA1 when the write command and the first chip selection signal CSA1 are asserted. The first buffer control circuit 1411 may enable the second write path signal CSWA2 when the write command and the second chip selection signal CSA2 are asserted. The first buffer control circuit 1411 may enable the first read path signal CSRA1 when the read command and the first chip selection signal CSA1 are asserted. The first buffer control circuit 1411 may enable the second read path signal CSRA2 when the read command and the second chip selection signal CSA2 are asserted. The first buffer control circuit 1411 may include substantially the same configuration as the buffer control circuit 211 illustrated in FIG. 4 except for types of input signals and output signals.

The first data buffering circuit 1421 may receive the first and second path selection signals PSA1 and PSA2 from the first buffer control circuit 1411. The first data buffering circuit 1421 may be connected to the first data bus 1101, 1201, or 1301, the first signal transmission lines 1112-1, 1212-1, or 1312-1, and the second signal transmission lines 1112-2, 1212-2, or 1312-2. The first data buffering circuit 1421 may connect the first data bus to the first signal transmission lines when the first path selection signal PSA1 is enabled. The first data buffering circuit 1421 may connect the first data bus to the second signal transmission lines when the second path selection signal PSA2 is enabled. First data signals DQA<1:n> may propagate through the first data bus, first memory data signals mDQA1<1:n> may propagate through the first signal transmission lines, and second memory data signals mDQA2<1:n> may propagate through the second signal transmission lines. The first data buffering circuit 1421 may receive the first data signals DQA<1:n> transmitted from an external apparatus and may output the first data signals DQA<1:n> as the first memory data signals mDQA1<1:n> when the first write path signal CSWA1 is enabled. The first data buffering circuit 1421 may receive the first data signals DQA<1:n> transmitted from the external apparatus and may output the first data signals DQA<1:n> as the second memory data signals mDQA2<1:n> when the second write path signal CSWA2 is enabled. The first data buffering circuit 1421 may receive the first memory data signals mDQA1<1:n> and may output the first memory data signals mDQA1<1:n> as the first data signals DQA<1:n> to the external apparatus when the first read path signal CSRA1 is enabled. The first data buffering circuit 1421 may receive the second memory data signals mDQA2<1:n> and may output the second memory data signals mDQA2<1:n> as the first data signals DQA<1:n> to the external apparatus when the second read path signal CSRA2 is enabled. The first data buffering circuit 1421 may include substantially the same configuration as the first data buffering circuit 221 illustrated in FIG. 4A except for types of input signals and output signals. When the buffer die 1400 is applied to the memory apparatus 1100 illustrated in FIG. 14 in the second byte mode, the first memory data signals mDQA1<1:n> may be transmitted between the first data buffering circuit 1421 and the first data pads 1121-1 of the first memory die 1121, and the second memory data signals mDQA2<1:n> may be transmitted between the first data buffering circuit 1421 and the first data pads 1122-1 of the second memory die 1122. When the buffer die 1400 is applied to the memory apparatuses 1200 and 1300 illustrated in FIGS. 15A and 15B in the first byte mode, the first memory data signals mDQA1<1:n> may be transmitted between the first data buffering circuit 1421 and the first data pads 1221-1 and 1321-1 of the first memory dies 1221 and 1321, and the second memory data signals mDQA2<1:n> may be transmitted between the first data buffering circuit 1421 and the first data pads 1222-1 and 1322-1 of the second memory dies 1222 and 1322.

The second data buffering circuit 1422 may receive the first and second path selection signals PSA1 and PSA2 from the first buffer control circuit 1411. The second data buffering circuit 1422 may be connected to the second data bus 1102, 1202, or 1302, the third signal transmission lines 1112-3, 1212-3, or 1312-3, and the fourth signal transmission lines 1112-4, 1212-4, or 1312-4. The second data buffering circuit 1422 may connect the second data bus to the third signal transmission lines when the first path selection signal PSA1 is enabled. The second data buffering circuit 1422 may connect the second data bus to the fourth signal transmission lines when the second path selection signal PSA2 is enabled. Second data signals DQA<n+1:2n> may propagate through the second data bus, third memory data signals mDQA1<n+1:2n> may propagate through the third signal transmission lines, and fourth memory data signals mDQA2<n+1:2n> may propagate through the fourth h signal transmission lines. The second data buffering circuit 1422 may receive the second data signals DQA<n+1:2n> transmitted from an external apparatus and may output the second data signals DQA<n+1:2n> as the third memory data signals mDQA1<n+1:2n> when the first write path signal CSWA1 is enabled. The second data buffering circuit 1422 may receive the second data signals DQA<n+1:2n> transmitted from the external apparatus and may output the second data signals DQA<n+1:2n> as the fourth memory data signals mDQA2<n+1:2n> when the second write path signal CSWA2 is enabled. The second data buffering circuit 1422 may receive the third memory data signals mDQA1<n+1:2n> and may output the third memory data signals mDQA1<n+1:2n> as the second data signals DQA<n+1:2n> to the external apparatus when the first read path signal CSRA1 is enabled. The second data buffering circuit 1422 may receive the fourth memory data signals mDQA2<n+1:2n> and may output the fourth memory data signals mDQA2<n+1:2n> as the second data signals DQA<n+1:2n> to the external apparatus when the second read path signal CSRA2 is enabled. The second data buffering circuit 1422 may include substantially the same configuration as the second data buffering circuit 222 illustrated in FIG. 5B except for types of input signals and output signals. When the buffer die 1400 is applied to the memory apparatus 1100 illustrated in FIG. 14 in the second byte mode, the third memory data signals mDQA1<n+1:2n> may be transmitted between the second data buffering circuit 1422 and the second data pads 1121-2 of the first memory die 1121, and the fourth memory data signals mDQA2<n+1:2n> may be transmitted between the second data buffering circuit 1422 and the second data pads 1122-2 of the second memory die 1122. When the buffer die 1400 is applied to the memory apparatuses 1200 and 1300 illustrated in FIGS. 15A and 15B in the first byte mode, the third memory data signals mDQA1<n+1:2n> may be transmitted between the second data buffering circuit 1422 and the second data pads 1223-2 and 1323-2 of the third memory dies 1223 and 1323, and the fourth memory data signals mDQA2<n+1:2n> may be transmitted between the second data buffering circuit 1422 and the second data pads 1224-2 and 1324-2 of the fourth memory dies 1224 and 1324.

The buffer die 1400 may further include a plurality of buffer circuits. The buffer die 1400 may further include a first data clock buffer circuit 1431, a first read strobe buffer circuit 1441, a system clock buffer circuit 1451, a first command address buffer circuit 1461, a first chip selection buffer circuit 1471, a second data clock buffer circuit 1432, and a second read strobe buffer circuit 1442. Components of the buffer die 1400 are merely illustrative, and the buffer die 1400 may further include any other components not illustrated in FIG. 16A in order to interface signals required for operation of the memory apparatus 1100, 1200, or 1300. The first data clock buffer circuit 1431 may receive a first data clock signal WCKTA1 and a first complementary data clock signal WCKBA1 from an external apparatus. The first data clock buffer circuit 1431 may buffer the first data clock signal WCKTA1 and the first complementary data clock signal WCKBA1 and may output a first memory data clock signal mWCKTA1 and a first complementary memory data clock signal mWCKBA1. Regardless of the byte mode, the first data clock buffer circuit 1431 may provide the first memory data clock signal pair mWCKTA1 and mWCKBA1 to the first and second memory dies, that is, 1121 and 1122 of FIGS. 14, 1221 and 1222 of FIG. 15A, and 1321 and 1322 of FIG. 15B, and the first and second memory dies may perform data input/output operations in synchronization with the first memory data clock signal pair mWCKTA1 and mWCKBA1.

The first read strobe buffer circuit 1441 may receive a first memory read strobe signal mRDQSTA1 and a first complementary memory read strobe signal mRDQSBA1. The first memory read strobe signal pair mRDQSTA1 and mRDQSBA1 may be generated based on the first memory data clock signal pair mWCKTA1 and mWCKBA1. The first read strobe buffer circuit 1441 may buffer the first memory read strobe signal pair mRDQSTA1 and mRDQSBA1 to generate a first read strobe signal RDQSTA1 and a first complementary read strobe signal RDQSBA1, and may output the first read strobe signal pair RDQSTA1 and RDQSBA1 to an external apparatus. Regardless of the byte mode, the first read strobe buffer circuit 1441 may receive the first memory read strobe signal pair mRDQSTA1 and mRDQSBA1 from one of the first and second memory dies, that is, 1121 and 1122 of FIGS. 14, 1221 and 1222 of FIG. 15A, and 1321 and 1322 of FIG. 15B.

The system clock buffer circuit 1451 may receive a system clock signal CKT and a complementary system clock signal CKB from the external apparatus and may buffer the system clock signal pair CKT and CKB. The system clock buffer circuit 1451 may output the buffered system clock signal as a memory system clock signal mCKT and may output the buffered complementary system clock signal CKB as a complementary memory system clock signal mCKB. When the buffer die 1400 is applied to the memory apparatus 1100 illustrated in FIG. 14 in the second byte mode, the system clock buffer circuit 1451 may provide the memory system clock signal pair mCKT and mCKB in common to the first to fourth memory dies 1121 to 1124. When the buffer die 1400 is applied to the memory apparatuses 1200 and 1300 illustrated in FIGS. 15A and 15B in the first byte mode, the system clock buffer circuit 1451 may provide the memory system clock signal pair mCKT and mCKB in common to the first to eighth memory dies 1221 to 1228 and 1321 to 1328.

The first command address buffer circuit 1461 may receive the command address signal CAA<1:m> from the external apparatus, and may generate a buffered command address signal BCAA<1:m> by buffering the command address signal CAA<1:m>. The first command address buffer circuit 1461 may output the buffered command address signal BCAA<1:m> as a first memory command address signal mCAA1<1:m> and a second memory command address signal mCAA2<1:m>. The buffered command address signal BCAA<1:m> may be provided to the buffer control circuit 1411. The command address signal CAA<1:m> may be synchronized with the system clock signal pair CKT and CKB. The first command address buffer circuit 1461 may generate both the first and second memory command address signals mCAA1<1:m> and mCAA2<1:m> from the command address signal CAA<1:m> in the first byte mode, and may generate only the first memory command address signal mCAA1<1:m> from the command address signal CAA<1:m> in the second byte mode. The first command address buffer circuit may receive a byte mode signal Xn. The byte mode signal Xn may be a signal capable of identifying the first and second byte modes, and the byte mode signal Xn may be enabled in the first byte mode and may be disabled in the second byte mode. A path for generating the second memory command address signal mCAA2<1:m> from the command address signal CAA<1:m> in the first command address buffer circuit 1461 may receive the byte mode signal Xn, and may be selectively activated according to whether the byte mode signal Xn is enabled to selectively generate the second memory command address signal mCAA2<1:m>. When the buffer die 1400 is applied to the memory apparatus 1100 illustrated in FIG. 14 in the second byte mode, the first command address buffer circuit 1461 may generate only the first memory command address signal mCAA1<1:m>, and may provide the first memory command address signal mCAA1<1:m> in common to the first and second memory dies. When the buffer die 1400 is applied to the memory apparatuses 1200 and 1300 illustrated in FIGS. 15A and 15B in the first byte mode, the first command address buffer circuit 1461 may generate both the first and second memory command address signals mCAA1<1:m> and mCAA2<1:m>, may provide the first memory command address signal mCAA1<1:m> in common to the first and second memory dies 1221, 1222, 1321, and 1322, and may provide the second memory command address signal mCAA2<1:m> in common to the third and fourth memory dies 1223, 1224, 1323, and 1324.

The first chip selection buffer circuit 1471 may receive the first chip selection signal CSA1 and the second chip selection signal CSA2 from the external apparatus. The first chip selection buffer circuit 1471 may generate a first buffered chip selection signal BCSA1 and a second buffered chip selection signal BCSA2 by buffering the first and second chip selection signals CSA1 and CSA2. The first chip selection buffer circuit 1471 may output the first buffered chip selection signal BCSA1 as a first memory chip selection signal mCSA1 and may output the second buffered chip selection signal BCSA2 as a second memory chip selection signal mCSA2. When the buffer die 1400 is applied to the memory apparatus 1100 illustrated in FIG. 14 in the second byte mode, the first chip selection buffer circuit 1471 may provide the first memory chip selection signal mCSA1 to the first memory die 1121 and may provide the second memory chip selection signal mCSA2 to the second memory die 1122. When the buffer die 1400 is applied to the memory apparatuses 1200 and 1300 illustrated in FIGS. 15A and 15B in the first byte mode, the first chip selection buffer circuit 1471 may provide the first memory chip selection signal mCSA1 in common to the first and third memory dies 1221, 1223, 1321, and 1323, and may provide the second memory chip selection signal mCSA2 in common to the second and fourth memory dies 1222, 1224, 1322, and 1324.

The second data clock buffer circuit 1432 may receive a second data clock signal WCKTA2 and a second complementary data clock signal WCKBA2 from the external apparatus. The second data clock signal pair WCKTA2 and WCKBA2 may be independent of the first data clock signal pair WCKTA1 and WCKBA1 and may have the same timing or different timing. The second data clock buffer circuit 1432 may buffer the second data clock signal WCKTA2 and the second complementary data clock signal WCKBA2 and may output a second memory data clock signal mWCKTA2 and a second complementary memory data clock signal mWCKBA2. The second data clock buffer circuit 1432 may receive the byte mode signal Xn. The second data clock buffer circuit 1432 may be selectively activated according to whether the byte mode signal Xn is enabled, thereby selectively generating the second memory data clock signal pair mWCKTA2 and mWCKBA2. When the buffer die 1400 is applied to the memory apparatus 1100 illustrated in FIG. 14 in the second byte mode, the second data clock buffer circuit 1432 may be deactivated. When the buffer die 1400 is applied to the memory apparatuses 1200 and 1300 illustrated in FIGS. 15A and 15B in the first byte mode, the second data clock buffer circuit 1432 may provide the second memory data clock signal pair mWCKTA2 and mWCKBA2 to the third and fourth memory dies 1223, 1224, 1323, and 1324, and the third and fourth memory dies 1223, 1224, 1323, and 1324 may perform data input/output operations in synchronization with the second memory data clock signal pair mWCKTA2 and mWCKBA2.

The second read strobe buffer circuit 1442 may receive a second memory read strobe signal mRDQSTA2 and a second complementary memory read strobe signal mRDQSBA2. The second memory read strobe signal pair mRDQSTA2 and mRDQSBA2 may be generated based on the second memory data clock signal pair mWCKTA2 and mWCKBA2. The second read strobe buffer circuit 1442 may buffer the second memory read strobe signal pair mRDQSTA2 and mRDQSBA2 to generate a second read strobe signal RDQSTA2 and a second complementary read strobe signal RDQSBA2, and may output the second read strobe signal pair RDQSTA2 and RDQSBA2 to the external apparatus. The second read strobe buffer circuit 1442 may receive the byte mode signal Xn. The second read strobe buffer circuit 1442 may be selectively activated according to whether the byte mode signal Xn is enabled to selectively generate the second read strobe signal pair RDQSTA2 and RDQSBA2. When the buffer die 1400 is applied to the memory apparatus 1100 illustrated in FIG. 14 in the second byte mode, the second read strobe buffer circuit 1442 may be deactivated. When the buffer die 1400 is applied to the memory apparatuses 1200 and 1300 illustrated in FIGS. 15A and 15B in the first byte mode, the second read strobe buffer circuit 1442 may receive the second memory read strobe signal pair mRDQSTA2 and mRDQSBA2 from the memory dies 1223, 1224, 1323, and 1324, and may buffer the second memory read strobe signal pair mRDQSTA2 and mRDQSBA2 to generate the second read strobe signal pair RDQSTA2 and RDQSBA2.

Referring to FIG. 16B, the buffer die 1400 may include a second buffer control circuit 1412, a third data buffering circuit 1423, and a fourth data buffering circuit 1424. The third data buffering circuit 1423 may constitute the third data control circuit 1133, 1233, and 1333 illustrated in FIG. 14, FIG. 15A, and FIG. 15B, and the fourth data buffering circuit 1424 may constitute the fourth data control circuit 1134, 1234, and 1334 illustrated in FIG. 14, FIG. 15A, and FIG. 15B. The second buffer control circuit 1412 may be provided in one of the third and fourth data control circuits 1423 and 1424, or may be provided between the third and fourth data control circuits 1423 and 1424. The second buffer control circuit 1412 may generate a first path selection signal PSB1 and a second path selection signal PSB2 based on a command address signal CAB<1:m> and chip selection signals CSB1 and CSB2. The second buffer control circuit 1412 may generate the first and second path selection signals PSB1 and PSB2 by receiving a buffered command address signal BCAB<1:m> generated by buffering the command address signal CAB<1:m> and a first buffered chip selection signal BCSB1 and a second buffered chip selection signal BCSB2 generated by buffering the first and second chip selection signals CSB1 and CSB2. The second buffer control circuit 1412 may enable the first path selection signal PSB1 when the first chip selection signal CSB1 is asserted. The second buffer control circuit 1412 may enable the second path selection signal PSB2 when the second chip selection signal CSB2 is asserted. The command address signal CAB<1:m> may include a write command and a read command. The first path selection signal PSB1 may include a first write path signal CSWB1 and a first read path signal CSRB1, and the second path selection signal PSB2 may include a second write path signal CSWB2 and a second read path signal CSRB2. The second buffer control circuit 1412 may enable the first write path signal CSWB1 when the write command and the first chip selection signal CSB1 are asserted. The second buffer control circuit 1412 may enable the second write path signal CSWB2 when the write command and the second chip selection signal CSB2 are asserted. The second buffer control circuit 1412 may enable the first read path signal CSRB1 when the read command and the first chip selection signal CSB1 are asserted. The second buffer control circuit 1412 may enable the second read path signal CSRB2 when the read command and the second chip selection signal CSB2 are asserted. The second buffer control circuit 1412 may include a configuration substantially identical to the first buffer control circuit 1411. The command address signal CAB<1:m> may have the same characteristics as the command address signal CAA<1:m>, and the first and second chip selection signals CSB1 and CSB2 may have the same characteristics as the first and second chip selection signals CSA1 and CSA2. The first and second path selection signals PSB1 and PSB2 may also have the same characteristics as the first and second path selection signals PSA1 and PSA2. The first and second write path signals CSWB1 and CSWB2 may have the same characteristics as the first and second write path signals CSWA1 and CSWA2, and the first and second read path signals CSRB1 and CSRB2 may also have the same characteristics as the first and second read path signals CSRA1 and CSRA2.

The third data buffering circuit 1423 may receive the first and second path selection signals PSB1 and PSB2 from the second buffer control circuit 1412. The third data buffering circuit 1423 may be connected to the third data bus 1103, 1203, or 1303, the fifth signal transmission lines 1112-5, 1212-5, or 1312-5, and the sixth signal transmission lines 1112-6, 1212-6, or 1312-6. The third data buffering circuit 1423 may connect the third data bus to the fifth signal transmission lines when the first path selection signal PSB1 is enabled. The third data buffering circuit 1423 may connect the third data bus to the sixth signal transmission lines when the second path selection signal PSB2 is enabled. Third data signals DQB<1:n> may propagate through the third data bus, fifth memory data signals mDQB1<1:n> may propagate through the fifth signal transmission lines, and sixth memory data signals mDQB2<1:n> may propagate through the sixth signal transmission lines. The third data buffering circuit 1423 may receive the third data signals DQB<1:n> transmitted from the external apparatus when the first write path signal CSWB1 is enabled, and may output the third data signals DQB<1:n> as the fifth memory data signals mDQB1<1:n>. The third data buffering circuit 1423 may receive the third data signals DQB<1:n> transmitted from the external apparatus when the second write path signal CSWB2 is enabled, and may output the third data signals DQB<1:n> as the sixth memory data signals mDQB2<1:n>. The third data buffering circuit 1423 may receive the fifth memory data signals mDQB1<1:n> when the first read path signal CSRB1 is enabled, and may output the fifth memory data signals mDQB1<1:n> as the third data signals DQB<1:n> to the external apparatus. The third data buffering circuit 1423 may receive the sixth memory data signals mDQB2<1:n> when the second read path signal CSRB2 is enabled, and may output the sixth memory data signals mDQB2<1:n> as the third data signals DQB<1:n> to the external apparatus. The third data buffering circuit 1423 may include substantially the same configuration as the first data buffering circuit 1421, except for types of an input signal and an output signal. When the buffer die 1400 is applied to the memory apparatus 1100 illustrated in FIG. 14 in the second byte mode, the fifth memory data signals mDQB1<1:n> may be transmitted between the third data buffering circuit 1423 and the third data pads 1123-3 of the third memory die 1123, and the sixth memory data signals mDQB2<1:n> may be transmitted between the third data buffering circuit 1423 and the third data pads 1124-3 of the fourth memory die 1124. When the buffer die 1400 is applied to the memory apparatuses 1200 and 1300 illustrated in FIGS. 15A and 15B in the first byte mode, the fifth memory data signals mDQB1<1:n> may be transmitted between the third data buffering circuit 1423 and the third data pads 1225-3 and 1325-3 of the fifth memory dies 1225 and 1325, and the sixth memory data signals mDQB2<1:n> may be transmitted between the third data buffering circuit 1423 and the third data pads 1226-3 and 1326-3 of the sixth memory dies 1226 and 1326.

The fourth data buffering circuit 1424 may receive the first and second path selection signals PSB1 and PSB2 from the second buffer control circuit 1412. The fourth data buffering circuit 1424 may be connected to the fourth data bus 1104, 1204, or 1304, the seventh signal transmission lines 1112-7, 1212-7, or 1312-7, and the eighth signal transmission lines 1112-8, 1212-8, or 1312-8. The fourth data buffering circuit 1424 may connect the fourth data bus to the seventh signal transmission lines when the first path selection signal PSB1 is enabled. The fourth data buffering circuit 1424 may connect the fourth data bus to the eighth signal transmission lines when the second path selection signal PSB2 is enabled. The fourth data signals DQB<n+1:2n> may propagate through the fourth data bus, the seventh memory data signals mDQB1<n+1:2n> may propagate through the seventh signal transmission lines, and the eighth memory data signals mDQB2<n+1:2n> may propagate through the eighth signal transmission lines. The fourth data buffering circuit 1424 may receive the fourth data signals DQB<n+1:2n> transmitted from the external apparatus when the first write path signal CSWB1 is enabled, and may output the fourth data signals DQB<n+1:2n> as the seventh memory data signals mDQB1<n+1:2n>. The fourth data buffering circuit 1424 may receive the fourth data signals DQB<n+1:2n> transmitted from the external apparatus when the second write path signal CSWB2 is enabled, and may output the fourth data signals DQB<n+1:2n> as the eighth memory data signals mDQB2<n+1:2n>. The fourth data buffering circuit 1424 may receive the seventh memory data signals mDQB1<n+1:2n> when the first read path signal CSRB1 is enabled, and may output the seventh memory data signals mDQB1<n+1:2n> as the fourth data signals DQB<n+1:2n> to the external apparatus. The fourth data buffering circuit 1424 may receive the eighth memory data signals mDQB2<n+1:2n> when the second read path signal CSRB2 is enabled, and may output the eighth memory data signals mDQB2<n+1:2n> as the fourth data signals DQB<n+1:2n> to the external apparatus. The fourth data buffering circuit 1424 may include substantially the same configuration as the second data buffering circuit 1422 except for types of an input signal and an output signal. When the buffer die 1400 is applied to the memory apparatus 1100 illustrated in FIG. 14 in the second byte mode, the seventh memory data signals mDQB1<n+1:2n> may be transmitted between the fourth data buffering circuit 1424 and the fourth data pads 1123-4 of the third memory die 1123, and the eighth memory data signals mDQB2<n+1:2n> may be transmitted between the fourth data buffering circuit 1424 and the fourth data pads 1124-4 of the fourth memory die 1124. When the buffer die 1400 is applied to the memory apparatuses 1200 and 1300 illustrated in FIGS. 15A and 15B in the first byte mode, the seventh memory data signals mDQB1<n+1:2n> may be transmitted between the fourth data buffering circuit 1424 and the fourth data pads 1227-4 and 1327-4 of the seventh memory dies 1227 and 1327, and the eighth memory data signals mDQB2<n+1:2n> may be transmitted between the fourth data buffering circuit 1424 and the fourth data pads 1228-4 and 1328-4 of the eighth memory dies 1228 and 1328.

The buffer die 1400 may further include a third data clock buffer circuit 1433, a third read strobe buffer circuit 1443, a second command address buffer circuit 1462, a second chip selection buffer circuit 1472, a fourth data clock buffer circuit 1434, and a fourth read strobe buffer circuit 1444. The third data clock buffer circuit 1433 may receive a third data clock signal WCKTB1 and a third complementary data clock signal WCKBB1 from the external apparatus. The third data clock buffer circuit 1433 may buffer the third data clock signal WCKTB1 and the third complementary data clock signal WCKBB1 to generate a third memory data clock signal mWCKTB1 and a third complementary memory data clock signal mWCKBB1. When the buffer die 1400 is applied to the memory apparatus 1100 illustrated in FIG. 14 in the second byte mode, the third data clock buffer circuit 1433 may provide the third memory data clock signal pair mWCKTB1 and mWCKBB1 to the third and fourth memory dies 1123 and 1124, and the third and fourth memory dies 1123 and 1124 may perform a data input/output operation in synchronization with the third memory data clock signal pair mWCKTB1 and mWCKBB1. When the buffer die 1400 is applied to the memory apparatuses 1200 and 1300 illustrated in FIGS. 15A and 15B in the first byte mode, the third data clock buffer circuit 1433 may provide the third memory data clock signal pair mWCKTB1 and mWCKBB1 to the fifth and sixth memory dies 1225, 1226, 1325, and 1326, and the fifth and sixth memory dies 1225, 1226, 1325, and 1326 may perform a data input/output operation in synchronization with the third memory data clock signal pair mWCKTB1 and mWCKBB1.

The third read strobe buffer circuit 1443 may receive a third memory read strobe signal mRDQSTB1 and a third complementary memory read strobe signal mRDQSBB1. The third memory read strobe signal pair mRDQSTB1 and mRDQSBB1 may be generated based on the third memory data clock signal pair mWCKTB1 and mWCKBB1. The third read strobe buffer circuit 1443 may buffer the third memory read strobe signal pair mRDQSTB1 and mRDQSBB1 and may output a third read strobe signal RDQSTB1 and a third complementary read strobe signal RDQSBB1 to the external apparatus. When the buffer die 1400 is applied to the memory apparatus 1100 illustrated in FIG. 14 in the second byte mode, the third read strobe buffer circuit 1443 may receive the third memory read strobe signal pair mRDQSTB1 and mRDQSBB1 from one of the third and fourth memory dies 1123 and 1124. When the buffer die 1400 is applied to the memory apparatuses 1200 and 1300 illustrated in FIGS. 15A and 15B in the first byte mode, the third read strobe buffer circuit 1443 may receive the third memory read strobe signal pair mRDQSTB1 and mRDQSBB1 from one of the fifth and sixth memory dies 1225, 1226, 1325, and 1326.

The second command address buffer circuit 1462 may receive a command address signal CAB<1:m> from the external apparatus and may buffer the command address signal CAB<1:m> to generate a buffered command address signal BCAB<1:m>. The second command address buffer circuit 1462 may output the buffered command address signal BCAB<1:m> as a first memory command address signal mCAB1<1:m> and a second memory command address signal mCAB2<1:m>. The buffered command address signal BCAB<1:m> may be provided to the second buffer control circuit 1412. The second command address buffer circuit 1462 may generate both the first memory command address signal mCAB1<1:m> and the second memory command address signal mCAB2<1:m> from the command address signal CAB<1:m> in the first byte mode and may generate only the first memory command address signal mCAB1<1:m> from the command address signal CAB<1:m> in the second byte mode. The second command address buffer circuit 1462 may receive the byte mode signal Xn. In the second command address buffer circuit 1462, a path for generating the second memory command address signal mCAB2<1:m> from the command address signal CAB<1:m> may receive the byte mode signal Xn and may be selectively activated according to whether the byte mode signal Xn is enabled to selectively generate the second memory command address signal mCAB2<1:m>. When the buffer die 1400 is applied to the memory apparatus 1100 illustrated in FIG. 14 in the second byte mode, the second command address buffer circuit 1462 may generate only the first memory command address signal mCAB1<1:m> and may provide the first memory command address signal mCAB1<1:m> in common to the third and fourth memory dies 1123 and 1124. When the buffer die 1400 is applied to the memory apparatuses 1200 and 1300 illustrated in FIGS. 15A and 15B in the first byte mode, the second command address buffer circuit 1462 may generate both the first memory command address signal mCAB1<1:m> and the second memory command address signal mCAB2<1:m>, may provide the first memory command address signal mCAB1<1:m> in common to the fifth and sixth memory dies 1225, 1226, 1325, and 1326, and may provide the second memory command address signal mCAB2<1:m> in common to the seventh and eighth memory dies 1227, 1228, 1327, and 1328.

The second chip selection buffer circuit 1472 may receive the first chip selection signal CSB1 and the second chip selection signal CSB2 from the external apparatus. The second chip selection buffer circuit 1472 may buffer the first and second chip selection signals CSB1 and CSB2 to generate a first buffered chip selection signal BCSB1 and a second buffered chip selection signal BCSB2. The second chip selection buffer circuit 1472 may output the first buffered chip selection signal BCSB1 as a first memory chip selection signal mCSB1 and may output the second buffered chip selection signal BCSB2 as a second memory chip selection signal mCSB2. When the buffer die 1400 is applied to the memory apparatus 1100 illustrated in FIG. 14 in the second byte mode, the second chip selection buffer circuit 1472 may provide the first memory chip selection signal mCSB1 to the third memory die 1123 and may provide the second memory chip selection signal mCSB2 to the fourth memory die 1124. When the buffer die 1400 is applied to the memory apparatuses 1200 and 1300 illustrated in FIGS. 15A and 15B in the first byte mode, the second chip selection buffer circuit 1472 may provide the first memory chip selection signal mCSB1 in common to the fifth and sixth memory dies 1225, 1226, 1325, and 1326 and may provide the second memory chip selection signal mCSB2 in common to the seventh and eighth memory dies 1227, 1228, 1327, and 1328.

The fourth data clock buffer circuit 1434 may receive a fourth data clock signal WCKTB2 and the fourth complementary data clock signal WCKBB2 from the external apparatus. The fourth data clock signal pair WCKTB2 and WCKBB2 may be independent of the third data clock signal pair WCKTB1 and WCKBB1 and may have the same timing as each other, but may have different timings. The fourth data clock buffer circuit 1434 may buffer the fourth data clock signal WCKTB2 and the fourth complementary data clock signal WCKBB2 to generate a fourth memory data clock signal mWCKTB2 and a fourth complementary memory data clock signal mWCKBB2. The fourth data clock buffer circuit 1434 may receive the byte mode signal Xn. The fourth data clock buffer circuit 1434 may be selectively activated according to whether the byte mode signal Xn is enabled to selectively generate the fourth memory data clock signal pair mWCKTB2 and mWCKBB2. When the buffer die 1400 is applied to the memory apparatus 1100 illustrated in FIG. 14 in the second byte mode, the fourth data clock buffer circuit 1434 may be deactivated. When the buffer die 1400 is applied to the memory apparatuses 1200 and 1300 illustrated in FIGS. 15A and 15B in the first byte mode, the fourth data clock buffer circuit 1434 may provide the fourth memory data clock signal pair mWCKTB2 and mWCKBB2 to the seventh and eighth memory dies 1227, 1228, 1327, and 1328, and the seventh and eighth memory dies 1227, 1228, 1327, and 1328 may perform a data input/output operation in synchronization with the fourth memory data clock signal pair mWCKTB2 and mWCKBB2.

The fourth read strobe buffer circuit 1444 may receive a fourth memory read strobe signal mRDQSTB2 and a fourth complementary memory read strobe signal mRDQSBB2. The fourth memory read strobe signal pair mRDQSTB2 and mRDQSBB2 may be generated based on the fourth memory data clock signal pair mWCKTB2 and mWCKBB2. The fourth read strobe buffer circuit 1444 may buffer the fourth memory read strobe signal pair mRDQSTB2 and mRDQSBB2 to generate a fourth read strobe signal RDQSTB2 and a fourth complementary read strobe signal RDQSBB2 and may output the fourth read strobe signal pair RDQSTB2 and RDQSBB2 to the external apparatus. The fourth read strobe buffer circuit 1444 may receive the byte mode signal Xn. The fourth read strobe buffer circuit 1444 may be selectively activated according to whether the byte mode signal Xn is enabled to selectively generate the fourth read strobe signal pair RDQSTB2 and RDQSBB2. When the buffer die 1400 is applied to the memory apparatus 1100 illustrated in FIG. 14 in the second byte mode, the fourth read strobe buffer circuit 1444 may be deactivated. When the buffer die 1400 is applied to the memory apparatuses 1200 and 1300 illustrated in FIGS. 15A and 15B in the first byte mode, the fourth read strobe buffer circuit 1444 may receive the fourth memory read strobe signal pair mRDQSTB2 and mRDQSBB2 from one of the seventh and eighth memory dies 1227, 1228, 1327, and 1328 and may buffer the fourth memory read strobe signal pair mRDQSTB2 and mRDQSBB2 to generate the fourth read strobe signal pair RDQSTB2 and RDQSBB2.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A memory apparatus comprising:
a package substrate;
a first memory die, a second memory die, a third memory die, and a fourth memory die sequentially disposed on the package substrate; and
a buffer die disposed on the package substrate, connected to a first data bus and a second data bus, and configured, based on a chip selection signal, to connect the first data bus to one of the first memory die and the second memory die and connect the second data bus to one of the third memory die and the fourth memory die.

2. The memory apparatus of claim 1, wherein the chip selection signal includes a first chip selection signal and a second chip selection signal,
the first memory die and the third memory die are accessed based on the first chip selection signal, the second memory die and the fourth memory die are accessed based on the second chip selection signal,
when the first chip selection signal is asserted, the buffer die connects the first data bus to the first memory die and connects the second data bus to the third memory die, and
when the second chip selection signal is asserted, the buffer die connects the first data bus to the second memory die and connects the second data bus to the fourth memory die.

3. The memory apparatus of claim 1, wherein the buffer die comprises a data control circuit configured to selectively connect the first data bus to the first and second memory dies and to selectively connect the second data bus to the third and fourth memory dies based on a command address signal and the chip selection signal.

4. The memory apparatus of claim 1, wherein the buffer die comprises:
a buffer control circuit configured to generate a first path selection signal and a second path selection signal based on a command address signal and the chip selection signal;
a first data buffering circuit configured to connect the first data bus to the first memory die and the second memory die based on the first path selection signal and the second path selection signal; and
a second data buffering circuit configured to connect the second data bus to the third memory die and the fourth memory die based on the first path selection signal and the second path selection signal.

5. The memory apparatus of claim 4, wherein the command address signal includes a write command and a read command, the chip selection signal includes a first chip selection signal and a second chip selection signal, the buffer control circuit enables a first write path signal based on the write command and the first chip selection signal, enables a second write path signal based on the write command and the second chip selection signal, enables a first read path signal based on the read command and the first chip selection signal, and enables a second read path signal based on the read command and the second chip selection signal.

6. The memory apparatus of claim 5, wherein the buffer control circuit comprises:
a command decoding circuit configured to generate a first preliminary write path signal, a second preliminary write path signal, a first preliminary read path signal, and a second preliminary read path signal based on the command address signal, the first chip selection signal, and the second chip selection signal; and
a latency control circuit configured to delay the first preliminary write path signal and the second preliminary write path signal by a time corresponding to a write latency to generate the first write path signal and the second write path signal and configured to delay the first preliminary read path signal and the second preliminary read path signal by a time corresponding to a read latency to generate the first read path signal and the second read path signal.

7. The memory apparatus of claim 6, wherein the first data buffering circuit comprises:
a write path selection circuit configured to transmit first data signals received through the first data bus to the first memory die based on the first write path signal and configured to transmit the first data signals to the second memory die based on the second write path signal; and
a read path selection circuit configured to transmit first memory data signals from the first memory die to the first data bus based on the first read path signal and configured to transmit second memory data signals from the second memory die to the first data bus based on the second read path signal.

8. The memory apparatus of claim 6, wherein the second data buffering circuit comprises:
a write path selection circuit configured to transmit second data signals received through the second data bus to the third memory die based on the first write path signal and configured to transmit the second data signals to the fourth memory die based on the second write path signal; and
a read path selection circuit configured to transmit third memory data signals from the third memory die to the second data bus based on the first read path signal and configured to transmit fourth memory data signals output from the fourth memory die to the second data bus based on the second read path signal.

9. The memory apparatus of claim 1, wherein the first to fourth memory dies each include n first data pads and n second data pads, and n is an integer of 2 or more,
the first data pads of the first memory die and the first data pads of the second memory die are connected to the first data bus through the buffer die, and
the second data pads of the third memory die and the second data pads of the fourth memory die are connected to the second data bus through the buffer die.

10. The memory apparatus of claim 9, wherein the second memory die is disposed on the first memory die with an offset such that the first data pads of the first memory die are exposed,
the third memory die is disposed on the second memory die with an offset such that the first data pads of the second memory die are exposed, and
the fourth memory die is disposed on the third memory die with an offset such that the second data pads of the third memory die are exposed.

11. The memory apparatus of claim 9, wherein the package substrate includes first pads, second pads, third pads, and fourth pads,
the first data pads of the first memory die are connected to the first pads through first bonding wires,
the first data pads of the second memory die are connected to the second pads through second bonding wires,
the second data pads of the third memory die are connected to the third pads through third bonding wires, and
the second data pads of the fourth memory die are connected to the fourth pads through fourth bonding wires.

12. The memory apparatus of claim 11, wherein the package substrate includes first signal transmission lines, second signal transmission lines, third signal transmission lines, and fourth signal transmission lines,
the first signal transmission lines connect the first pads and the buffer die, the second signal transmission lines connect the second pads and the buffer die, the third signal transmission lines connect the third pads and the buffer die, and the fourth signal transmission lines connect the fourth pads and the buffer die, and
the buffer die connects one of the first signal transmission lines and the second signal transmission lines to the first data bus and connects one of the third signal transmission lines and the fourth signal transmission lines to the second data bus.

13. The memory apparatus of claim 1, wherein a voltage swing of a signal transmitted through the first data bus and the second data bus is greater than a voltage wing of a signal transmitter between the first memory die to the fourth memory die and the buffer die.

14. The memory apparatus of claim 1, wherein a voltage swing of signals transmitted between the buffer die and the memory dies is smaller than a voltage swing of signals transmitted between the buffer die and an external apparatus.

15. The memory apparatus of claim 1, wherein the first memory die and the third memory die constitute a first rank associated with a first chip selection signal and the second memory die and the fourth memory die constitute a second rank associated with a second chip selection signal.

16. A memory apparatus comprising:
a package substrate;
a buffer die disposed on the package substrate;
a first memory die, a second memory die, a third memory die, and a fourth memory die sequentially disposed on the buffer die,
wherein the buffer die is connected to a first data bus and a second data bus and, based on a chip selection signal, connects the first data bus to one of the first memory die and the second memory die and connects the second data bus to one of the third memory die and the fourth memory die.

17. The memory apparatus of claim 16, wherein the chip selection signal includes a first chip selection signal and a second chip selection signal,
the first memory die and the third memory die are accessed based on the first chip selection signal, the second memory die and the fourth memory die are accessed based on the second chip selection signal,
when the first chip selection signal is asserted, the buffer die connects the first data bus to the first memory die and connects the second data bus to the third memory die, and
when the second chip selection signal is asserted, the buffer die connects the first data bus to the second memory die and connects the second data bus to the fourth memory die.

18. The memory apparatus of claim 16, wherein each of the first to fourth memory dies each include n first data pads and n second data pads, and n is an integer of 2 or more,
the first data pads of the first memory die and the first data pads of the second memory die are connected to the first data bus through the buffer die, and
the second data pads of the third memory die and the second data pads of the fourth memory die are connected to the second data bus through the buffer die.

19. The memory apparatus of claim 18, wherein the second memory die is disposed on the first memory die with an offset in a second direction opposite to a first direction such that the first data pads of the first memory die are exposed in the first direction,
the third memory die is disposed on the second memory die with an offset in the second direction such that the first data pads of the second memory die are exposed in the first direction, and
the fourth memory die is disposed on the third memory die with an offset in the first direction such that the second data pads of the third memory die are exposed in the second direction.

20. The memory apparatus of claim 19, wherein the package substrate includes first pads, second pads, third pads, and fourth pads,
the first pads and the second pads are disposed on the package substrate in the first direction, and the third pads and the fourth pads are disposed on the package substrate in the second direction,
the first data pads of the first memory die are connected to the first pads through first bonding wires,
the first data pads of the second memory die are connected to the second pads through second bonding wires,
the second data pads of the third memory die are connected to the third pads through third bonding wires, and
the second data pads of the fourth memory die are connected to the fourth pads through fourth bonding wires.

21. The memory apparatus of claim 20, wherein the package substrate comprises:
first signal transmission lines that connect the first pads and the buffer die;
second signal transmission lines that connect the second pads and the buffer die;
third signal transmission lines that connect the third pads and the buffer die; and
fourth signal transmission lines that connect the fourth pads and the buffer die.
